(19) United States
(12) Patent Application Publication
(10) Pub. No.: US 2024/0407148 A1
(43) Pub. Date: Dec. 5, 2024

(54) TOOL AND PROCESSES FOR PICK-AND-PLACE ASSEMBLY

(71) Applicants: Board of Regents, The University of Texas System, Austin, TX (US); Silicon Metamaterials, Inc., Austin, TX (US)

(72) Inventors: Sidlgata V. Sreenivasan, Austin, TX (US); Paras Ajay, Austin, TX (US); Austin Anthis, Austin, TX (US)

(21) Appl. No.: 18/696,516

(22) PCT Filed: Sep. 30, 2022
(86) PCT No.: PCT/US2022/045466

§ 371 Date: Mar. 28, 2024

Related U.S. Application Data
(60) Provisional application No. 63/400,004, filed on Aug. 22, 2022.
(60) Provisional application No. 63/290,228, filed on Dec. 16, 2021.
(60) Provisional application No. 63/250,252, filed on Sep. 30, 2021.

(51) Int. Cl. H05K 13/04; H05K 3/30

(52) U.S. Cl. CPC H05K 13/0408; H05K 3/305

(57) ABSTRACT

A system for assembling a group of dies from a source substrate onto a transfer substrate. A high-throughput low-precision system is configured to pick the group of dies from the source substrate and placed onto an intermediate substrate, where the placement of the group of dies onto the intermediate substrate is performed such that the X and/or Y pitch of the placed group of dies matches a corresponding system-in-package (SiP) pitch. Furthermore, a parallel high-precision system is configured to pick and place the group of dies from the intermediate substrate onto the transfer substrate, where the placement of the group of dies onto the transfer substrate is performed at the SiP pitch, where a precision of assembly onto the transfer substrate is sub-500 nm.

### CROSS REFERENCE TO RELATED APPLICATIONS

This application claims priority to U.S. Provisional Patent Application Ser. No. 63/250,252 entitled “Tool and Processes for Pick-and-Place Assembly,” filed on Sep. 30, 2021, which is incorporated by reference herein in its entirety.

This application further claims priority to U.S. Provisional Patent Application Ser. No. 63/290,228 entitled “Tool and Processes for Pick-and-Place Assembly,” filed on Dec. 16, 2021, which is incorporated by reference herein in its entirety.

This application additionally claims priority to U.S. Provisional Patent Application Ser. No. 63/400,004 entitled “Tool for Pick-and-Place Assembly,” filed on Aug. 22, 2022, which is incorporated by reference herein in its entirety.

### TECHNICAL FIELD

The present invention relates generally to surface-mount technology component placement systems, and more particularly to a tool and process for pick-and-place assembly.

### BACKGROUND

Surface-mount technology (SMT) component placement systems, commonly called pick-and-place machines or P&Ps, are robotic machines which are used to place surface-mount devices (SMDs) onto a printed circuit board (PCB). They are used for high speed, high precision placing of a broad range of electronic components, such as capacitors, resistors, integrated circuits, etc. onto the PCBs which are in turn used in computers, consumer electronics as well as industrial, medical, automotive, military and telecommunications equipment. Similar equipment exists for through-hole components. This type of equipment is sometimes also used to package microchips using the flip chip method.

The placement equipment is part of a larger overall machine that carries out specific programmed steps to create a PCB assembly. Several sub-systems work together to pick up and correctly place the components onto the PCB. These systems normally use pneumatic suction cups, attached to a plotter-like device to allow the cup to be accurately manipulated in three dimensions. Additionally, each nozzle can be rotated independently.

Surface mount components may be placed along the front (and often back) faces of the machine. Most components are supplied on paper or plastic tape, in tape reels that are loaded onto feeders mounted to the machine. Larger integrated circuits (ICs) are sometimes supplied arranged in trays which are stacked in a compartment. More commonly ICs will be provided in tapes rather than trays or sticks. Improvements in feeder technology mean that tape format is becoming the preferred method of presenting parts on an SMT machine.

Early feeder heads were much bulkier, and as a result it was not designed to be the mobile part of the system. Rather, the PCB itself was mounted on a moving platform that aligned the areas of the board to be populated with the feeder head above.

Through the middle of the machine there is a conveyor belt, along which blank PCBs travel, and a PCB clamp in the center of the machine. The PCB is clamped, and the nozzles pick up individual components from the feeders/trays, rotate them to the correct orientation and then place them on the appropriate pads on the PCB with high precision. High-end machines can have multiple conveyors to produce multiple same or different kinds of products simultaneously.

Unfortunately, there are currently limitations in such surface-mount technology component placement systems in picking and placing components on a target device, such as a printed circuit board. For example, such surface-mount technology component placement systems are expensive and the type of components to be mounted is limited. Furthermore, the speed of such surface-mount technology component placement systems is limited.

### SUMMARY

In one embodiment of the present invention, an apparatus comprises a chucking module for chucking dies, where the dies have a pre-specified range of die sizes and a pre-specified range of die thicknesses, and where a chucking area between the chucking module and the dies varies adaptively depending on a die size.

In another embodiment of the present invention, a system for assembling a group of dies from a source substrate onto a transfer substrate comprises a high-throughput low-precision system configured to pick the group of dies from the source substrate and placed onto an intermediate substrate, where the placement of the group of dies onto the intermediate substrate is performed such that one or more of X and Y pitch of the placed group of dies matches a corresponding system-in-package (SiP) pitch. The system further comprises a parallel high-precision system configured to pick and place the group of dies from the intermediate substrate onto the transfer substrate, where the placement of the group of dies onto the transfer substrate is performed at the SiP pitch, where a precision of assembly onto the transfer substrate is sub-500 nm.

In a further embodiment of the present invention, a system for assembling a group of dies from a source substrate onto a product substrate comprises a high-throughput low-precision system configured to pick the group of dies from the source substrate and placed onto an intermediate substrate, where the placement of the group of dies onto the intermediate substrate is performed such that one or more of X and Y pitch of the placed group of dies matches a corresponding system-in-package (SiP) pitch. The system further comprises a parallel high-precision system configured to assemble the group of dies from the intermediate substrate onto the product substrate, where the placement of the group of dies onto the product substrate is performed at the SiP pitch, where a precision of assembly onto the product substrate is sub-500 nm.

Furthermore, in another embodiment of the present invention, a system for assembling a group of dies from a source substrate onto an intermediate substrate or a transfer substrate comprises a high-throughput low-precision system for picking the group of dies from the source substrate and placed onto the intermediate substrate or the transfer substrate, where the placement of the group of dies onto the intermediate substrate or the transfer substrate is performed such that one or more of X and Y pitch of the placed group of dies matches a corresponding system-in-package (SiP) pitch, where a precision of assembly onto the intermediate substrate or the transfer substrate is sub-500 nm, and where the group of dies are secured in a vicinity of their final position on the intermediate substrate or the transfer substrate using self-assembly principles.

In a further embodiment of the present invention, a system for assembling a group of dies from a source substrate onto an intermediate substrate and/or a product substrate comprises an array of bonding heads configured to pick the group of dies from the source substrate, where a first sub-group of the array of bonding heads picks up a first sub-group of the group of dies and subsequently a second sub-group of the array of bonding heads picks up a second sub-group of the group of dies, and where placement of the group of dies onto the intermediate substrate and/or the product substrate is performed with sub-500 nm precision in a parallel fashion.

In another embodiment of the present invention, a system for assembling a group of dies from a source substrate onto a product substrate comprises an array of bonding heads configured to pick the group of dies from a source substrate, where a first sub-group of the array of bonding heads picks up a first sub-group of the group of dies and subsequently a second sub-group of the array of bonding heads picks up a second sub-group of the group of dies, where the picked first and second sub-groups of the group of dies are subsequently transferred to an array of short-stroke stages at a system-in-package (SiP) pitch in a parallel fashion, where the array of short-stroke stages are used to place the group of dies onto the product substrate at the SiP pitch, and where a precision of assembly onto the product substrate is sub-500 nm.

In a further embodiment of the present invention, a system for assembling a group of dies from a source substrate onto a product substrate comprises a high-throughput die pick-and-place system populating an array of die chucks, where one or more of X and Y pitch of the die chucks matches a corresponding system-in-package (SiP) pitch, where the die chucks are oriented in a same direction as the source substrate and in an opposing direction to the product substrate, where the die chucks are subsequently used to place the group of dies onto the product substrate in parallel, and where a precision of assembly onto the product substrate is sub-500 nm.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates an exemplary system for pick-and-place assembly in accordance with an embodiment of the present invention;

FIG. 2 illustrates a top view of an exemplary transfer chuck in accordance with an embodiment of the present invention;

FIG. 3 illustrates another embodiment of the present invention of the top view of an exemplary transfer chuck that includes an array of elongated ACMs that are fixed to the Y rail;

FIG. 4 illustrates a further embodiment of the present invention of the top view of an exemplary transfer chuck with x direction flexure;

FIGS. 5A-5E illustrate another exemplary transfer chuck with an array of adaptive chuck modules (ACMs) that are moveable with respect to one another using a variable pitch mechanism (VPM) in accordance with an embodiment of the present invention;

FIGS. 6A-6F illustrate an additional exemplary transfer chuck with an array of adaptive chuck modules (ACMs) that are moveable with respect to one another using a variable pitch mechanism (VPM) in accordance with an embodiment of the present invention;

FIGS. 7A-7B illustrate an exemplary split transfer chuck design in accordance with an embodiment of the present invention;

FIGS. 8A-8C illustrate an exemplary Z support plate for enhanced stiffness for the VPM in accordance with an embodiment of the present invention;

FIG. 9 illustrates an exemplary pick-and-place tool design in accordance with an embodiment of the present invention;

FIGS. 10A-10B illustrates an alternative exemplary pick-and-place tool design in accordance with an embodiment of the present invention;

FIGS. 11A-11G illustrate an exemplary wiring architecture for ACMs in accordance with an embodiment of the present invention;

FIGS. 12A-12D illustrate an exemplary planar-motor-based transfer chucks (TCs) in accordance with an embodiment of the present invention;

FIG. 13 illustrates an exemplary process for die placement in accordance with an embodiment of the present invention;

FIG. 14 is a cross-section of an exemplary adaptive chucking module (ACM) in accordance with an embodiment of the present invention;

FIGS. 15A-15B illustrate an exemplary adaptive chucking module (ACM) with viewing windows for metrology in accordance with an embodiment of the present invention;

FIG. 16 is a flowchart of a method for fabricating adaptive chucking modules in accordance with an embodiment of the present invention;

FIGS. 17A-17G depict the cross-sectional views for fabricating adaptive chucking modules using the steps described in FIG. 16 in accordance with an embodiment of the present invention;

FIG. 18 is a flowchart of a method for fabricating adaptive chucking modules that utilize electrostatic chucking in accordance with an embodiment of the present invention;

FIGS. 19A-19C depict the cross-sectional views for fabricating adaptive chucking modules that utilize electrostatic chucking using the steps described in FIG. 18 in accordance with an embodiment of the present invention;

FIG. 20 illustrates a method for pick-and-place assembly in accordance with an embodiment of the present invention;

FIGS. 21A-21B illustrate an alternative method for pick-and-place assembly in accordance with an embodiment of the present invention;

FIGS. 22A-22C illustrate front-to-back alignment of alignment marks placed on the backside of dies in accordance with an embodiment of the present invention;

FIG. 23 illustrates die-to-transfer-wafer alignment using alignment marks on the frontside of the die in accordance with an embodiment of the present invention;

FIG. 24 illustrates die-to-transfer-wafer alignment using alignment marks on the backside of the die in accordance with an embodiment of the present invention;

FIG. 25 illustrates die-to-transfer-wafer alignment using an angled light source and a surface-normal incoming beam into the imaging assembly in accordance with an embodiment of the present invention;

FIG. 26 illustrates an exemplary top-down view of the variable pitch mechanism in accordance with an embodiment of the present invention;

FIG. 27 is a legend for materials in magnetic actuator drawings in accordance with an embodiment of the present invention;

FIG. 28 illustrates an exemplary semi-passive reluctance design for a cross-point puck in accordance with an embodiment of the present invention;

FIGS. 29A-29B illustrate an exemplary scenario when the cross-point puck (CPP) is displaced relative to the steel guide rails in accordance with an embodiment of the present invention;

FIGS. 30A-30B illustrate an exemplary scenario if the Lorentz coils cannot fit in the air gap in accordance with an embodiment of the present invention;

FIGS. 31A-31B illustrate an exemplary variation of the semi-passive design (FIGS. 30A-30B) without one of the rails in accordance with an embodiment of the present invention;

FIG. 32 illustrates an exemplary hybrid air bearing and magnetic actuation configuration in accordance with an embodiment of the present invention;

FIGS. 33A-33B illustrate an exemplary scenario when the rails are made of steel in accordance with an embodiment of the present invention;

FIGS. 34A-34D illustrate coil configurations for X, Y and θ_{z} actuation which takes advantage of the air bearing constraint in accordance with an embodiment of the present invention;

FIG. 35 illustrates an exemplary scenario in which placing optical sensors in the air gap between the CPP and the rails provides a feedback signal for measuring the relative position between them in accordance with an embodiment of the present invention;

FIG. 36 illustrates a fully passive design where the X-directed rails provide a Y stabilization and vice-versa in accordance with an embodiment of the present invention;

FIGS. 37A-37B illustrate an exemplary design of the CPP which utilizes easier-to-manufacture steel rails but maintains the same type of passive stiffness as magnetic rails in accordance with an embodiment of the present invention;

FIGS. 38A-38B illustrate an exemplary configuration of the CPP where AC-excited coils in the guide rails repel a diamagnetic CPP and stabilize it without the need for sensors or controllers in accordance with an embodiment of the present invention;

FIGS. 39A-39B illustrate an exemplary array of Halbach rails that creates a strong magnetic field above them in accordance with an embodiment of the present invention;

FIG. 40 illustrates an exemplary N×1 VPM in accordance with an embodiment of the present invention;

FIG. 41 illustrates an exemplary N×1 VPM with staggered movers across three sets of stators in accordance with an embodiment of the present invention;

FIGS. 42A-42B illustrate an exemplary monopolar electrostatic ACM in accordance with an embodiment of the present invention;

FIG. 43 illustrates an exemplary monopolar electrostatic ACM for picking up multiple dies using the same ACM in accordance with an embodiment of the present invention;

FIG. 44 is a flowchart of a method for fabricating an exemplary monopolar electrostatic ACM in accordance with an embodiment of the present invention;

FIGS. 45A-45E depict the cross-sectional views for fabricating an exemplary monopolar electrostatic ACM using the steps described in FIG. 44 in accordance with an embodiment of the present invention;

FIG. 46 illustrates an exemplary piezo stack configuration for the short-stroke stage in accordance with an embodiment of the present invention;

FIGS. 47A-47B illustrate an exemplary piezo inchworm actuator configuration in accordance with an embodiment of the present invention;

FIGS. 48A-48B illustrate an exemplary stage which exploits the Lorentz force between a current-carrying coil and a magnetic field to provide three degrees of freedom position control in accordance with an embodiment of the present invention;

FIG. 49 illustrates an exemplary alternative configuration of a stage that uses stator-mounted electromagnets to interact with permanent magnets on the mover in accordance with an embodiment of the present invention;

FIG. 50 illustrates exemplary magnet-biased reluctance actuators interacting with the steel portions of the mover to provide three degrees of freedom control in accordance with an embodiment of the present invention;

FIG. 51 illustrates an exemplary diagram demonstrating the force-producing mechanism of the magnet-biased actuator in accordance with an embodiment of the present invention;

FIG. 52 illustrates an exemplary flexure configuration in which series, orthogonal cantilevers provide compliance in the plane and stiffness perpendicular to the plane in accordance with an embodiment of the present invention;

FIG. 53 illustrates an alternative exemplary flexure configuration in which the series, orthogonal cantilevers in FIG. 52 are re-oriented and shrunk to provide room for actuation in accordance with an embodiment of the present invention;

FIGS. 54A-54C illustrate an exemplary out-of-plane flexure that allows for more access to the mover for actuation in accordance with an embodiment of the present invention;

FIG. 55 is a flowchart of a method for serial pickup, parallel placement in accordance with an embodiment of the present invention;

FIGS. 56A-56B depict the cross-sectional views for serial pickup, parallel placement using the steps described in FIG. 55 in accordance with an embodiment of the present invention;

FIGS. 57A-57B depict one configuration for turret-based pick and place in accordance with an embodiment of the present invention;

FIGS. 58A-58D depict a configuration for planar-motor-based pick and place in accordance with an embodiment of the present invention;

FIGS. 59A-59C illustrate a fan-out style nBH in accordance with an embodiment of the present invention;

FIG. 60A illustrates a method of preventing unwanted oscillations of the cantilever structure by placing a curable adhesive on the destination substrate to create a liquid interface between the die and the substrate in accordance with an embodiment of the present invention;

FIG. 60B illustrates inserting fluid between a rigid structural backplane and the backside of the chuck in accordance with an embodiment of the present invention;

FIGS. 61A-61B illustrate an exemplary single Universal Chucking Moule Bonding Head (UCM-BH) in accordance with an embodiment of the present invention;

FIG. 62 illustrates a gap between the UCM and the die in accordance with an embodiment of the present invention;

FIGS. 63A-63D depict various views of a leaky chuck design in accordance with an embodiment of the present invention;

FIGS. 64A-64E depict a grid of vacuum cells with connections in the back layer in accordance with an embodiment of the present invention;

FIGS. 65A-65D illustrate check valves and a moving vacuum source in accordance with an embodiment of the present invention;

FIGS. 66A-66E illustrate interchangeable vacuum masks in accordance with an embodiment of the present invention;

FIGS. 67A-67E illustrate a vacuum mask design which employs permanently attached masks of flexible material which are actuated to cover the desired number of rows and columns in accordance with an embodiment of the present invention;

FIGS. 68A-68B illustrates pin-actuated check valves in accordance with an embodiment of the present invention;

FIG. 69 illustrates a permanent chuck body with a temporary chucking area boundary attached to it using dispensable dielectrics in accordance with an embodiment of the present invention;

FIG. 70 illustrates a smart mesa design in accordance with an embodiment of the present invention;

FIGS. 71A-71B illustrate a single vacuum cell constructed using MEMS techniques in accordance with an embodiment of the present invention;

FIGS. 72A-72D illustrate the process flow for vacuum-cell pick-up using the smart mesa design in accordance with an embodiment of the present invention;

FIGS. 73A-73C illustrate an adhesive-enabled vacuum-cell-pickup design in accordance with an embodiment of the present invention;

FIGS. 74A-74C illustrate two implementations of a MEMS-scale valve in accordance with an embodiment of the present invention;

FIG. 75 illustrates a smart mesa design using high-CTE hollow pillars to connect vacuum cells to the chuck body in accordance with an embodiment of the present invention;

FIG. 76 illustrates a DMD-inspired smart mesa design in accordance with an embodiment of the present invention;

FIGS. 77A-77B illustrates a passive mesa design in accordance with an embodiment of the present invention; and

FIG. 78 illustrates an exemplary design for a curved UCM in accordance with an embodiment of the present invention.

### DETAILED DESCRIPTION

As stated in the Background section, unfortunately, there are currently limitations in such surface-mount technology component placement systems in picking and placing components on a target device, such as a printed circuit board. For example, such surface-mount technology component placement systems are expensive and the type of components to be mounted is limited. Furthermore, the speed of such surface-mount technology component placement systems is limited.

The principles of the present invention provide a means for picking and placing components on a target device, such as a printed circuit board, in a less expensive manner than prior surface-mount technology component placement systems. Furthermore, the tool of the present invention for pick-and-place assembly enables the type of components to be mounted to be less limiting. Additionally, the speed for such placement of the components on a target device is less limiting using the tool of the present invention.

The present application incorporates herein the following references in their entirety: U.S. Patent Application Publication No 2021/0350061 (“Nanofabrication and Design Techniques for 3D ICs and Configurable ASICs), U.S. Patent Application Publication No. 2021/0366771 (“Nanoscale-Aligned Three-Dimensional Stacked Integrated Circuit”) and U.S. Patent Application Publication No. 2021/0134640 (“Heterogeneous Integration of Components Onto Compact Devices Using Moiré Based Metrology and Vacuum Based Pick-and-Place”).

Prior to discussing the Figures, the following provides definitions for various terms used herein.

“SiP,” as used herein, refers to “system-in-package” where separately manufactured die are integrated into a higher-level assembly.

“Field,” as used herein, refers to individual die, or a small cluster of die collocated in the SiP.

“SPP,” as used herein, refers to SiP pitch on product-substrate (SPP) including SPPₓ and SPP_{y}.

“Transfer chuck (TC),” as used herein, refers to a system that is used to transfer fields and/or dies from one substrate to another while maintaining thermo-mechanical stability of said fields and/or dies.

“Variable pitch mechanism (VPM),” as used herein, refers to a sub-system of the transfer chuck, which can be used to change the pitch of the dies picked up by the transfer chuck prior to placement onto a transfer/product/intermediate substrate.

“Adaptive chucking module (ACM),” as used herein, refers to a sub-system of the transfer chuck, which can be used to securely hold dies of non-arbitrary and/or arbitrary lateral dimension (within pre-defined maximum and minimum lateral dimensions), in a thermo-mechanically stable manner. Furthermore, ACM and its auxiliary systems (such as the ACM receptacle), as well as one or more dies that are being held by an ACM, are referred to, interchangeably, as the ACM system, ACM assembly, ACM receptacle, and cross-point puck.

“Alignment,” is used herein interchangeably with the terms “overlay” and “placement.”

“Metrology microscope assembly,” as used herein, refers to a sub-system for measuring the alignment of dies with respect to a reference. This could consist of the metrology optics, imagers, and electronics.

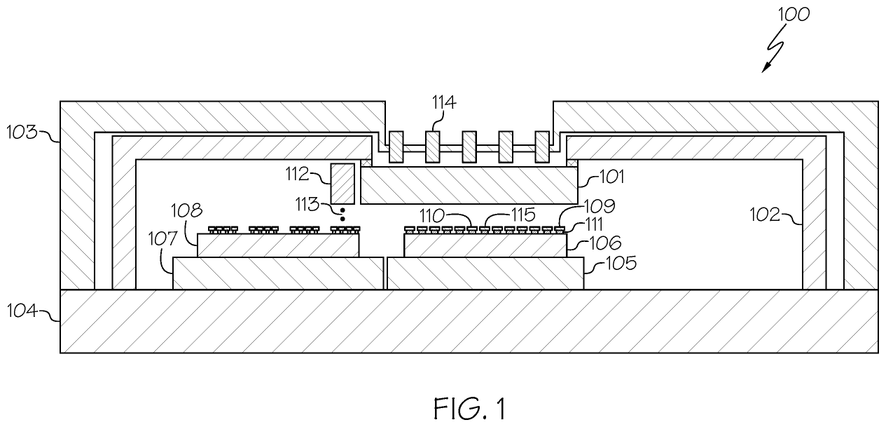

Referring now to FIG. 1, FIG. 1 illustrates an exemplary system 100 for pick-and-place assembly in accordance with an embodiment of the present invention.

As shown in FIG. 1, such a system 100 includes a transfer chuck (TC) 101 along with a transfer chuck (TC) frame 102. Furthermore, system 100 includes a stable metrology frame 103, where both frames 102, 103 are mounted on XY motion stage 104.

Furthermore, as shown in FIG. 1, source substrate chuck 105, which holds a source substrate 106, as well as transfer substrate chuck 107, which holds a transfer substrate 108, are placed on XY motion stage 104.

Additionally, as shown in FIG. 1, source substrate 106 includes good dies 109, bad dies 110 as well as die release adhesive 111. Furthermore, as shown in FIG. 1, system 100 may include an optional inkjet 112 for dispensing of adhesive 113, such as on transfer substrate 108.

Furthermore, system 100 may include optional alignment microscopes 114.

A further discussion regarding system 100 is provided below.

In one embodiment, system 100 contains TC 101 for picking up one or more dies 115, including good dies 109, from source substrate 106 and placing them onto transfer substrate 108. In one embodiment, TC 101 contains a variable pitch mechanism (VPM) for changing the pitch of dies 115 picked up from source substrate 106 prior to placing them onto transfer substrate 108. ACM assemblies, that are part of TC 101, could be used to avoid picking up known bad dies (KBDs) 110 by turning off the chucking force on the ACM that is intended for bad die 110.

In one embodiment, a set of alignment microscopes 114 are used to measure the alignment/placement precision of dies 115 during one or more of the die pickup and die placement steps. In one embodiment, source substrate 106 is held onto a thermo-mechanically stable substrate chuck 105. In one embodiment, substrate chuck 105 has optionally embedded addressable light sources to expose the die adhesive, such as die release adhesive 111. In one embodiment, the adhesive, such as die release adhesive 111, is a phase-change adhesive. In one embodiment, the light sources are composed of addressable arrays of ultraviolet (UV) light sources at the 365 nm wavelength and visible light sources at the 520 nm wavelength.

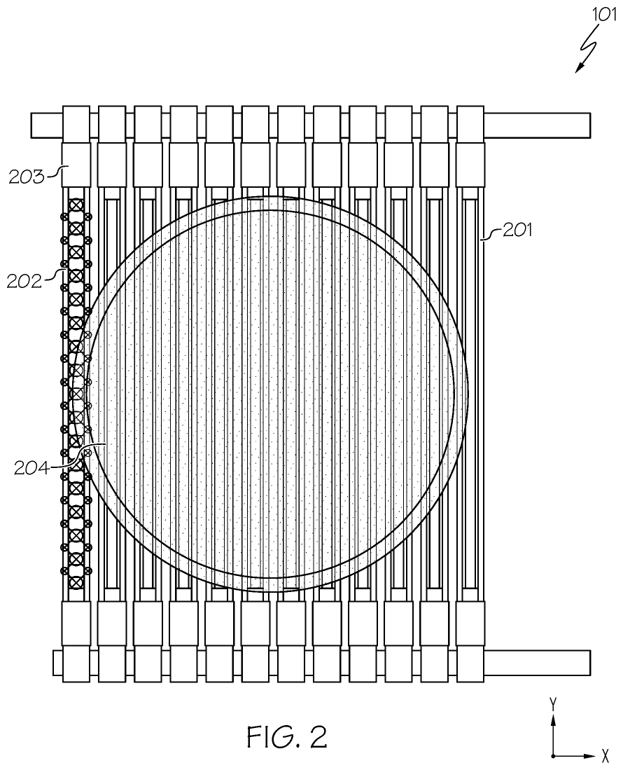

Referring now to FIG. 2, FIG. 2 illustrates a top view of an exemplary transfer chuck 101 in accordance with an embodiment of the present invention.

As shown in FIG. 2, transfer chuck 101 includes an array of adaptive chuck modules 201 (ACMs). Such ACMs 201 are moveable with respect to one another using a variable pitch mechanism (VPM). Furthermore, as shown in FIG. 2, transfer chuck 101 includes a fixed central ACM 202, which is not moveable as opposed to ACMs 201. Additionally, as shown in FIG. 2, transfer chuck 101 includes voice coil actuators 203 and a Z support plate 204 for ACMs 201, 202.

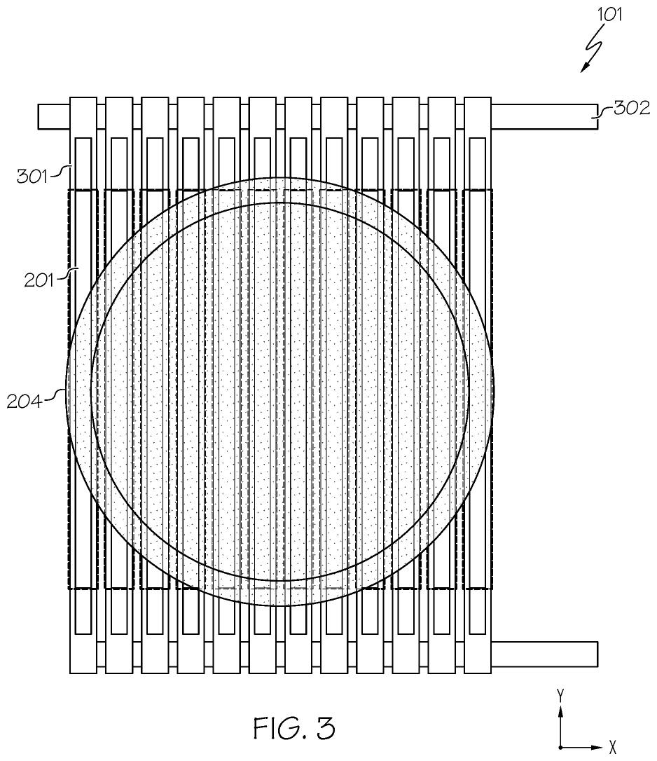

FIG. 3 illustrates another embodiment of the present invention of the top view of an exemplary transfer chuck 101 that includes an array of elongated ACMs 201 that are fixed to the Y rail 301. In one embodiment, the width of Y rail 301 is approximately 15 mm. Such ACMs 201 are moveable with respect to one another using a variable pitch mechanism (VPM). FIG. 3 also illustrates Z support plate 204 for ACMs 201. Additionally, FIG. 3 illustrates X rail 302.

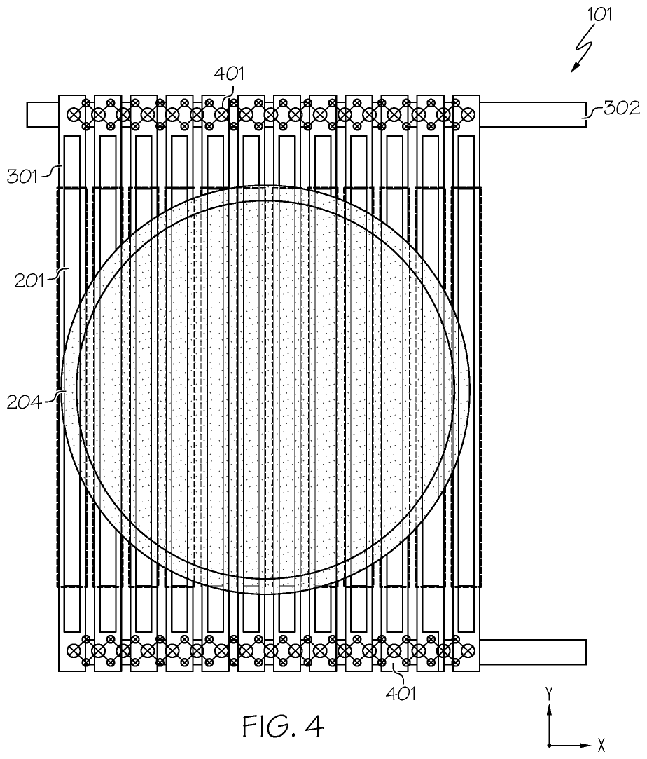

Referring now to FIG. 4, FIG. 4 illustrates a further embodiment of the present invention of the top view of an exemplary transfer chuck 101 with x direction flexure. As shown in FIG. 4, transfer chuck 101 includes an array of elongated ACMs 201 that are moveable with respect to one another using a variable pitch mechanism (VPM). Furthermore, FIG. 4 illustrates Z support plate 204 for ACMs 201. Additionally, FIG. 4 illustrates transfer chuck 101 with X direction flexure 401.

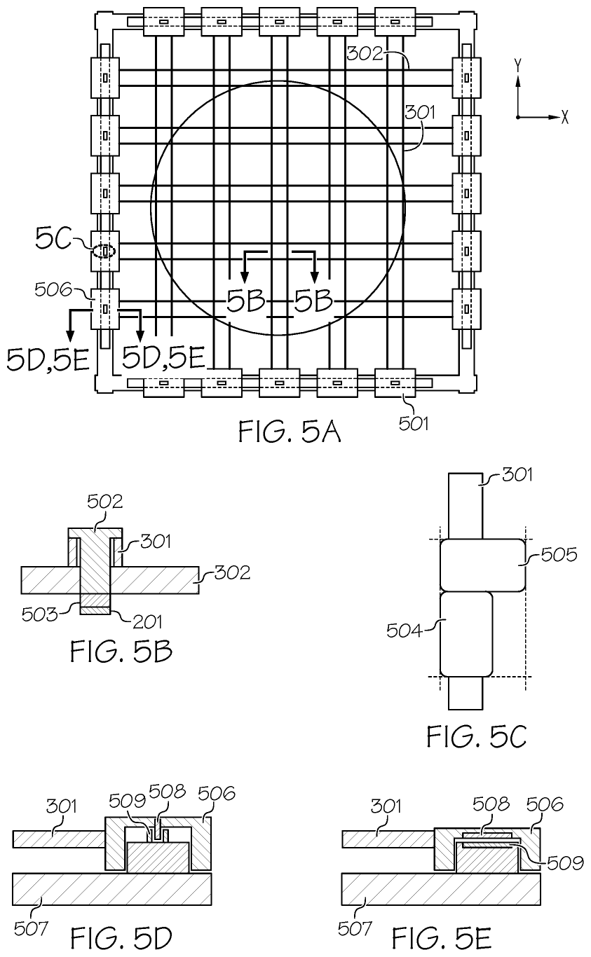

Referring now to FIGS. 5A-5E, FIGS. 5A-5E illustrate another exemplary transfer chuck 101 with an array of adaptive chuck modules (ACMs) 201 that are moveable with respect to one another using a variable pitch mechanism (VPM) in accordance with an embodiment of the present invention.

As shown in FIG. 5A, FIG. 5A illustrates the top view of transfer chuck 101 containing an X rail 302 and a Y rail 301. In one embodiment, the ends of Y rails 301 are supported on X rails 302 using air bearings 501.

FIG. 5B is expanded view of the cross-section of the ACM receptacle 502 in relation to Y rail 301 and X rail 302. Furthermore, FIG. 5B illustrates the short-stroke actuator assembly 503 on ACM 201.

FIG. 5C illustrates an exemplary 1D+ encoder heads (X encoder head 504 and Y encoder head 505) attached near the end of each Y rail 301 with an encoder strip (not shown) that lies above/below in accordance with an embodiment of the present invention.

FIGS. 5D and 5E are an expanded view of the cross-section of a variable pitch mechanism 506 across Y rail 301 in accordance with an embodiment of the present invention.

As shown in FIGS. 5D and 5E, VPMs 506 are placed across the surrounding Y rail 301 of transfer chuck 101 (referred to as “VPM Y rail”). In one embodiment, VPMs 506 are supported by granite base 507.

In one embodiment, VPM 506 includes a mover 508, such as a coil, as well as stator(s) 509, such as a permanent magnet. FIGS. 5D and 5E illustrate the different embodiments of VPMs 506 with different configurations of mover 508 and stator(s) 509.

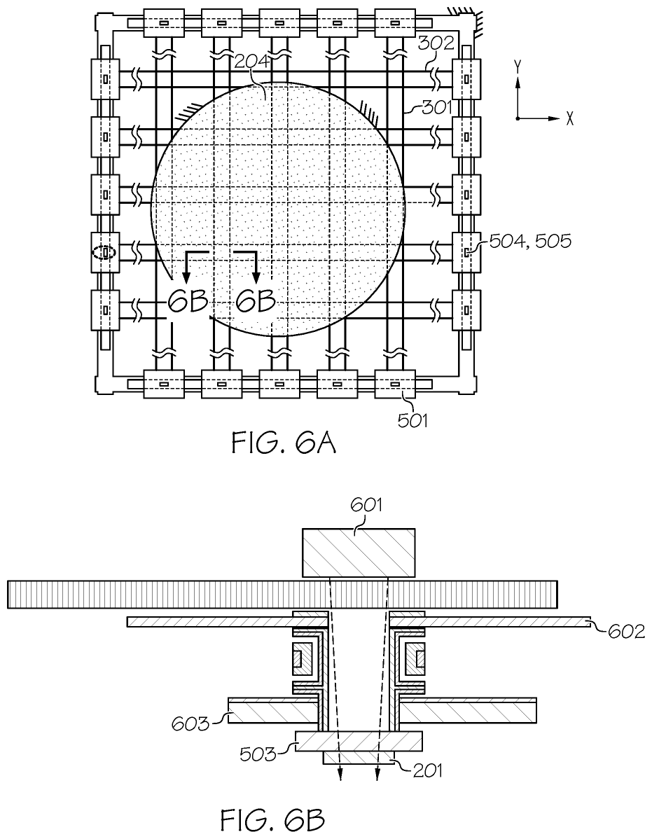

FIGS. 6A-6F illustrate an additional exemplary transfer chuck 101 with an array of adaptive chuck modules (ACMs) 201 that are moveable with respect to one another using a variable pitch mechanism (VPM) 506 in accordance with an embodiment of the present invention.

As shown in FIG. 6A, FIG. 6A illustrates the top view of transfer chuck 101 containing an X rail 302 and a Y rail 301. Furthermore, as shown in FIG. 6A, transfer chuck includes Z support plate 204 as well as exemplary 1D encoder heads 504, 505 attached near the end of each Y rail 301 with an encoder strip (not shown) that lies above them. Furthermore, as illustrated in FIG. 6A, the ends of Y rails 301 are supported on X rails 302 using air bearings 501.

FIG. 6B is an expanded view of the cross-section of the area below a portion of Z support plate 204 in accordance with an embodiment of the present invention.

As shown in FIG. 6B, support plate 204 physically isolates metrology module 601 from actuation. FIG. 6B further illustrates the short-stroke actuator assembly 503 on ACM 201 underneath support plate 204 along with umbilical 602 and thinner X/Y rails 302, 301 (identified by element 603).

FIGS. 6C and 6D illustrates clamping of ACM receptable 502 to the X and Y rails 302, 301 in accordance with an embodiment of the present invention. FIG. 6D is an expanded view of the cross-section of clamping ACM receptable 502 to X and Y rails 302, 301 as shown in FIG. 6C via the through hole 604 for alignment metrology.

As shown in FIG. 6D, FIG. 6D illustrates an exemplary 300 mm wafer and wafer chuck 605 upon which the ends (identified by element 606) of X/Y rails 302, 301 are supported on air bearings 501 or magnetic bearings and actuated using linear motors or a scissor mechanism. FIG. 6D also illustrates a second pair of rails 607, which are a reflection from the ground.

FIG. 6E is an expanded view of the cross-section of ACM receptacle 502. ACM receptacle 502 includes Lorentz actuators 608 (e.g., voice coils) used in magnetic bearings. Furthermore, ACM receptable 502 includes short-stroke XYθ stage 609, ACM 201 and die 115. A cross-section of XYθ stage 609 is shown in FIG. 6F.

As shown in FIG. 6F, short-stroke XYθ stage 609 includes a stationary frame 610 and flexure arms 611 through which a vacuum is routed to ACM 201. Additionally, FIG. 6F illustrates a pair of Lorentz actuators 608 and a single XY flexure 612 of the planar mechanism. Furthermore, FIG. 6F illustrates mover 508, which interfaces with ACM 201.

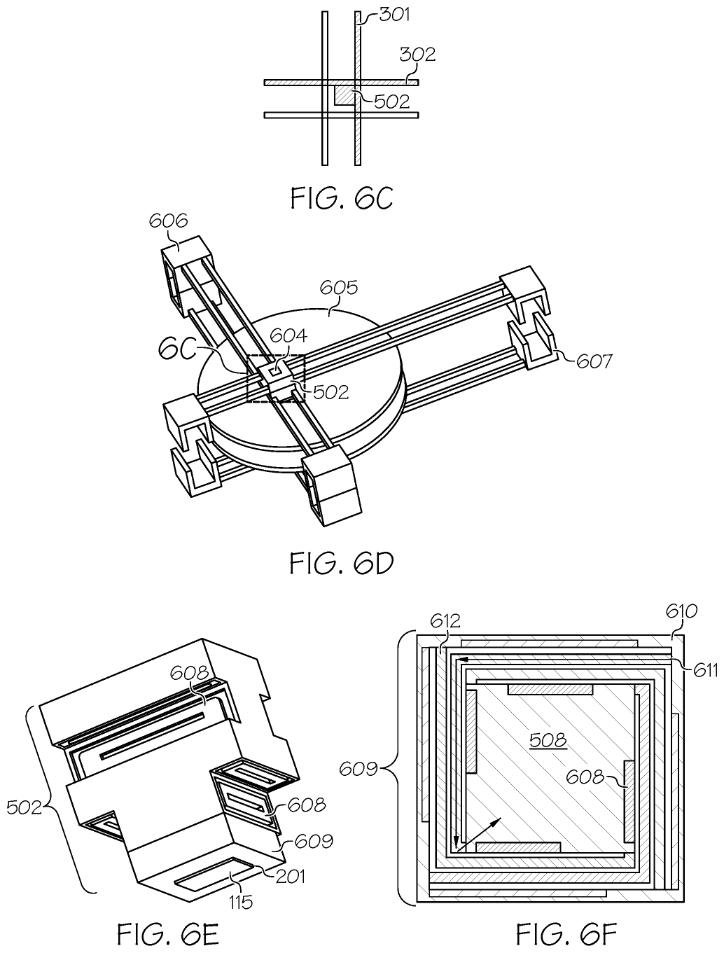

FIGS. 7A-7B illustrate an exemplary split transfer chuck design in accordance with an embodiment of the present invention. In particular, FIG. 7A illustrates a Y VPM 701 which picks up dies 115, adjusts their pitch in the Y direction and places them onto an intermediate substrate. FIG. 7B illustrates an X VPM 702 that picks up dies 115 from the intermediate substrate, adjusts their pitch in the X direction and places them onto the transfer substrate 108/product substrate.

Referring to FIG. 7A, FIG. 7A illustrates the fixed die pickup chucks 703.

Referring to FIG. 7B, FIG. 7B illustrates z support plate 204 along with the ACM assembly 704, which includes a short-stroke high-precision stage 609.

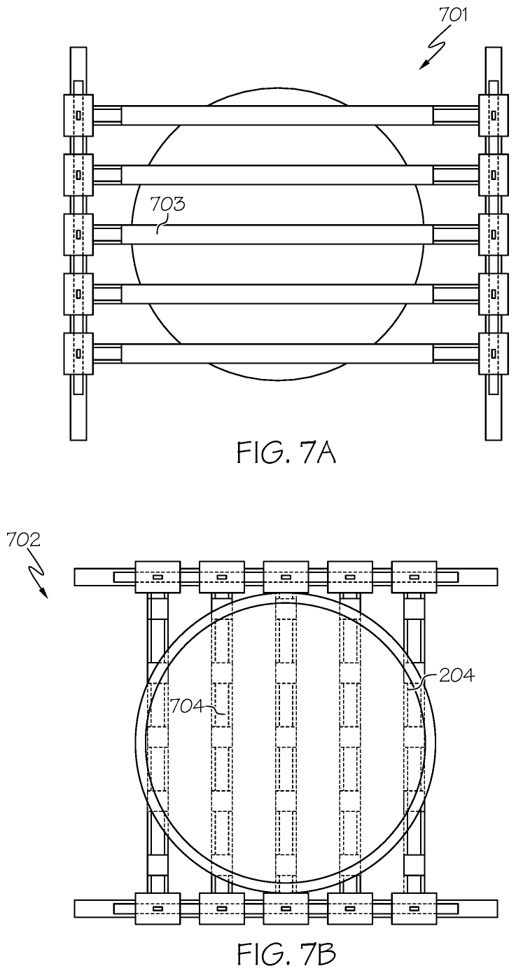

FIGS. 8A-8C illustrate an exemplary Z support plate 204 for enhanced stiffness for VPM 506 in accordance with an embodiment of the present invention.

As shown in FIG. 8A, FIG. 8A illustrates an exemplary Z support plate 204. FIG. 8B illustrates an expanded view of the cross-section of Z support plate 204 which illustrates viewing windows 801 and contact surface 802. In one embodiment, the distance between the same ends of adjacent viewing windows 801 is approximately 0.45 mm.

As shown in FIG. 8C, FIG. 8C illustrates the cross-section of the support substrate with windows 801 in scratch resistant coating 803.

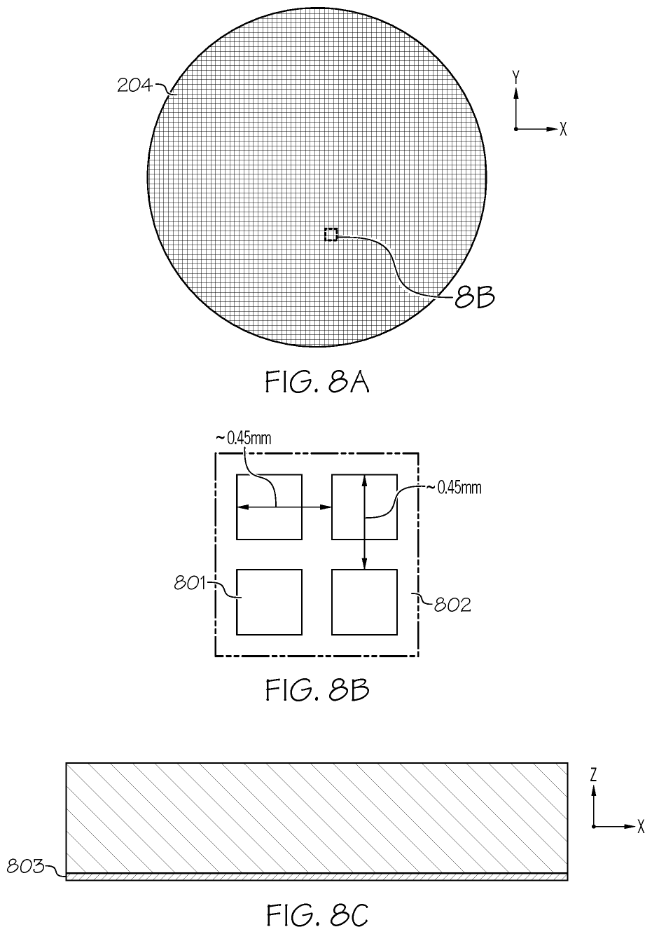

Referring now to FIG. 9, FIG. 9 illustrates an exemplary pick-and-place tool design 900 in accordance with an embodiment of the present invention.

As shown in FIG. 9, pick-and-place tool design 900 includes a transfer chuck (also referred to as “transfer wafer chuck”) 101 supporting a transfer wafer 901. Furthermore, FIG. 9 illustrates voice coil actuators 203 for tip-tilt-Z actuation. Additionally, FIG. 9 illustrates XY stage 104.

Furthermore, FIG. 9 illustrates a metrology frame 103 upon which metrology microscopes 902 are supported. Additionally, FIG. 9 illustrates transfer chuck frame 102 connected to VPM X/Y rails 903, such as VPM Y rails (see Y rail 301 of FIGS. 5D and 5E).

Additionally, FIG. 9 illustrates vibrationally-isolated kinematic mounts 904. In addition, FIG. 9 illustrates support plate 204 along with ACM assemblies 704.

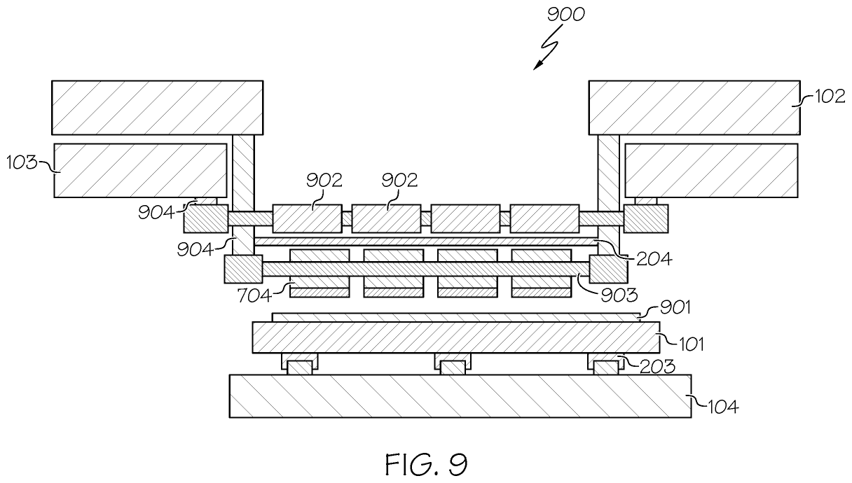

FIGS. 10A-10B illustrates an alternative exemplary pick-and-place tool design 1000 in accordance with an embodiment of the present invention.

As shown in FIG. 10A, pick-and-place tool design 1000 includes an assembly 1001 for up-looking metrology. Additionally, FIG. 10A illustrates z-actuation 1002 for TC 101 as well as microscopes 902 being in mechanically isolated shells 1003. Furthermore, as shown in FIG. 10A, tool frame 1004 is connected to z-actuation 1002.

Additionally, FIG. 10A illustrates vibrationally-isolated kinematic mounts 1005 to frame 103.

FIG. 10B illustrates a cross-section of an area surrounding mechanically isolated shells 1003 in which optics 1006 are located in the center within mechanically isolated shells 1003. Furthermore, as shown in FIG. 10B, such mechanically isolated shells 1003 are supported via grounding supports 1007.

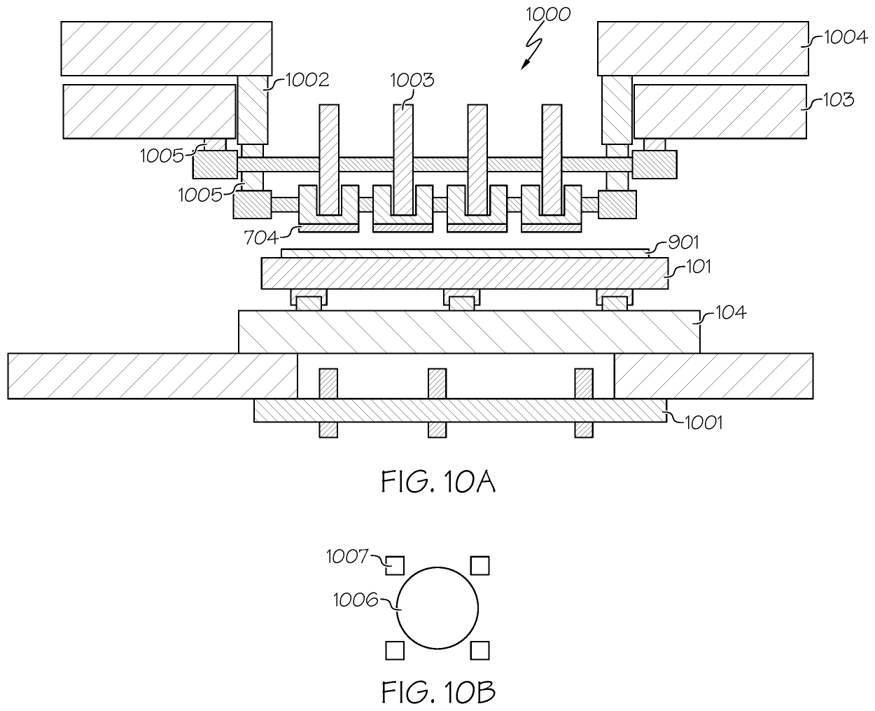

FIGS. 11A-11G illustrate an exemplary wiring architecture for ACMs 201 in accordance with an embodiment of the present invention.

As shown in FIG. 11A, FIG. 11A illustrates the scenario of one-by-one die 115 assembly in which maglev controllers and pneumatics 1101 are outside the assembly area containing ACM 201. In one embodiment, ACM 201 has the dimensions of 15 mm×15 mm.

As shown in FIG. 11B, FIG. 11B illustrates the scenario of a 4×4 multi die 115 assembly, where a cross-section of maglev controllers and pneumatics 1101 is shown in FIG. 11C.

As shown in FIG. 11C, maglev controllers and pneumatics 1101 include a vacuum (supply) line 1102, control connections (or lines) 1103, a pressure line 1104 and power lines 1105. In one embodiment, the horizontal distance across a maglev controller and pneumatic 1101 is approximately 4 mm. In one embodiment, the height of a maglev controller and pneumatic 1101 is approximately 8 mm.

FIG. 11D illustrates a 9×9 multi die 115 assembly, where an expanded version of such an assembly is shown in FIG. 11E.

As shown in FIG. 11E, wire spools 1106 (a cylinder or reel on which wire is wound) are used to wound wire that is used for ACMs 201. In one embodiment, ACMs 201 have the dimension of 15 mm×15 mm. An expanded view of the cross-section of ACM 201 is shown in FIG. 11F.

FIG. 11F illustrates the vacuum supply line 1102, power line 1105 and control line 1103. Additionally, FIG. 11F illustrates flexures 1107 in which cooling fluid 1108 is routed through flexure 1107. In one embodiment, the diameter of flexure 1107 is approximately 1 mm.

Additionally, FIG. 11F illustrates local control and power amplification circuitry 1109.

FIG. 11G illustrates the area beneath support plate 204 (cross-point puck assembly), which consists of a vacuum or magnetic bearing 1110, an umbilical array 602, a cooling grid 1111 as well as the rest of the cross-point puck assembly 1112.

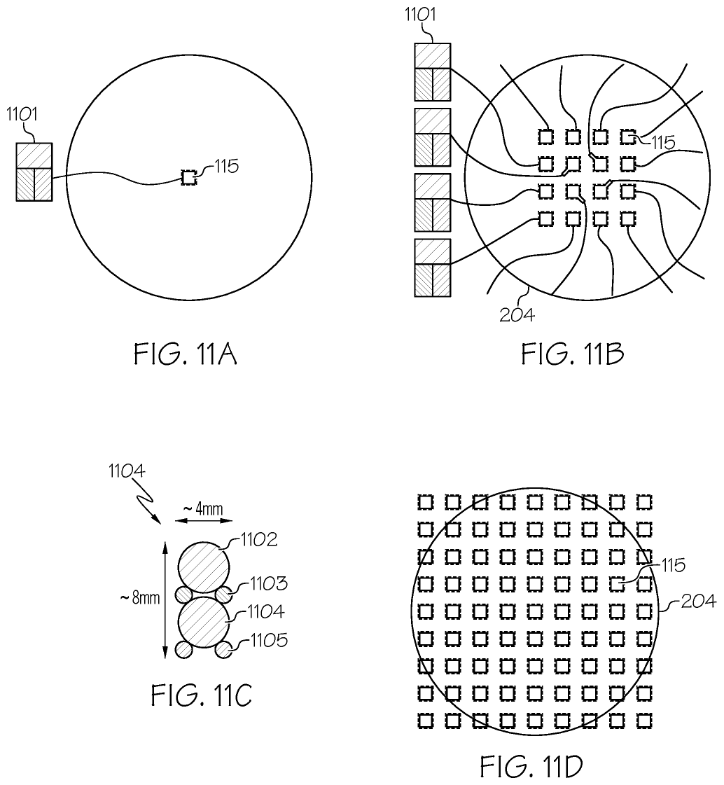

FIGS. 12A-12D illustrate an exemplary planar-motor-based TCs 101 in accordance with an embodiment of the present invention.

Referring to FIG. 12A, FIG. 12A illustrates an embodiment of the downward-facing TC 101. As shown in FIG. 12A, such a TC 101 includes a stator plate 1201 for the planar motors, mover sub-assemblies 1202 containing one or more ACMs 201, die 115, and an encoder plate 1203, which could be a separate component or be part of transfer substrate 108. Furthermore, FIG. 12A illustrates light beam 1204 from the displacement sensor.

FIG. 12B illustrates an alternative embodiment of the downward-facing TC 101 in which encoder plate 1203 is beneath stator 1201.

FIG. 12C illustrates an embodiment of the upward-facing TC 101, which is the reversal of the design shown in FIG. 12A.

FIG. 12D illustrates an alternative embodiment of the upward-facing TC 101, which is the reversal of the design shown in FIG. 12B.

The following discuses FIGS. 1-4, 5A-5E, 6A-6F, 7A-7B, 8A-8C, 9, 10A-10B, 11A-11G and 12A-12D.

In one embodiment, transfer chuck 101 is composed of an array of adaptive chucking modules (ACMs) 201, each of which can be used to pick and place one or more fields from/to one or more of the source substrate 106/intermediate substrate/transfer substrate 108/product substrate. Prior to die placement onto transfer substrate 108/intermediate substrate/product substrate, ACM assemblies 704 are clamped onto a support plate, such as support plate 204, to constrain spurious displacement of ACM assemblies 704 during die placement. In one embodiment, support plate 204 is composed of a material that is transparent in UV, visible, and/or IR wavelengths. In one embodiment, support plate 204 is composed of glass, display glass, fused silica, sapphire, and/or silicon carbide. In one embodiment, one or more of the faces of support plate 204 are coated with a scratch resistant hard layer, such as scratch resistant coating 803 (for instance, SiC, SiN, sapphire). The scratch resistant layer could have windows, such as windows 801 to permit through-support-plate metrology. In one embodiment, ACMs 201 clamp onto support plate 204 using vacuum suction, electrostatic forces, and/or magnetic forces. In one embodiment, support plate 204 is composed of a metal or a metal alloy (for instance stainless steel, aluminum, invar), polymer, ceramic, etc. or a combination thereof. In one embodiment, support plate 204 contains through-holes/windows 801 to enable metrology. In one embodiment, windows 801 for metrology have tapered walls to reduce shadowing due to the height of the walls. In one embodiment, the lateral size of windows 801 is at most one-third of the field-of-view (FOV) of the metrology system. A metrology calibration could be performed prior to loading of a new support plate in order to compensate for the thickness variations in support plate 204. In an exemplary calibration procedure, a reference set of alignment marks on a thermally stable substrate could be observed using the metrology assembly through the newly loaded support plate.

In one embodiment, VPM 506 consists of X and Y rails 302, 301 that are arranged orthogonally to one another. In one embodiment, X and Y rails 302, 301 reside in planes with different heights. In one embodiment, X and Y rails 302, 301 are independently actuatable. In one embodiment, ACM assemblies 704 lie at the intersection of pairs of X and Y rails 302, 301. In one embodiment, ACM assemblies 704 move with respect to X rails 302 freely in the Y direction, while being constrained to move with X rail 302 in the X direction. In one embodiment, ACM assemblies 704 move with respect to Y rails 301 freely in the X direction, while being constrained to move with Y rail 301 in the Y direction. In one embodiment, ACM assemblies 704 are connected to the X and Y rails 302, 301, using one or more of several contact or non-contact methods: air-bearings, magnetic bearings, roller bearings (for instance, ultra-clean roller bearings), etc. In one embodiment, one or more surfaces of ACM assemblies 704 and the X/Y rails 302/301 are polished to create low-roughness surfaces for the bearings. In one embodiment, ACM assemblies 704 and/or the X/Y rails 302/301 contain embedded permanent magnets and/or electromagnets to create repulsive force for non-contact actuation of ACMs 201 with respect to X/Y rails 302/301. In one embodiment, ACM assemblies 704 and/or X/Y rails 302/301 contain routing for cooling fluids 1108 to circulate and remove excess heat generated during actuation. In one embodiment, X/Y rails 302/301 are composed of metals, metal alloys, polymers and/or ceramics (such as, e.g., porous SiC, SiN, non-porous SiC). In one embodiment, X/Y rails 302/301 are used to clamp the ACM receptacles 502 to increase the stiffness of the VPM super-structure.

In the general case, there could exist a set of parallel lines (e.g., lines 1102, 1103, 1105), and a second set of parallel lines (e.g., lines 1102, 1103, 1105), where the first set of lines are non-parallel to the second set of lines, where the lines intersect at an array of cross-points, in the vicinity of which one or more items (for instance, metrology microscopes 902, ACMs 201, dies 115, etc.) can be held, and where the mechanism allows relative motion between cross-points (and associated items) that lie on a first line in the first set and cross-points (and associated items) that lie on a second line in the first set as well as relative motion between cross-points (and associated items) that lie on a first line in the second set and cross-points (and associated items) that lie on a second line in the second set.

In one embodiment, microscopes for metrology (e.g., microscopes 902), prior to die placement onto transfer substrate 108/intermediate substrate/product substrate, are moved into recesses inside ACM assemblies 704, such that prior to die placement, the working distance of the microscopes from the transfer substrate 108/intermediate substrate/product substrate is low as shown in FIGS. 10A-10B. In one embodiment, microscopes 902 are composed of an inner imaging assembly which is mechanically isolated from an outer shell 1003 (onto which the ACM assemblies 704 could clamp for mechanical stability). In one embodiment, the imaging optics, such as optics 1006, are part of the outer shell 1003, whereas, the imager could be part of a mechanically isolated inner frame. In one embodiment, metrology module 601 utilizes and is designed for UV light.

In one embodiment, the pitch of metrology microscopes 902 is changed using a variable pitch mechanism 506.

In one embodiment, die placement metrology is conducted, in an in-situ (on-axis) or off-axis manner, using upward looking microscopes. The upward looking microscopes could utilize moiré metrology for die placement measurement.

In one embodiment, one or more control signals, electrical power, vacuum and pressure supply, and fluidic cooling are provided to each ACM 201 using a group of wiring harnesses, such as via vacuum supply lines 1102, power lines 1105, control lines 1103, etc. In one embodiment, the wiring harnesses are integrated into a planar micro-machined structure. In one embodiment, the micro-machined structure is monolithically constructed (using for instance, a combination of macro-machining, and micro-machining techniques, such as photolithography, etching, planarization, etc.). In one embodiment, the planar structure is composed of silicon, plastic (e.g., ball grid array (BGA) substrate), metal, alloys, metal-core-with-plastic-cladding, and/or metal-and-silicon bilayer. In one embodiment, the expansion and/or contraction of the wiring harness is enabled by a set of actuation sources attached at the end of each X/Y rail 302/301. In one embodiment, the expansion and/or contraction is created using a set of wires that are connected to the wiring harness structure near its edges. In one embodiment, the expansion and/or contraction of the wiring harness is synchronized with the expansion and/or contraction of ACM assemblies 704.

In one embodiment, TC 101 consists of a VPM 506 that is composed of an array of planar motors. Movers 508 and the stators 509 of the planar motor could be composed of permanent magnets and/or electromagnets. In one embodiment, movers 508 are attached to ACMs 201 which are used to attach to dies 115. In one embodiment, movers 508 contain embedded displacement sensors. In one embodiment, metrology could be integrated from the transfer substrate side of the planar-motor-based TC (for instance, a set of up-looking microscopes placed underneath transfer substrate 108 and/or the encoder plate 1203 as shown in FIG. 12A. In one embodiment, the metrology is performed in an off-axis or on-axis manner, and in-situ or ex-situ manner. In one embodiment, the metrology utilizes moiré alignment metrology.

In one embodiment, TC 101 is compliant in the Z direction, and the pick-and-place process utilizes ultra-flat source substrate 106/transfer substrate 108/intermediate substrate/product substrate that are held onto substrate chucks that are stiff in the Z direction to provide flat references for dies 115 being picked and placed. In one embodiment, source substrate 106 is an ultra-flat 300 mm glass substrate.

In one embodiment, short-stroke actuators 503 (or “short-stroke actuator assemblies”) are used to achieve fine motion of ACMs 201 with respect to VPM 506. In one embodiment, short-stroke actuators 503 are composed of a planar flexure mechanism. In one embodiment, short-stroke actuators 503 utilize piezoelectric, electromagnetic, and/or fluidic actuation methods, to actuate a mover, such as mover 508 with respect to a stator 509. In one embodiment, stator 509 of short-stroke actuators 503 is connected to ACM receptacle 502. In one embodiment, short-stroke actuators 503 utilize light-based methods (e.g., laser encoders, laser confocal sensors, moiré metrology, etc.), and/or electronic methods (e.g., capacitive sensors, magnetic sensors), and/or mechanical methods (e.g., pressure gages, ultrasonic sensors, accelerometers, etc.) to measure the relative displacement of mover 508 with respect to stator 509.

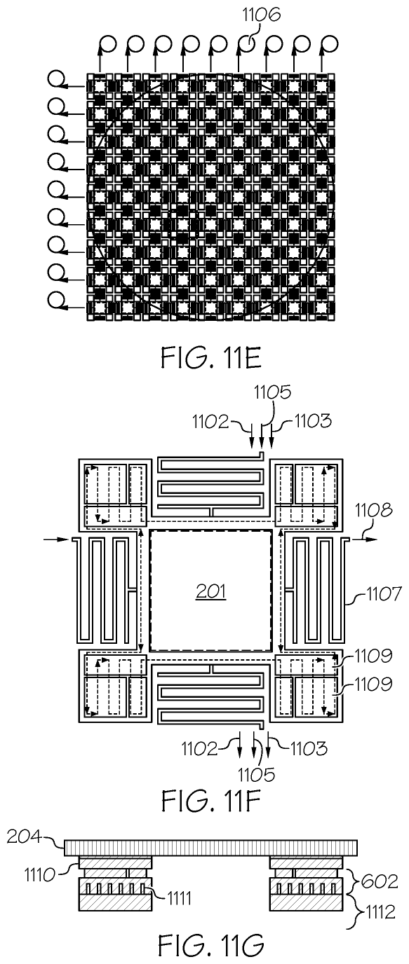

FIG. 13 illustrates an exemplary process for die placement in accordance with an embodiment of the present invention. Referring to FIG. 13, ACM 201 is deflected as illustrated by deflecting ACM 201. When ACM 201 is deflected, such as illustrated in FIG. 13, air bearing 1301 is created on the periphery.

Furthermore, FIG. 13 illustrates die 115 on transfer substrate (also referred to as “transfer wafer”) 108 currently being placed or adjusted. Additionally, FIG. 13 illustrates adhesive 1302 being dispensed near the center of dies 115 as well as illustrates adhesive 1303 with optimized shrink upon curing.

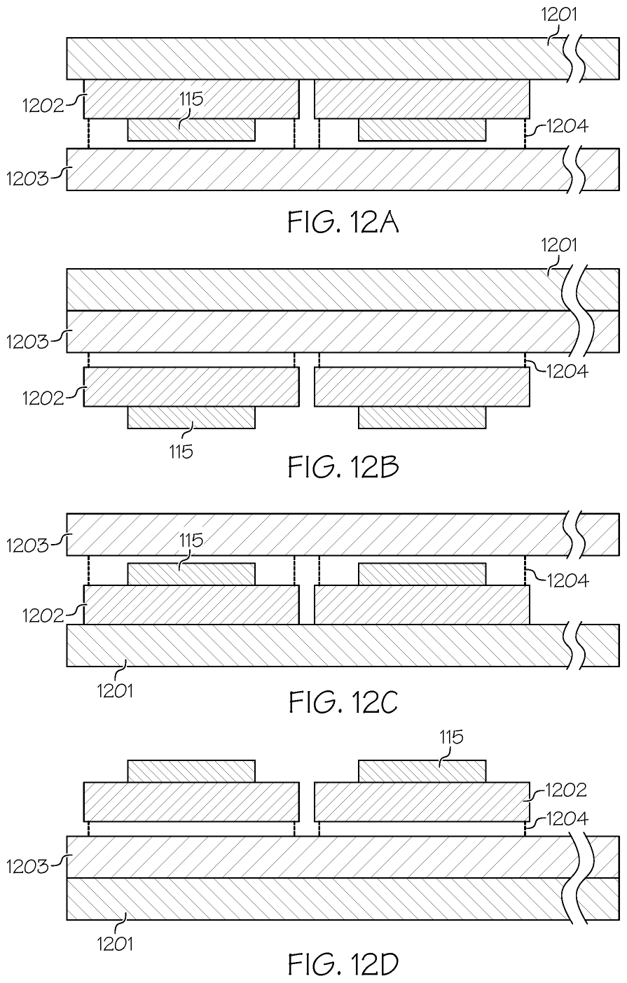

Referring now to FIG. 14, FIG. 14 is a cross-section of an exemplary adaptive chucking module (ACM) 201 in accordance with an embodiment of the present invention.

In particular, FIG. 14 illustrates the valve and pin parts of ACM 201. As shown in FIG. 14, FIG. 14 illustrates a die 115, an ACM pin 1401 as well as a pressure manifold 1402. Furthermore, FIG. 14 illustrates exemplary connections 1403 to thin film transistors (“TFT”).

Additionally, as shown in FIG. 14, ACM 201 includes a fixed electrode 1404 and a moving electrode 1405 on a polysilicon membrane 1406. Furthermore, ACM 201 includes a dual seal 1407 and a vacuum inlet 1408 underneath polysilicon membrane 1406 and above vacuum manifold 1409.

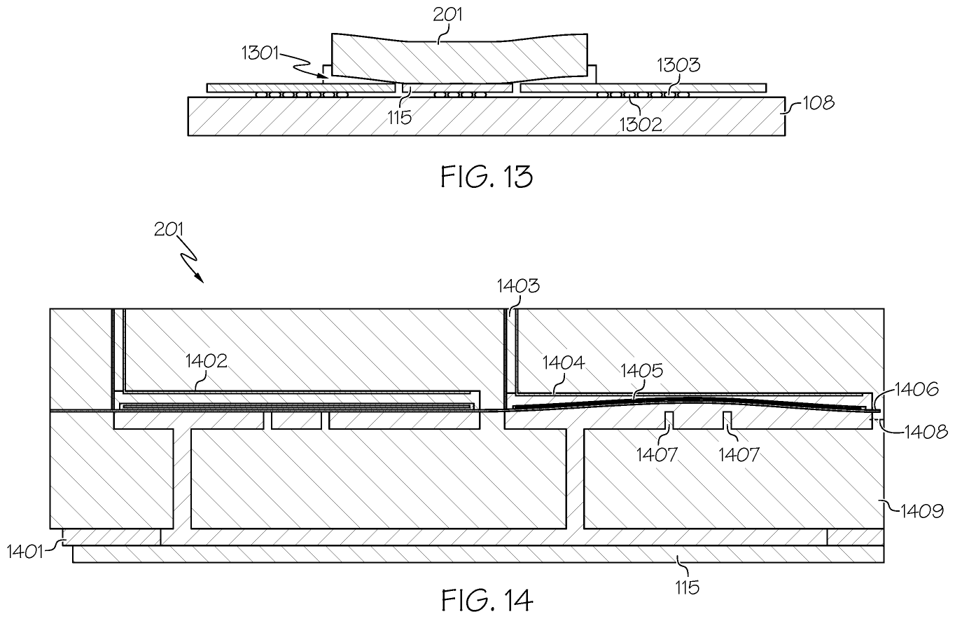

FIGS. 15A-15B illustrate an exemplary adaptive chucking module (ACM) 201 with viewing windows for metrology in accordance with an embodiment of the present invention.

As shown in FIG. 15A, which is a cross-section of ACM 201, a die 115 is dispensed between two ACM pins 1401.

FIG. 15B illustrates a top-view of ACM 201 which includes viewing window 801 and contact surface 802.

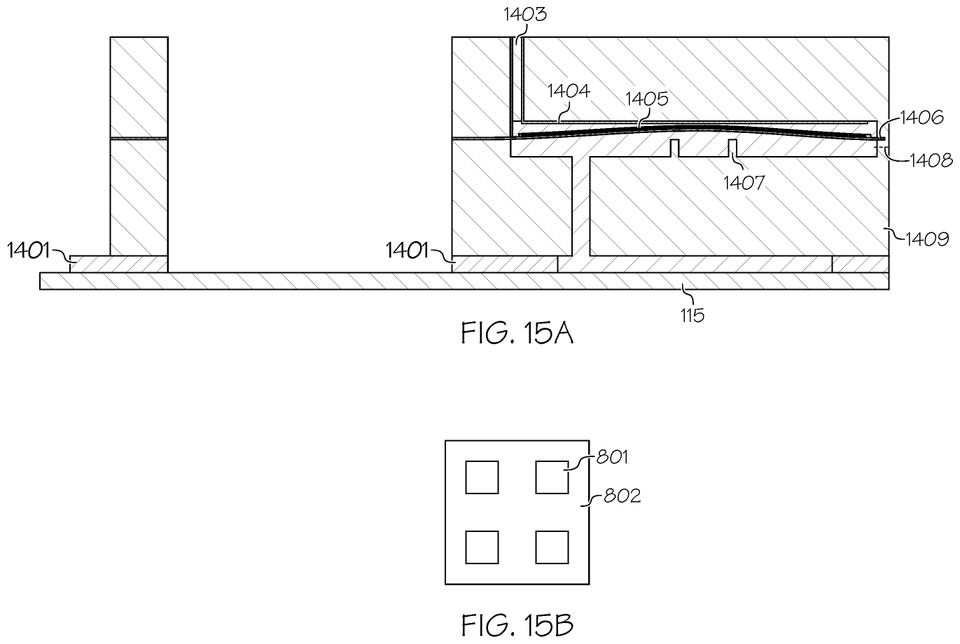

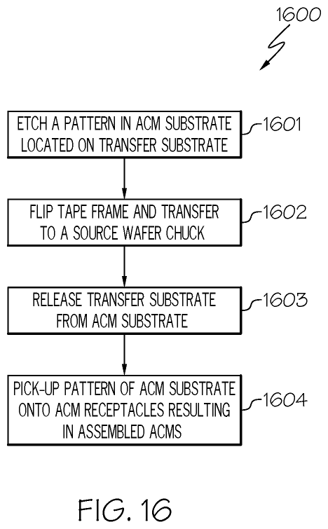

**NOT SURE THIS IS DESCRIBED CORRECTLY** FIG. 16 is a flowchart of a method 1600 for fabricating adaptive chucking modules 201 in accordance with an embodiment of the present invention. FIGS. 17A-17G depict the cross-sectional views for fabricating adaptive chucking modules 201 using the steps described in FIG. 16 in accordance with an embodiment of the present invention;

Referring to FIG. 16, in conjunction with FIGS. 17A-17G, in step 1601, a pattern 1701 is etched in ACM substrate 1702 located on transfer substrate 108, which is supported by tape frame 1703 as shown in FIGS. 17A-17B. In one embodiment, such a pattern 1701 is performed via deep reactive-ion etching. It is noted that element 1701, as used herein, is used to identify the entire pattern etched in ACM substrate 1702 or a particular segment or portion of the pattern etched in ACM substrate 1702. In one embodiment, ACM substrate 1702 is made from silicon. FIG. 17C illustrates a cross-section view of a portion of patterned ACM substrate 1702, which illustrates a portion of pattern 1701 formed in ACM substrate 1702.

In step 1602, tape frame 1703 is flipped and transferred to a source wafer chuck 105 (also referred to as a “source substrate chuck”), such as via electrostatic force as shown in FIG. 17D.

In step 1603, transfer substrate 108 is released from ACM substrate 1702 as shown in FIGS. 17D and 17E. In one embodiment, transfer substrate 108 is released via ACM release points 1704, which are required at specific locations in order to have a checkerboard-type pick-and-place.

In step 1604, pattern 1701 of ACM substrate 1702 is picked-up onto ACM receptacles 502 on Y-rail 301 of VPM 506 as shown in FIGS. 17E and 17F, resulting in assembled ACMs 201 on transfer chuck 101 as shown in FIG. 17F. Such assembled ACMs 201 include ACM receptables 502 assembled on Y-rail 301 of VPM 506, in which pattern 1701 is attached to ACM receptacles 502. A cross-section of a portion of the assembled ACMs 201 is shown in FIG. 17G.

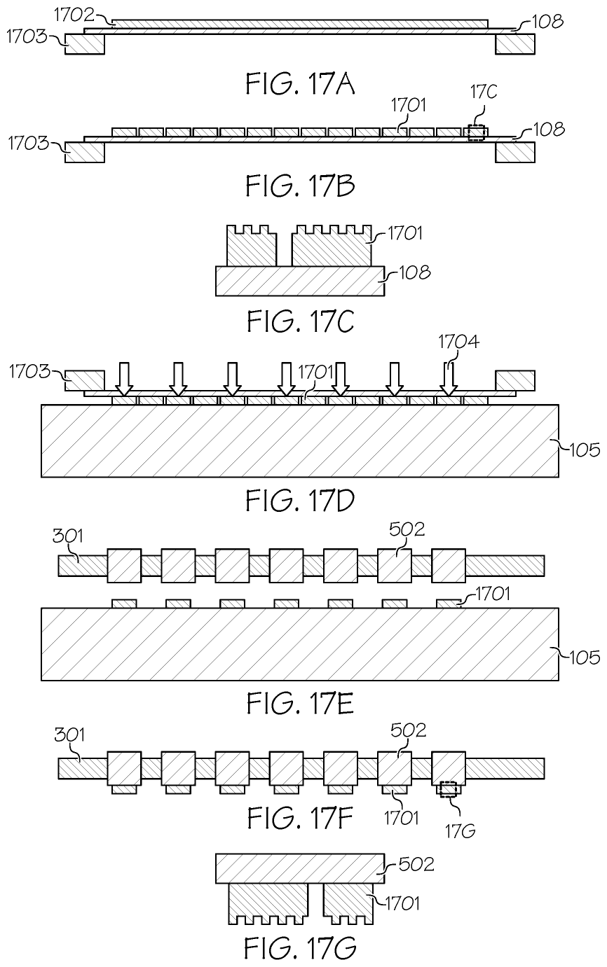

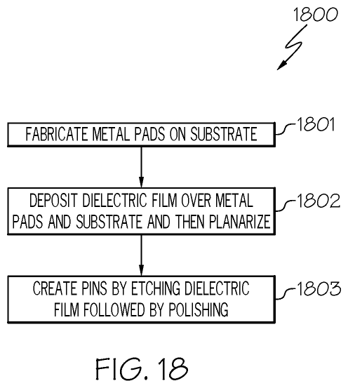

FIG. 18 is a flowchart of a method 1800 for fabricating adaptive chucking modules 201 that utilize electrostatic chucking in accordance with an embodiment of the present invention. FIGS. 19A-19C depict the cross-sectional views for fabricating adaptive chucking modules 201 that utilize electrostatic chucking using the steps described in FIG. 18 in accordance with an embodiment of the present invention.

Referring to FIG. 18, in conjunction with FIGS. 19A-19C, in step 1801, metal pads 1901 are fabricated on substrate 1902 as shown in FIG. 19A. In one embodiment, substrate 1902 includes bulk silicon, glass, sapphire, polymer and/or a substrate with a thin film transistor (TFT) array. In the embodiment in which substrate 1902 corresponds to a substrate with a thin film transistor array, connections are fabricated to the underlying TFT array in case substrate 1902 is utilized.

In step 1802, dielectric film 1903 is deposited over metal pads 1901 and substrate 1902 and then planarized as shown in FIG. 19B. Deposition may be performed using various deposition techniques, such as chemical vapor deposition, physical vapor deposition, atomic layer deposition, etc. Furthermore, planarization may be performed using various planarization techniques, such as chemical mechanical planarization, spin-etch planarization, etc.

In step 1803, pins 1904, such as pins 1401 of FIG. 14, are created by etching dielectric film 1903 as shown in FIG. 19C. The final structure as shown in FIG. 19C illustrates an ACM with electrostatic chucking (facing upwards). In one embodiment, etching may be performed using various etching techniques, such as reactive-ion etching, plasma etching, wet etching, atomic layer etching, etc. Furthermore, in one embodiment, pins 1904 are polished to smooth its surface, such as via chemical-mechanical planarization.

Referring to FIGS. 13-14, 15A-15B, 16, 17A-17G, 18 and 19A-19C, ACMs 201 may be composed of an array of valve units. In one embodiment, an electrostatic actuation mechanism is utilized to actuate the valves. In one embodiment, a seal, such as seal 1407, consisting of one or more chambers is utilized to isolate vacuum inlet 1408 from the outlet. In one embodiment, the air volume contained inside the seal, such as seal 1407, consisting of one or more chambers is used to cushion the impact of the membrane as it closes the valve. The valve units could be utilized to create vacuum and/or pressure on a die 115. Vacuum could be used to clamp a die 115 to ACM 201 in a pre-determined area. Furthermore, pressure could be used to deflect ACM 201 around the periphery of die 115 to prevent interference of ACM 201 with neighboring dies 115. Additionally, in one embodiment, ACM 201 is deflected (see deflecting ACM 201 in FIG. 13) by pressuring the side of ACM 201 that is opposite to die 115. The deflection of ACM 201 (see deflecting ACM 201 in FIG. 13) could be specified in such a manner that dies 115 of variable lateral dimension could be picked-and-placed using ACM 201 while preventing ACM interference with neighboring dies 115. In one embodiment, an adhesive with a specified shrinkage (upon curing), such as adhesive 1303, is utilized to prevent ACM interference with neighboring dies 115.

In one embodiment, ACM 201 is composed of an array of addressable units that chuck a die 115 based on the principles of electrostatic chucking. In one embodiment, ACM 201 is composed of a combination of pneumatic valve units and electrostatic chucking units. In one embodiment, ACM 201 is composed of one or more pneumatic valve units arranged in concentric rings around a central portion that is composed of electrostatic chucking units.

In one embodiment, ACMs 201 are custom fabricated for a specific die 115. Such ACMs 201 could be loaded onto VPM 506 at the start of the assembly of the relevant die 115. In one embodiment, all dies 115 of one type could be assembled onto a pre-specified set of product substrates before changing over to the next set of dies 115 and ACMs 201.

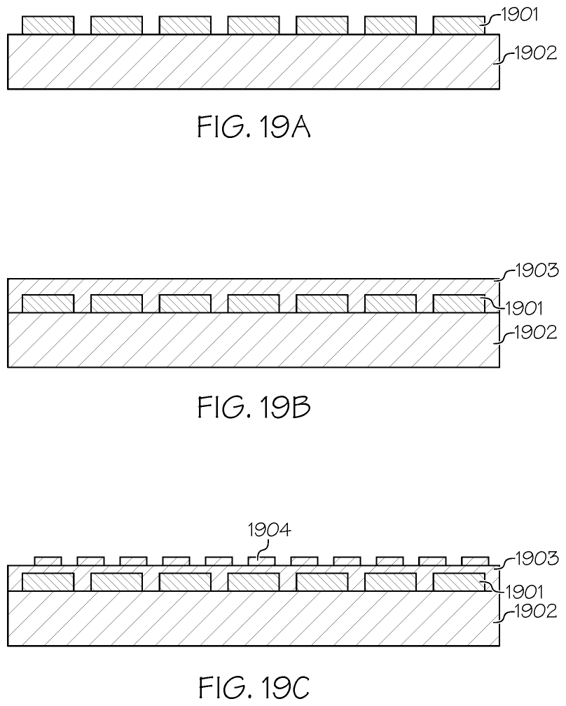

FIG. 20 illustrates a method for pick-and-place assembly in accordance with an embodiment of the present invention.

Referring to FIG. 20, FIG. 20 illustrates source substrate 106 (e.g., system-on-a-chip (SoC)) containing known bad dies 110. In one embodiment, dies, such as die 2001, near the edge of source substrate 106 may be left unused. These could potentially be recovered later.

In one embodiment, a high-precision multi-die pick-and-place using TC 101 could be used to populate transfer wafer 108 from source wafers 106 and buffer wafers 2002. In one embodiment, low-precision high-speed die-by-die assembly could be performed to repopulate buffer wafer 2002.

FIG. 20 further illustrates buffer wafer 2002 for multi-die replacement of known bad dies 110. In one embodiment, a separate buffer wafer 2002 is used for filling unpicked edge regions. In one embodiment, the depleted spots 2003 on buffer wafer 2002 may be replenished using a low-precision high-speed die-by-die assembler.

FIG. 20 additionally illustrates transfer wafer 108 being populated from source wafers 106 and buffer wafers 2002.

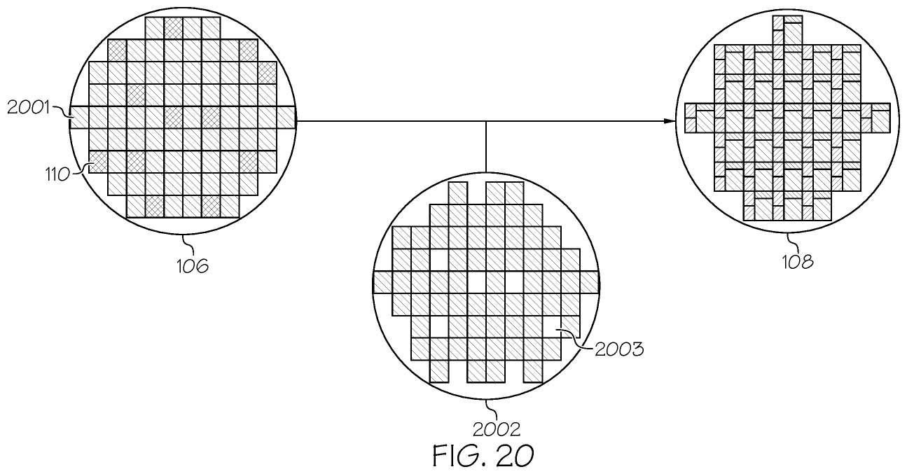

FIGS. 21A-21B illustrate an alternative method for pick-and-place assembly in accordance with an embodiment of the present invention.

Referring to FIG. 21A, FIG. 21A illustrates source substrate 106 (e.g., system-on-a-chip (SoC)) containing known bad dies 110.

In one embodiment, using a low-precision high-speed die-by-die assembly 2101, dies 115, including known good dies 109, from source substrate 106 are assembled onto transfer wafer 108′ as shown in FIG. 21A. As a result, transfer wafer 108′ includes dies 115 assembled in a low-precision manner.

An expanded view of dies 115 on transfer wafer 108′ is shown in FIG. 21B. Referring to FIG. 21B, FIG. 21B illustrates die 2102A (“Die A”) and die 2102B (“Die B”) fixed on transfer wafer 108′ via adhesive 2103, such as an ultraviolet (“UV”)-curable adhesive and/or a switchable adhesive. Furthermore, FIG. 21B illustrates optional mesas 2104 in transfer wafer 108′ for die self-assembly.

Returning to FIG. 21A, FIG. 21A illustrates a step 2105 for performing die placement metrology in an off-axis (ex-situ) manner if a switchable adhesive 2103 is utilized or, alternatively, performing die placement metrology in an on-axis (in-situ) manner if a non-switchable adhesive 2103 is utilized.

Furthermore, as shown in FIG. 21A, in-liquid die placement correction 2106 may be performed using short-stroke actuators, such as short-stroke actuators 503, and curing of adhesive 2103, thereby resulting in transfer wafer 108″ with dies assembled in a high-precision manner as shown in FIG. 21A.

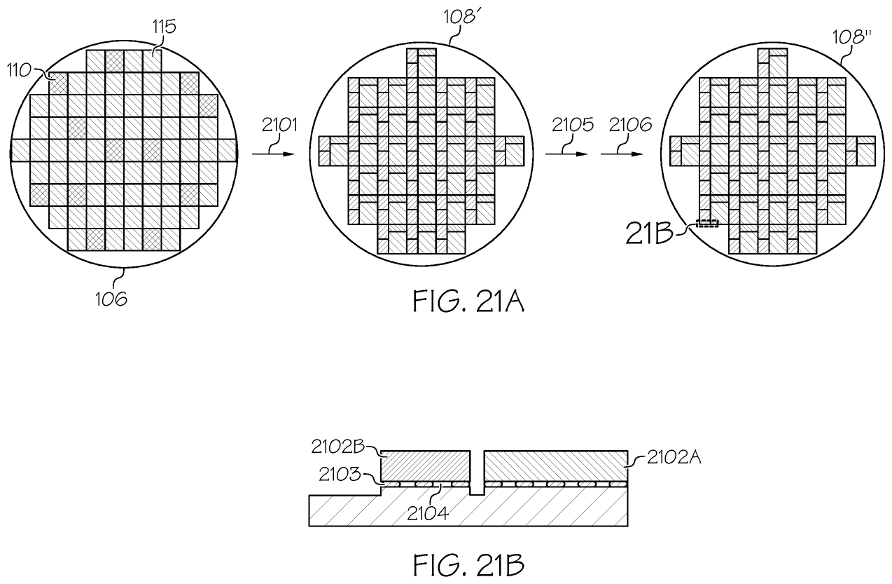

FIGS. 22A-22C illustrate front-to-back alignment of alignment marks placed on the backside of dies 115 in accordance with an embodiment of the present invention.

Referring to FIG. 22A, FIG. 22A illustrates die 115 prior to slicing, which includes top-side peripheral alignment marks 2201, bottom-side peripheral alignment marks 2202, circuit elements 2203 and the bottom-side main alignment marks 2204.

In one embodiment, the X/Y distance 2205 between the bottom-side main alignment marks 2204 is smaller than the smallest X and Y lateral dimension for all dies 115 on the transfer substrate 108/intermediate substrate/product substrate as shown in FIG. 22B.

In one embodiment, the position of the top and bottom peripheral marks 2201, 2202 with respect to circuit elements 2203 and main alignment marks 2204 is known by design. Thus, the alignment between circuit elements 2203 and bottom-side main alignment marks 2204 may be obtained by measuring the alignment between peripheral marks 2201, 2202 prior to dicing. In one embodiment, peripheral marks 2201, 2202 may be diced out post-measurement.

Referring to FIG. 22C, FIG. 22C illustrates die 115 post-dicing where the relative positions 2206 between circuit elements 2203 and bottom-side main alignment marks 2204 are known.

Referring to FIGS. 20, 21A-21B and 22A-22C, in one embodiment, source substrate 106 consists of a square or rectangular-shaped substrate.

In one embodiment, a high-throughput low-precision pick-and-place system is used to remove known bad dies (KBDs) 110 from a source substrate 106 and populate it with known good dies, such as good dies 109. In one embodiment, a high-throughput low-precision pick-and-place system is used to remove dies 115, such as near the edge of a circular source substrate 106 and reposition them such that dies 115 are arranged in a square or rectangular-shaped bounding box, instead of a circular bounding box, as shown in FIG. 20.

In one embodiment, one or more TCs 101, each of which picks up one or more dies 115 from one or more source substrates 106 in one shot, are arranged on a carousel and/or a conveyor belt in such a manner that at any instant at least one TC 101 is picking up dies 115 from source substrate(s) 106 while at least one TC 101 is placing dies 115 onto an intermediate substrate/transfer substrate 108/product substrate.

In one embodiment, a high-throughput low-precision pick-and-place system is used to pick-and-place dies 115 onto transfer substrate 108/intermediate substrate/product substrate. In one embodiment, a light switchable adhesive, such as adhesive 2103, is used to attach dies 115 to the transfer substrate 108/intermediate substrate/product substrate. Alternatively, a non-switchable adhesive 2103 in liquid form could be used to secure dies 115 in the vicinity of their final precise position using self-assembly principles (for instance, capillary-driven self-assembly). In one embodiment, transfer substrate 108 contains mesas 2104 that are of similar lateral dimensions as dies 115 to facilitate the self-assembly. In one embodiment, direct hybrid bonding is performed, where an adhesive would not be required. In one embodiment, a deformable solid or gel-type adhesive 2103 is used to secure dies 115 during coarse (low-precision) as well as fine alignment steps, where the deformability of adhesive 2103 is reduced after the fine alignment step (for instance, using a UV curing step). A fine alignment step could be performed after low-precision die placement, where a chuck 101 and/or an ACM 201 could attach to one or more dies 115 on transfer substrate 108/intermediate substrate/product substrate. In case a light switchable adhesive 2103 is used, adhesive 2103 could be liquified using exposure to light of a suitable wavelength prior to the fine alignment step. In one embodiment, metrology of the die locations is performed in-situ as ACM 201 is actuating the location of dies 115 using imaging-based metrology methods and/or moiré-based metrology methods. Alternatively, metrology of the die locations is performed ex-situ using an off-axis metrology technique when adhesive 2103 is in a solid form. In one embodiment, die actuation is performed by precisely displacing ACM 201 with respect to a fixed grid using a short-stroke nano-positioning stage 609 (for instance, a compact stage that utilizes electromagnetic actuators, piezoelectric actuators, electro-thermal actuators, etc.). In one embodiment, dies 115 are actuated using piezoelectric elements that contact die 115 and displace it laterally (for instance, using a piezo-walk elements). In one embodiment, the metrology and die actuation are performed iteratively until a desired alignment spec is achieved. In one embodiment, ACM 201 is smaller than the size of the smallest X and Y lateral dimensions for all dies 115 on transfer substrate 108/intermediate substrate/product substrate.

In one embodiment, source substrate 106/transfer substrate 108/intermediate substrate/product substrate contains an array of alignment marks placed in a precise and stable grid (for instance, a grid, where the location of any two alignment marks is precise to within 20 nm 36). The backside of each die 115 could also contain alignment marks (e.g., alignment marks 2202, 2204), the position of which is known with respect to circuit elements 2203 on the front-side. In one embodiment, the array of alignment marks (e.g., alignment marks 2201, 2202, 2204) on source substrate 106/transfer substrate 108/intermediate substrate/product substrate is formed in a manner such that corresponding alignment marks on dies 115 being placed overlap with the substrate marks. In one embodiment, the relative alignment between dies 115 and the relevant substrate is performed using relative alignment metrology techniques, such as using up-looking moiré microscopes on a fixed or changeable grid (where the grid could be changed using a VPM 506).

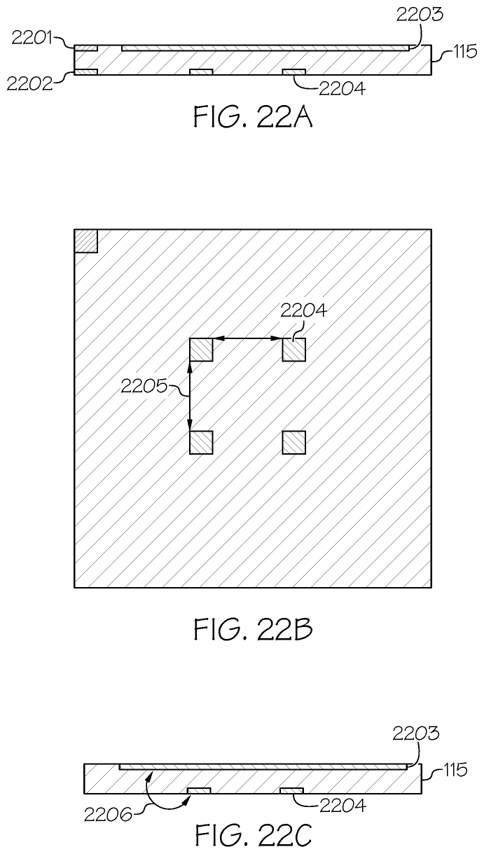

Prior to the discussion regarding the next set of Figures, the following provides definitions for various terms used herein in connection with FIGS. 23-25.

“SiP,” as used herein, refers to system-in-package. A SiP is formed of separately manufactured dice that have been physically and/or functionally integrated so as to create a system larger than each individual die. It is used interchangeably with the term Multi-Chip Module (MCM), 2.5D IC and 3D IC herein.

“Field,” as used herein, refers to individual die or a small cluster of die collocated in the SiP.

“SPP,” as used herein, refers to SiP pitch on product-substrate (SPP) including SPPₓ and SPP_{y}.

“Transfer chuck (TC),” as used herein, refers to a system that is used to transfer fields and/or dies from one substrate to another while maintaining thermo-mechanical stability of said fields and/or dies.

“Variable pitch mechanism (VPM),” as used herein, refers to a sub-system of the transfer chuck, which can be used to change the pitch of the dies picked up by the transfer chuck, prior to placement onto a transfer/product/intermediate substrate.

“Mini transfer chuck (Mini-TC),” as used herein, refers to a sub-system of the transfer chuck, which can be used to securely hold dies of non-arbitrary and/or arbitrary lateral dimension (within pre-defined maximum and minimum lateral dimensions), in a thermo-mechanically stable manner. The term mini-TC is used interchangeably with the term adaptive chucking module (ACM) herein. Also, the mini-TC and its auxiliary systems (such as the mini-TC receptacle) as well as one or more dies that are being held by the mini-TC, are referred to herein, interchangeably, as the mini-TC system, mini-TC assembly, mini-TC receptacle, and the cross-point puck.

“Alignment,” as used herein, is used interchangeably with overlay and placement herein.

“Metrology microscope assembly,” as used herein, is a sub-system for measuring the alignment of dies with respect to a reference. This could consist of the metrology optics, imagers, and electronics.

“Actuation units,” as used herein, are used to actuate one or more dies, along one or more of the X, Y, Z, θ_{X}, θ_{Y}, and θ_{Z} axes. These could also to be used to create deformation in the one or more dies. In the description of the following Figures, the actuation units are also referred to as short-stroke actuators and short-stroke stages.

“Wafer,” as used herein, is used interchangeably with the word substrate.

Prior to discussing FIGS. 23-25, a discussion regarding FIG. 1 is deemed appropriate. As shown in FIG. 1, system 100 includes transfer chuck (TC) 101 for picking up one or more dies 115 from source substrate 106 and placing them onto transfer substrate 108. In one embodiment, TC 101 contains a variable pitch mechanism (VPM) (see VPM 506 of FIGS. 5D and 5E) for changing the pitch of dies 115 picked up from source substrate 106 prior to placing them onto transfer substrate 108 (or any other substrate that the dies need to be placed on). A set of alignment microscopes could be used to measure the alignment/placement precision of dies 115 during one or more of the die pickup and die placement steps. In one embodiment, source substrate 106 is held onto a thermo-mechanically stable substrate chuck 105. In one embodiment, substrate chuck 105 optionally has embedded addressable light sources to expose the die adhesive, such as adhesive 113. In one embodiment, adhesive 113 is a light-switchable adhesive. In one embodiment, the light sources are composed of addressable arrays of UV light sources at 365 nm wavelength and visible light sources at 520 nm wavelength. In one embodiment, TC 101 contains an array of short-stroke stages (e.g., short-stroke stage 609) attached to the VPM (e.g., VPM 506), corresponding to the group of dies 115 to be picked up, to displace dies 115 locally and/or precisely in one or more of the X, Y, Z, θ_{X}, θ_{Y}, and θ_{Z} axes. In one embodiment, TC 101 attaches to the group of dies 115 to be picked-and-placed using a group of adaptive transfer chucks (ACMs) (e.g., ACMs 201). In one embodiment, TC 101 contains an array of cross-point pucks (CPPs), corresponding to the group of dies 115 to be picked-and-placed, where each cross-point puck interfaces with the VPM (e.g., VPM 506) as well as the short-stroke stage (e.g., short-stroke stage 609) and the ACM (e.g., ACM 201). The cross-point pucks could also act as local nodes for cable routing and management as well as for thermal management.

In one embodiment, transfer chuck (TC) 101 is used for picking up one or more dies 115 from a source substrate 106 and placing them onto a product substrate. In one embodiment, TC 101 is used to permanently bond the picked dies 115 onto the product substrate. Examples of such bonding include hybrid bonding, fusion bonding, thermo-compression bonding, eutectic bonding, solder bump bonding, micro-bump bonding, wire bonding, etc. The system for pick-and-place assembly, which contains TC 101, could contain additional sub-systems to support the bonding techniques. In one embodiment, the system for pick-place assembly could contain heaters, high-pressure-creating subs-systems, solder dispense sub-systems, solder reflow sub-systems, plasma cleaning sub-systems, and/or plasma activation subs-systems.

In one embodiment, a high-throughput pick-and-place system (for instance, a chip shooter) is utilized to pick-and-place dies from source substrate 106 to transfer substrate 108. In one embodiment, the throughput of the chip shooter is optimized to match the throughput of other components in series in the pick-and-place assembly line (for instance, adhesive dispense stations, precise alignment modules, etc.).

FIG. 23 illustrates die-to-transfer-wafer alignment using alignment marks on the frontside of die 115 in accordance with an embodiment of the present invention.

Referring to FIG. 23, FIG. 23 illustrates a portion of transfer substrate chuck 107 and a portion of transfer substrate 108. Furthermore, FIG. 23 illustrates circuit elements 2203 and top-side peripheral alignment marks 2201 on die 115 which is held by transfer substrate 108 via fluid 2301 (e.g., liquified adhesive). In one embodiment, fluid 2301 between die 115 and transfer substrate 108 (or any other substrate on which die alignment is being performed) is a light-sensitive adhesive.

FIG. 23 further illustrates an exemplary and optional complementary mark 2302 on transfer substrate 108 for moiré metrology. Furthermore, FIG. 23 illustrates an exemplary light path 2303, where, for example, infrared (IR) light, is used in the alignment metrology. Additionally, FIG. 23 illustrates an optional mirror assembly 2304 to sense multiple marks using a single imager assembly.

Furthermore, FIG. 23 illustrates an exemplary alignment optics and imaging assembly 2305 which may be placed over optional VPM 506.

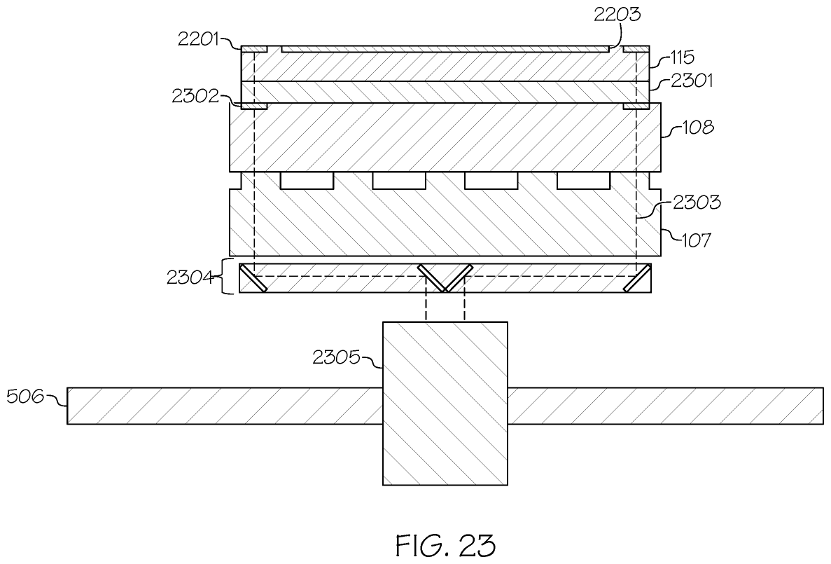

Referring now to FIG. 24, FIG. 24 illustrates die-to-transfer-wafer alignment using alignment marks on the backside of die 115 in accordance with an embodiment of the present invention.

As shown in FIG. 24, bottom-side alignment marks 2204 are now utilized for die-to-transfer-wafer alignment. Furthermore, FIG. 24 illustrates exemplary and optional complementary marks 2302 on transfer substrate 108 for moiré metrology. It is noted that such marks 2302 in FIG. 24 are located in a different location than marks 2302 in FIG. 23 since such marks 2302 are complementary to bottom-side alignment marks 2204 (see FIG. 24).

Additionally, FIG. 24 illustrates an exemplary light path 2303, where, for example, visible or infrared (IR) light, is used in the alignment metrology.

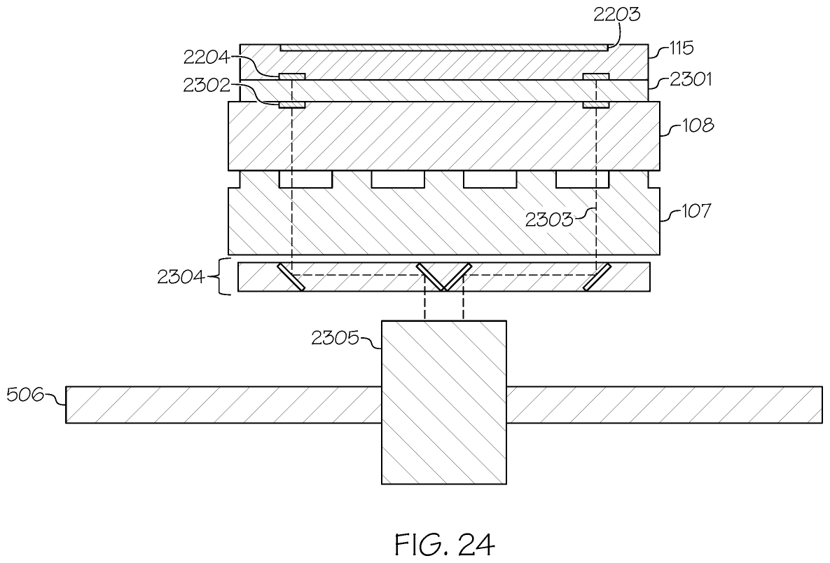

FIG. 25 illustrates die-to-transfer-wafer alignment using an angled light source and a surface-normal incoming beam into the imaging assembly in accordance with an embodiment of the present invention.

As shown in FIG. 25, FIG. 25 illustrates an exemplary angled incident light 2501 towards an alignment mark on die 115. It is noted that die 115 and the alignment marks are not shown in detail in FIG. 25. FIG. 25 further illustrates an exemplary incoming light 2502 towards imaging assembly 2305 (with alignment information) that is orthogonal to the plane of die 115.

Referring to FIGS. 23-25, in one embodiment, transfer substrate 108 contains a group of alignment marks (e.g., alignment marks 2302). In one embodiment, the group of alignment marks are on a rectilinear grid or groups of rectilinear grids. In one embodiment, the alignment marks (e.g., alignment marks 2302) are suitable for moiré-based alignment metrology, on-axis imaging-based metrology or off-axis imaging-based metrology. In one embodiment, transfer substrate 108 is made of a thermo-mechanically stable substrate. In one embodiment, transfer substrate 108 is made of silicon, silicon carbide, silicon oxide, sapphire, polymers, polymer coatings, metals, metal coatings, etc. and any combination thereof. In one embodiment, transfer substrate 108 is maintained in a thermo-mechanically stable state using thermal actuators for instance, such that the relative displacement of the group of alignment marks on transfer substrate 108 is minimized. In one embodiment, the alignment marks (e.g., alignment marks 2302) are made on the frontside and/or the backside of transfer substrate 108. The alignment marks (e.g., alignment marks 2302) are made on transfer substrate 108 (using etching, for instance) or a coating on transfer substrate 108 using patterning techniques, such as nano-imprint lithography, photolithography, etc.

In one embodiment, dies 115 (that are intended to be placed on transfer substrate 108) contain one or more alignment marks (e.g., alignment marks 2201, 2204). In one embodiment, the alignment marks (e.g., alignment marks 2201, 2204) are suitable for moiré-based alignment metrology, on-axis imaging-based metrology, off-axis imaging-based metrology, etc. The alignment marks (e.g., alignment marks 2201, 2204) are made on the frontside and/or the backside of die 115. The alignment marks (e.g., alignment marks 2201, 2204) are made on die 115 itself (using etching, for instance) or a coating on die 115 using patterning techniques, such as nano-imprint lithography, photolithography, etc.

In one embodiment, the alignment marks on the backside of dies 115, such as alignment marks 2204, are aligned with respect to corresponding alignment marks on transfer substrate 108, where the location of the die backside alignment marks is known with respect to the die frontside. This alignment could be conducted in-parallel with die actuation during die placement onto transfer substrate 108. In one embodiment, the alignment is performed using a moiré-based alignment technique. In one embodiment, alignment optics and imaging assembly 2305 is placed on the opposite side of transfer substrate chuck 107 as transfer substrate 108. In one embodiment, transfer substrate chuck 107 is constructed in part, or in full, using materials that are transparent to the wavelength(s) of light used in alignment metrology. In one embodiment, transfer substrate chuck 107 is constructed using sapphire, transparent silicon carbide, silicon, silicon carbide, fused silica, polymer coatings, polymers, metal coatings, metals, etc. or any combination thereof. The pins of transfer substrate chuck 107, and the alignment marks on dies 115 could be positioned in such a manner that for any arbitrary die 115, at most one chuck pin overlaps with an alignment mark on die 115 (for instance, by placing the die alignment marks on a rectilinear grid and placing the chuck pins in a non-rectilinear grid). In one embodiment, the gap between the backside of transfer substrate 108 and the frontside of transfer substrate chuck 107 is filled using a fluid that is index matched to the chuck pins. Examples of such fluid include isopropanol, water, etc.

In one embodiment, the alignment marks (e.g., alignment marks 2201) on the frontside of dies 115 are aligned with respect to corresponding alignment marks (e.g., alignment marks 2302) on transfer substrate 108. In one embodiment, such an alignment is conducted in-parallel with die actuation during die placement onto transfer substrate 108. In one embodiment, the alignment is performed using a moiré-based alignment technique or an infrared (IR) light-based moiré alignment technique. In one embodiment, alignment optics and imaging assembly 2305 is placed on the opposite side of transfer substrate chuck 107 as transfer substrate 108. In one embodiment, transfer substrate chuck 107 is constructed in part, or in full, using materials that are transparent to the wavelength(s) of light used in alignment metrology. In one embodiment, transfer substrate chuck 107 is constructed using sapphire, transparent silicon carbide, silicon, silicon carbide, fused silica, polymer coatings, polymers, metal coatings, metals, etc. In one embodiment, the pins of transfer substrate chuck 107 and the alignment marks on dies 115 are positioned in such a manner that for any arbitrary die 115, at most one chuck pin overlaps with an alignment mark on die 115 (for instance, by placing the die alignment marks on a rectilinear grid and placing the chuck pins in a non-rectilinear grid). In one embodiment, the gap between the backside of transfer substrate 108 and the frontside of transfer substrate chuck 107 is filled using a fluid that is index matched to the chuck pins. Examples of such a fluid include isopropanol, water, etc.

In one embodiment, alignment optics and imaging assembly 2305 corresponding to each die 115 is attached to a variable pitch mechanism (VPM) 506 that adjusts the distance between the alignment optics and imaging assemblies such that this distance is matched with the distance between dies 115 being placed on transfer substrate 108. In one embodiment, the light source for moiré alignment metrology is at an angle (e.g., incident light 2501), such that the diffracted light with the alignment signal comes out normal to die 115 and/or the plane of transfer substrate 108. In one embodiment, one or more mirror assemblies 2304 are utilized to collect light from one or more corners of one or more dies 115 and integrate the alignment signals into one or more output signals. In one embodiment, one or more mirror assemblies 2304 are utilized to distribute light to one or more corners of one or more dies 115.

In one embodiment, alignment metrology of dies 115 with respect to transfer substrate 108 (or any other substrate onto which dies 115 are being placed, for instance, the product substrate) could be performed using absolute position measurement techniques (for instance, imaging-based metrology methods), and relative alignment measurement techniques (for instance, moiré-based alignment methods).

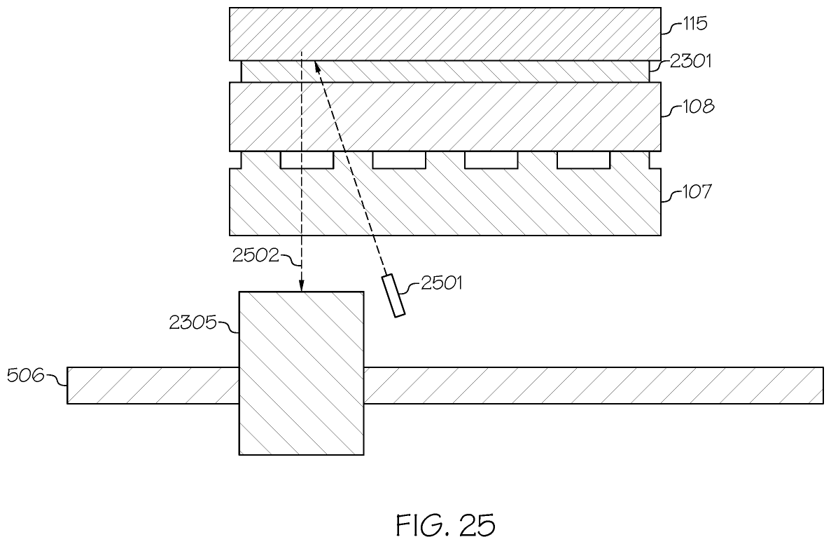

FIG. 26 illustrates an exemplary top-down view of variable pitch mechanism 506 in accordance with an embodiment of the present invention. As shown in FIG. 26, variable pitch mechanism 506 includes X rails 2601 and Y rails 2602 which translate via linear motors 2603 to adjust the X and Y pitch of the array of cross-point pucks (CPPs) 2604. Furthermore, FIG. 26 illustrates a wafer 2605, such as transfer substrate 108.

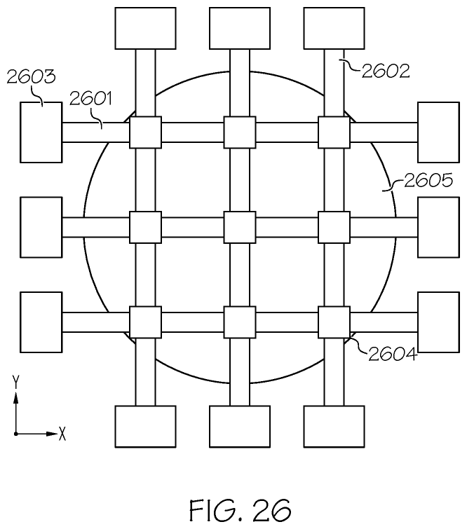

FIG. 27 is a legend for materials in magnetic actuator drawings in accordance with an embodiment of the present invention.

As shown in FIG. 27, drawing 2701 represents a coil, drawing 2702 represents a permanent magnet, drawing 2703 represents non-magnetic materials and drawing 2704 represents ferromagnetic material.

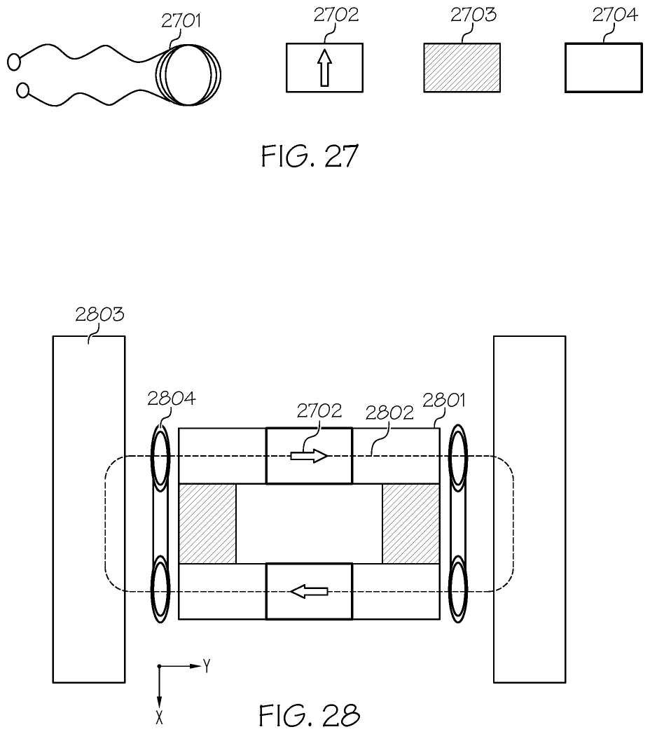

FIG. 28 illustrates an exemplary semi-passive reluctance design for a cross-point puck 2604 in accordance with an embodiment of the present invention.

Referring to FIG. 28, FIG. 28 illustrates that permanent magnets 2702 in the mover 2801 generate flux (see flux path 2802) that travels through steel rails 2803 to generate passive Z, θₓ and θ_{y} constraints and levitation. Furthermore, FIG. 28 illustrates Lorentz coils 2804 which provide X and θ_{z} thrust. It is noted that the Y actuation method is not shown in FIG. 28.

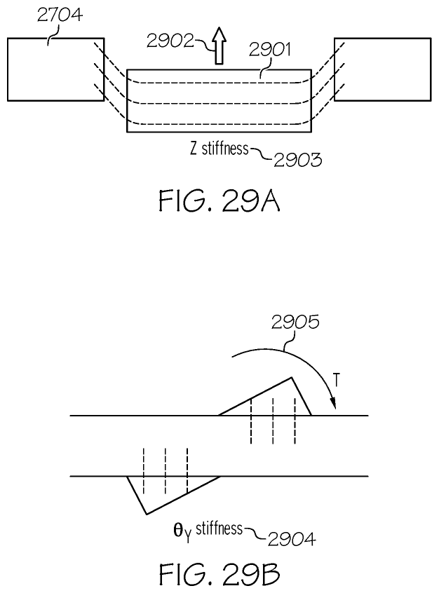

FIGS. 29A-29B illustrate an exemplary scenario when CPP 2604 is displaced relative to steel guide rails 2803 in accordance with an embodiment of the present invention.

As shown in FIG. 29A, permanent magnetic flux 2901 from ferromagnetic material 2704 produces a restoring force (F) 2902 which stabilizes CPP 2604 in the Z, θₓ and θ_{y} directions. FIG. 29A illustrates Z-stiffness 2903, whereas, FIG. 29B illustrates θ_{y} stiffness 2904 when CPP 2604 is displaced by T 2905.

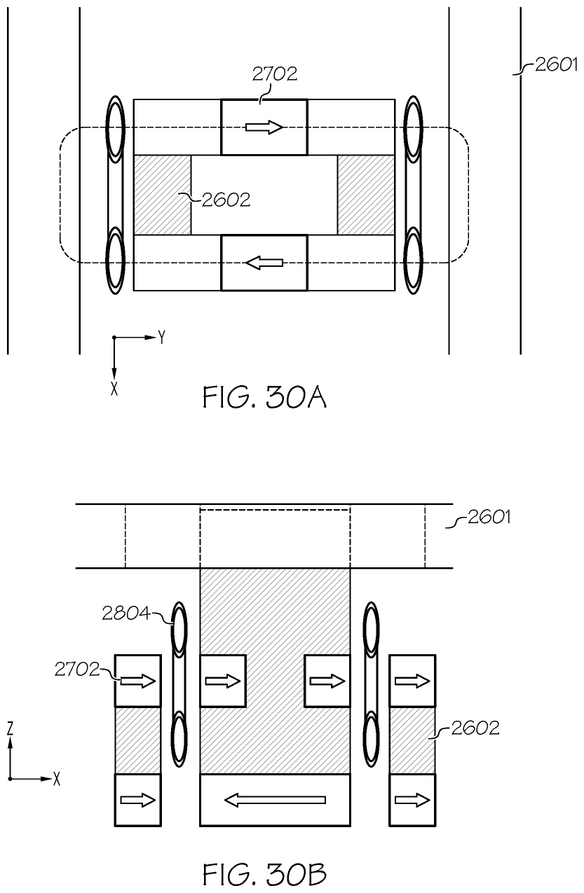

FIGS. 30A-30B illustrate an exemplary scenario if Lorentz coils 2804 cannot fit in the air gap in accordance with an embodiment of the present invention.

As shown in FIGS. 30A-30B, if Lorentz coils 2804 cannot fit in the air gap, then X rails 2601 could be reserved for passive stiffness with small air gaps while Y rails 2602 could utilize a combination of permanent magnet repulsion and Lorentz coils 2804 to control the stage in X, Y and θ_{z}.

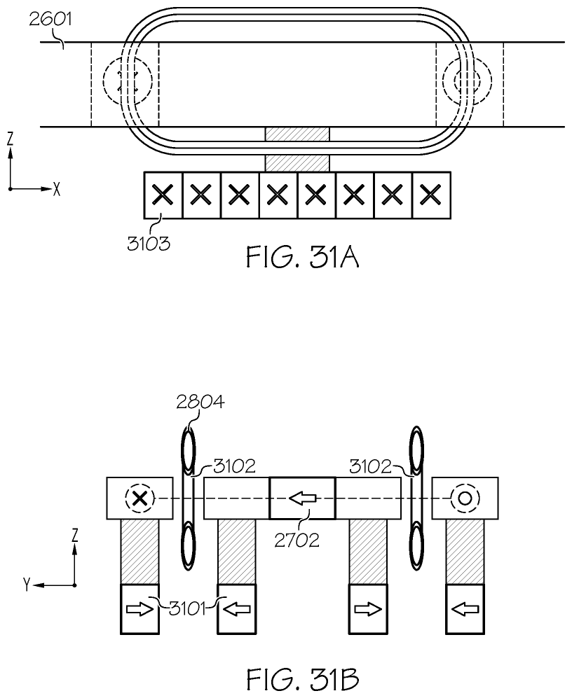

FIGS. 31A-31B illustrate an exemplary variation of the semi-passive design (FIGS. 30A-30B) without one of the rails in accordance with an embodiment of the present invention.

Referring to FIGS. 31A and 31B, Lorentz coils 2804 in the gap provide X and θ_{z} force. Furthermore, permanent magnet repulsion centers CPP 2604 between two rails in the Y direction.

In one embodiment, if Lorentz coils 2804 cannot fit the air gap, then X rails 2601 may be reserved for passive stiffness with small air gaps while the Y rails 2602 could utilize a combination of permanent-magnet repulsion (i.e., repulsive force between the pols repels magnet 2702 along its path of motion) and Lorentz coils 2804 to control the stage in the X, Y and θ_{z} direction. For example, FIGS. 31A-31B illustrate Y-actuation 3101 and X, θ_{z} actuation 3102. In one embodiment, Y-actuation 3101 is integrated in X rails 2601 as shown in element 3103.

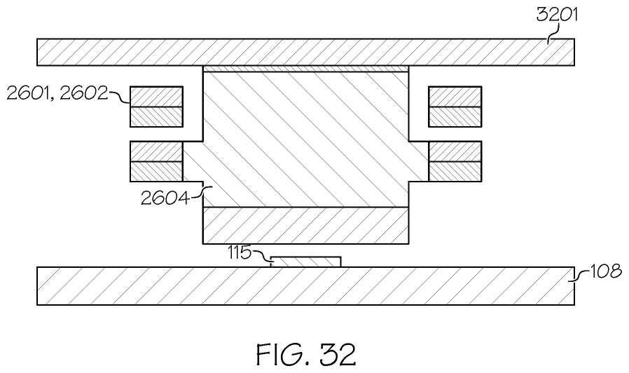

FIG. 32 illustrates an exemplary hybrid air bearing and magnetic actuation configuration in accordance with an embodiment of the present invention.

As shown in FIG. 32, check point puck (CPP) 2604 is attached to cross rails 2601, 2602. In such a setup, magnetic VPM rails 2601, 2602 provide the air bearing preload in addition to stabilizing CPP 2604 in the Y and θ_{z} direction. Furthermore, FIG. 32 illustrates glass 3201 mounted to the Z head. Additionally, FIG. 32 illustrates die 115 on transfer substrate 108. Furthermore, FIG. 32 illustrates a cross-section view of check point puck 2604 with glass 3201 mounted to the Z head.

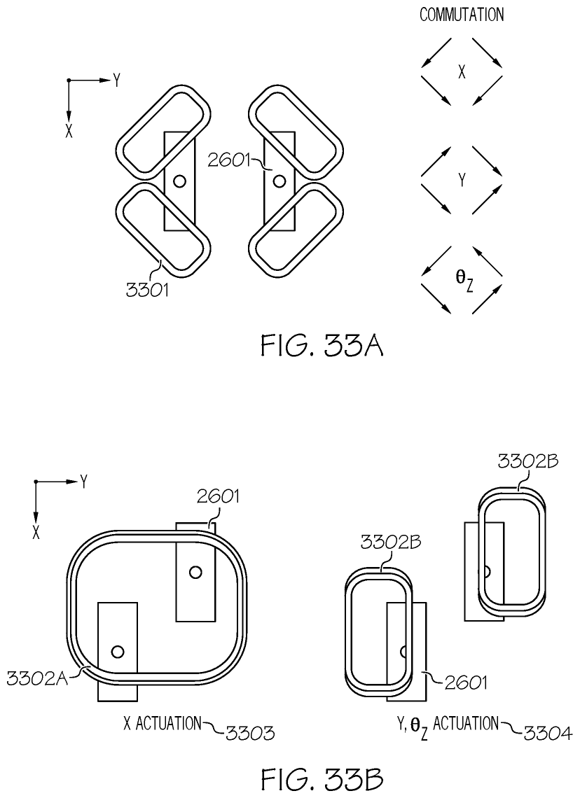

FIGS. 33A-33B illustrate an exemplary scenario when the rails (e.g., rails 2601, 2602) are made of steel in accordance with an embodiment of the present invention.

Referring to FIGS. 33A and 33B, if the rails (e.g., rails 2601, 2602) are made of steel, then arranging permanent magnets 2702 along part of the width of CPP 2604 rather than the entire width allows for X, Y and θ_{z} actuation to all be accomplished in one gap between rails 2601, 2602 and CPP 2604 with Lorentz coils 2804. In the depictions of FIGS. 33A-33B, only X-rails 2601 would be needed for three degrees of freedom active control.

Furthermore, FIG. 33A illustrates diagonal coils 3301 and FIG. 33B illustrates two coil layers, such as coil layers 3302A, 3302B. Furthermore, as shown in FIG. 33B, X actuation 3303 as well as Y and θ_{z} actuation 3304 are accomplished.

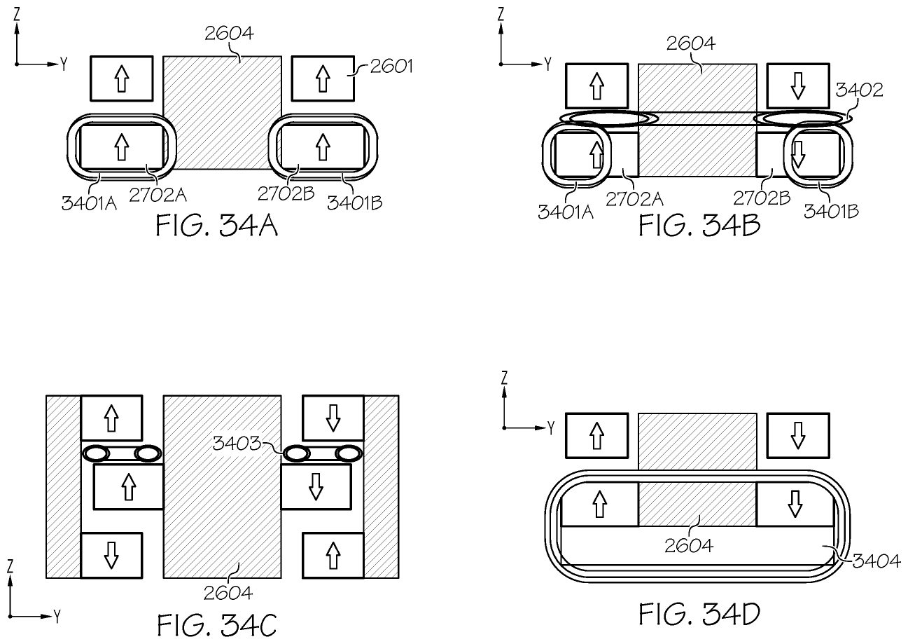

FIGS. 34A-34D illustrate coil configurations for X, Y and θ_{z} actuation which takes advantage of the air bearing constraint in accordance with an embodiment of the present invention.

As shown in FIG. 34A, permanent magnets 2702A, 2702B as well as X and θ_{z} coils 3401A and 3401B are mounted to CPP 2604.

As shown in FIG. 34B, a third coil 3402 may be added for active Y control resulting in a change in the direction of the flow of current for X and θ_{z} coils 3401A, 3401B as well as change in the direction of the field for magnet 2702A, 2702B.

As shown in FIG. 34C, X and θ_{z} coils 3403 are added illustrating another exemplary coil configuration for X, Y and θ_{z} actuation.

As shown in FIG. 34D, a coil 3404 is mounted to CPP 2604 in the manner shown in FIG. 34D that allows for X, Y and θ_{z} actuation.

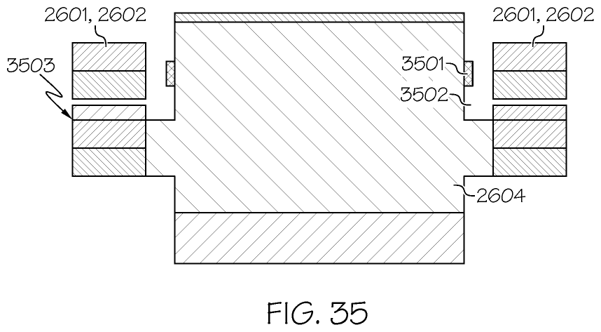

FIG. 35 illustrates an exemplary scenario in which placing optical sensors 3501 in the air gap 3502 between CPP 2604 and rails 2601, 2602 provides a feedback signal for measuring the relative position between them in accordance with an embodiment of the present invention.

Furthermore, FIG. 35 illustrates coils 3503 producing a Lorentz force.

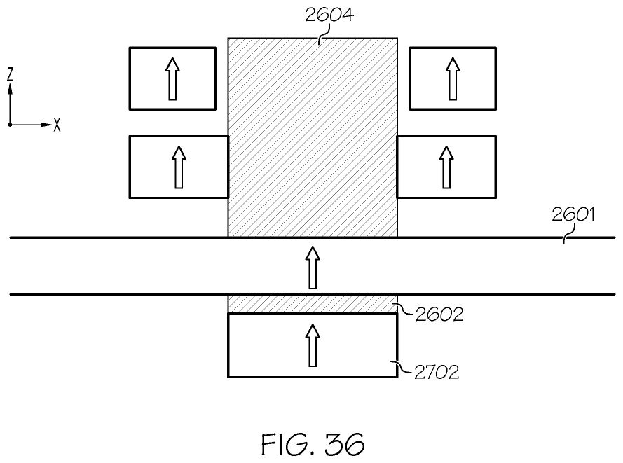

FIG. 36 illustrates a fully passive design where X-directed rails 2601 provide a Y stabilization and vice-versa in accordance with an embodiment of the present invention. In one embodiment, both X and Y rails 2601, 2602 contribute to the θ_{z} passive stiffness and both provide air bearing preload force.

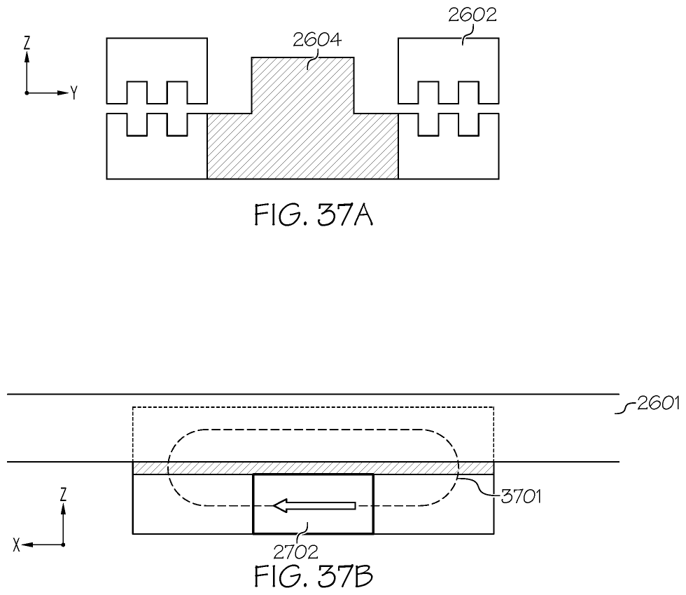

FIGS. 37A-37B illustrate an exemplary design of CPP 2604 which utilizes easier-to-manufacture steel rails but maintains the same type of passive stiffness as magnetic rails in accordance with an embodiment of the present invention.

As illustrated in FIGS. 37A-37B, rails 2601, 2602 are made of steel but maintain the same type of passive stiffness as magnetic rails. It is noted that the notches in rail 2602 and flux-guide cross sections 3701 increase lateral passive stiffness.

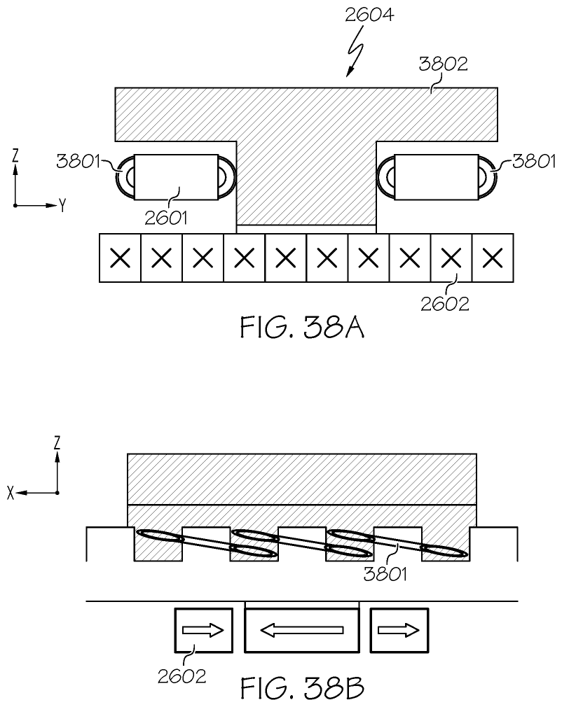

FIGS. 38A-38B illustrate an exemplary configuration of CPP 2604 where AC-excited coils 3801 in the guide rails (e.g., rails 2601, 2602) repel a diamagnetic CPP and stabilize it without the need for sensors or controllers in accordance with an embodiment of the present invention.

As shown in FIG. 38A, CPP 2604 includes an aluminum mover 3802 along with coils 3801 in guide rails (e.g., X rails 2601) comprised of steel. FIG. 38A further illustrates a small permanent magnetic Y rail 2602 for X actuation.

FIG. 38B illustrates AC-excited coils 3801 in connection with Y rails 3602.

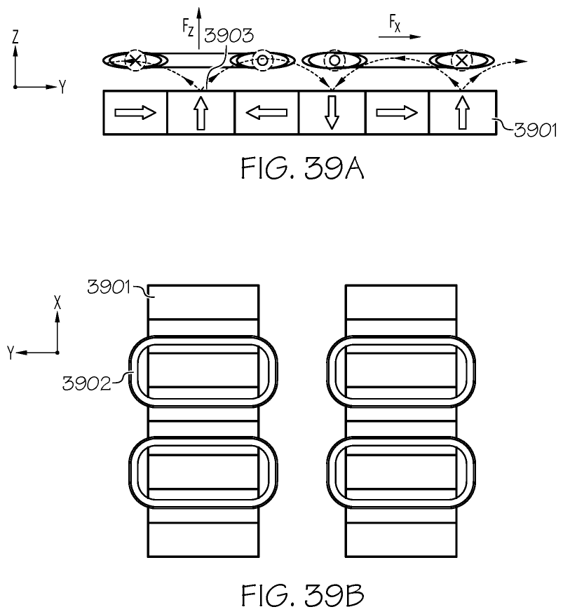

FIGS. 39A-39B illustrate an exemplary array of Halbach rails 3901 that creates a strong magnetic field above them in accordance with an embodiment of the present invention.

Referring to FIG. 39A, as coils, such as mover coils 3902, move along Halbach array rails 3901, a strong magnetic field 3903 is created. In one embodiment, coils 3902 on CPP 2604 interact with field 3903 to produce lift and thrust.

Furthermore, FIG. 39B illustrates coils 3902 moving along Halbach array rails 3901 in the X direction producing Z, X, θ_{z} and θₓ actuation. In one embodiment, similar rails 3901 in the Y direction produce Z, Y, θ_{z} and θ_{y} actuation.

Referring to FIGS. 26-28, 29A-29B, 30A-30B, 31A-31B, 32, 33A-33B, 34A-34D, 35, 36, 37A-37B, 38A-38B and 39A-39B, several configurations for a variable-pitch mechanism (VPM) 506 are disclosed that can be integrated into a larger SiP assembly platform and enable nanometer-level overlay with high throughput. In one embodiment, VPM 506 equips the machine to pick up multiple die 115 from a source wafer 106 which have constant spacing or ‘pitch.’ It will then translate each die 115 to a new wafer where die 115 will be packaged precisely within assemblies that have a different pitch than source wafer 106. As a result, the mechanism handles many die 115 simultaneously, move them to a new location, and vary the pitch between them before placing them down with nanometer precision. Hence, the name variable-pitch mechanism.

Most designs consist fundamentally of linear guide rails 2601, 2602 and cross-point pucks 2604 (CPPs) as shown in FIG. 26. Guide rails 2601, 2602 can be arranged as a grid above the wafers: some in the X-direction and some in the Y-direction. Each guide rail 2601, 2602 can be moved independently by linear actuators 2603: X-oriented rails 2601 transit in the Y-direction and vice versa. In one embodiment, a CPP 2604 can be inserted at each intersection of X and Y guide rails 2601, 2602 to create a grid of CPPs over the wafer. Each CPP 2604 may house a chucking mechanism that can pick up and release a single die 115. By adjusting the pitch of rails 2601, 2602, the CPP grid spacing can change which in turn varies the pitch of the die pattern.

To extend the life of the mechanism and reduce maintenance, wear, and particle generation, rails 2601, 2602 can locate the CPPs 2604 without frictional contact. In one embodiment, rails 2601, 2602 locates CPPs 2604 with air bearings, magnetic actuation, or another non-contact constraint method.

The following discusses several CPP designs and their associated guiderail structure for six degree-of-freedom (6-DoF) control.

In one embodiment, a CPP semi-passive concept uses permanent magnet flux 2802 and steel rails 2803 (rails 2601, 2602 made of steel) to stabilize some axes of motion as displayed in FIG. 28. Flux in the air gaps between CPP 2604 and guide rails 2601, 2602 serves to provide a force which maximizes their mutual inductance, aligning CPP 2604 with rails 2601, 2602. This flux stabilizes the system in Z, θx, and θy (see FIGS. 29A-29B). Conversely, the system generates a decentering force in the Y direction which will need to be countered with an actuator to keep CPP 2604 centered between the rails (e.g., rails 2601, 2602). As mover 2801 travels toward one rail 2601, 2602, more flux travels through that rail which increases the force pulling mover 2801 towards it. In addition, the permanent magnet flux makes the θz axis unstable and allows free movement in X which both require additional actuation. It is noted that the permanent magnet flux will produce eddy current braking effects when CPP 2604 is moved in the X direction. In one embodiment, in any axis where active actuation is employed, position sensors and a controller are incorporated to stabilize the system.

FIG. 28 depicts Lorentz coils 2804 providing actuation in X and θz. In one embodiment, coils 2804 are mounted to CPP 2604 and arranged such that they pass through the strong magnetic flux in the air gap between CPP 2604 and guide rail 2601, 2602 in the vertical direction. When current flows through them, they produce force in the X direction. In one embodiment, placing coils 2804 on either side of CPP 2604 allows for differential mode control to give θz actuation.

FIGS. 30A-30B shows an alternative configuration for X, Y, and θz actuation using the same semi-passive design. The smaller the gap between CPP 2604 and guide rail 2601, 2602, the greater the passive stiffness. As a result, adding Lorentz coils 2804 into the gap may weaken the passive stiffness too much. If that is the case, coils 2804 could be placed on a lower level to allow for small air gaps. In one embodiment, Lorentz coils 2804 provide Y and θz control via interaction with Y rails 2602 while additional permanent magnets on Y rails 2602 provide a repulsive force to locate CPP 2604 between X rails 2601.

In another variation, Y rails 2602 can be entirely removed. If Lorentz coils 2804 can be fit into the small air gap between CPP 2604 and the guide rails (e.g., rails 2602) to provide X and θz force, then a row of magnets attached to the guide rails below the primary steel structure could provide passive repulsion force against a corresponding magnet on CPP 2604 to stabilize the system in the Y direction. If there are no Y rails 2602, then the X controller needs some way of sensing the CPP global position on the rail rather than its position relative to the Y rails 2602. In this case, a linear encoder read-head could be mounted to CPP 2604 with a corresponding scale running the length of each X rail 2601. In any of these configurations, θz sensing could be achieved using a pair of eddy current, optical, or other non-contact sensors mounted on CPP 2604 and reading against the rail.

To add rigidity in the out-of-plane directions (Z, θx, and θy), air bearings could be employed to partially constrain each CPP 2604 while magnetic rails position them in X, Y and θz. In this configuration, a rigid planar surface would lie above the VPM array as shown in FIGS. 32A-32B. A preload force holds each CPP 2604 up against the plane and constrains three degrees of freedom while air bearings eliminate friction at the interface. Then, any other actuation method discussed herein, could be integrated into the stage to control the remaining degrees of freedom. Since air bearings are typically constrained at only one point and are free to rotate to align with the mating surface, each CPP 2604 would likely require three independent air bearings to provide planar constraint. In the configuration shown in FIGS. 31A-31B, the VPM rails are composed of permanent magnets which provide an attractive force that both preloads the air bearings and passively aligns CPP 2604 in two degrees of freedom. FIGS. 33A-33B display two methods by which three degrees of freedom (3-DoF) actuation could be achieved using Lorentz coils 2804 in the air gap between CPP magnets and steel rails 2601, 2602. In these designs, only one direction of rails would be needed and CPPs 2604 could move themselves along the length of the rail for planar motion. FIGS. 34A-34D show various other methods by which X, Y, or θz motion could be generated. In each instance, coils are mounted to CPP 2604 and immersed in the air gap magnetic field to generate a Lorentz force. Optical intensity sensors could serve as position feedback sensors mounted to CPP 2604 in this or any other configurations discussed herein. As shown in FIG. 35, their small packaging and simple wiring make them an attractive choice for mounting to the levitated body. They operate by shining a light on a separate surface—in this case the constraining rails—and converting the intensity of reflected light into an analog voltage. Such position feedback would enable closed-loop control for X, Y, and θz in the air bearing hybrid design and eliminate steady-state error down to the noise floor of the position signal.

In FIG. 36, another air bearing design is shown which allows for a fully passive (no actuation electronics) CPP 2604. In this case, X and Y rails 2601, 2602 provide magnetic force which aligns CPP 2604 passively in Y and X respectively. In addition, they provide θz stability and produce the air bearing preload force as previously discussed. Thus, CPP 2604 could be constrained in six degrees of freedom without the need for onboard coils and sensors. The X and Y coordinates of each CPP 2604 would be controlled by moving the cross rails which would be rigidly attached to linear actuators (e.g., linear motors 2603) at their ends. FIGS. 37A-37B illustrate a method of replacing the magnetic cross rails with steel while maintaining a good degree of the preload force and passive stiffness. Switching to steel rails would increase the rigidity of the rails and reduce manufacturing complexity.

Another configuration uses an entirely different approach which consists of AC current in coils on the guide rails producing eddy currents and a repulsive force in CPP 2604. FIGS. 38A-38B depict such a setup. The AC coils produce a time-varying magnetic field which causes eddy currents to form in a CPP body made of a paramagnetic material, such as aluminum. The eddy currents shield out the coil flux and produce a repulsive force between CPP 2604 and rail 2601, 2602. In one embodiment, two rails with coil windings stabilize a paramagnetic object in five degrees of freedom passively—meaning no closed-loop feedback control is needed. The sixth degree of freedom can be controlled through using another passive means, such as magnetic repulsion between rail 2601, 2602 and CPP 2604 or by running multi-phase current through the coils. The construction of CPP 2604 would be greatly simplified in comparison with other designs since it can be made of aluminum with no magnets, coils, or sensors. And once the coil current and frequency were tuned, the system would levitate without the need for a controller.

FIGS. 39A-39B depict a different arrangement where the guide rails consist of permanent magnet Halbach arrays 3901. Such arrays create concentrated, strong magnetic fields on one side with very little field on the other. In FIGS. 39A-39B, the magnet layout produces a field above the rails. Coils 3902 on CPP 2604 can interact with such fields to produce lift and thrust force. One pair of rails in the X-direction and four CPP coils would together produce X, Z, θx, and θz force. An identical set on Y rails 2602 and four more coils would provide the Y and θy control as well as additional Z and θz capacity. In one embodiment, the coils are arranged in pairs as shown in FIGS. 39A-39B. As they pass over the array, each individual coil alternates between producing lift and thrust. Sensors can be utilized that are also able to tell the global position of CPP 2604 relative to X and Y rails 2601, 2602. Having full, closed-loop, 6-DoF control over CPP 2604 would allow for tunable dynamic performance and very accurate positioning. In this case, it may be possible to eliminate the need for a short stroke stage attached to CPP 2604.

Furthermore, the following discusses two mechanical-bearing-based solutions. They allow for simple and stiff designs which may be advantageous in some scenarios. In one configuration, a grid pattern of steel rails is maintained, but CPPs 2604 are connected to them via linear roller bearings rather than magnetic levitation. The bearings will provide a high stiffness connection between rails 2601, 2602 and CPP 2604 which can easily tolerate disturbance forces from cables and elsewhere. Another design consists of a single column of CPPs 2604 rather than a two-dimensional array. A traditional scissor lift mechanism in the horizontal plane constrains CPPs 2604 which lie at the central intersections of linkages. In this way, a single motor can vary the pitch of any number of CPPs 2604 placed in the column. In any mechanical design, special care would be needed in selecting the short-stroke stage mounted to each CPP 2604 that compensates for error in the mechanical pitch adjustment.

In one embodiment, an array of CPPs 2604 is present, and a corresponding set of cross-rails are utilized to change the pitch of CPPs 2604 along the X and/or Y axes, wherein, when CPPs 2604 are as close to each other as possible along both X and Y axes, the density of CPPs 2604 in the X axis is different compared to their density along the Y axis. For instance, the density of CPPs 2604 could be 1 CPP per 30 mm along the X axis, and 1 CPP per 10 mm along the Y axis in the closest approach scenario. Such density variation in CPPs 2604 could be implemented using thinner rails for one of the axes. Alternatively, a different method to attach CPP 2604 to the cross-rails could be utilized. For instance, CPP 2604 could be attached to the X cross-rails 2601 using roller bearings, whereas, they could be attached to Y rails 2602 using magnetic levitation. In general, one or more of the following methods could be utilized to attach CPPs 2604 to either one of the X rails 2601 or Y rails 2602: mechanical bearings, fluidic bearings, and magnetic bearings.

In one embodiment, for the group of rails that translate along the X axis (Y rails 2602), one of the rails in the group of rails is un-actuated and fixed to the stationary VPM frame. In one embodiment, for the group of rails that translate along the Y axis (X rails 2601), one of the rails in the group of rails is un-actuated and fixed to the stationary VPM frame.

In one embodiment, CPPs 2604 are supported in the Z direction using an adhesive layer between dies 115 being held on their corresponding CPPs 2604 (on ACM 201 on CPP 2604) and the substrate that dies 115 are to be placed on (for instance, transfer substrate 108). As dies 115 are urged towards said substrate, the adhesive layer between dies 115 and the substrate (e.g., transfer substrate 108) would limit the motion of the corresponding CPP 2604 in the Z direction.

In one embodiment, VPM 506 consists of an N×1 (or alternatively, a 1×N) array of CPPs 2604, where N is an integer greater than 0. In one embodiment, N is greater than 10. In another embodiment, N is greater than 20. In another embodiment, N is greater than 30.

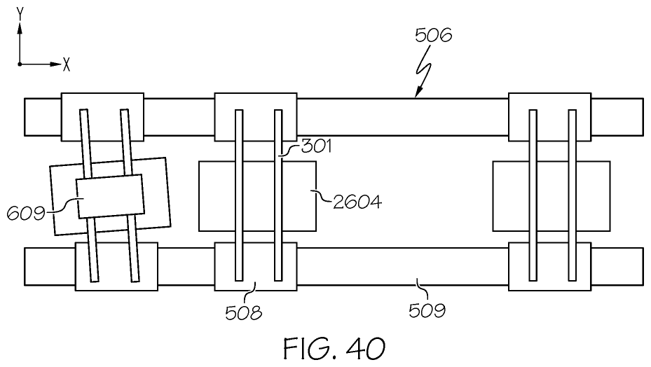

Referring now to FIG. 40, FIG. 40 illustrates an exemplary N×1 VPM 506 in accordance with an embodiment of the present invention.

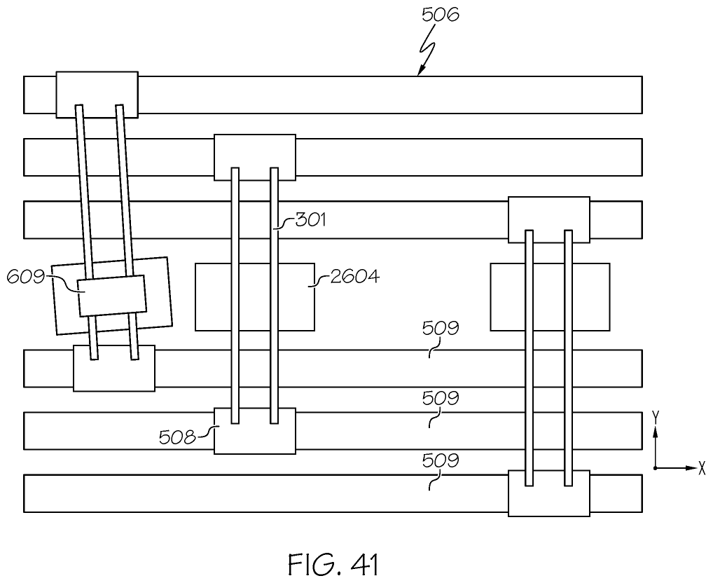

As shown in FIG. 40, cross-point pucks 2604 could be rigidly attached to the Y rails 301 (or X rails 302), in the N×1 (or 1×N) configuration. Precise short-stroke motion of CPPs 2604 could be achieved using one or more of the following methods: precise X motion using same-direction motion of the rail movers 508, precise θ_{Z} motion using differential motion of the two movers connected to Y rails 301, precise Y motion using either an integral short-stroke stage or Y motion of movers 508. Movers 508 could be supported on stators 509 using mechanical bearings (for instance, roller bearings), magnetic bearings, fluidic bearings (for instance, air bearings), etc. The rails could be attached to movers 508 using flexures that permit rotation of the rails with respect to movers 508 along the θ_{Z} axis. In one embodiment, CPPs 2604 are connected to a short-stroke stage 609, which is in turn connected to Y rails 301 (or X rails 302). In one embodiment, short-stroke stage 609 is designed to actuate along only one axis (for instance, the Y axis). In one embodiment, movers 508 for Y rails 301 of the N×1 (or alternatively, X rails 302 of a 1×N) VPM could be placed in a staggered configuration (an exemplar configuration is shown in FIG. 41).

FIG. 41 illustrates an exemplary N×1 VPM 506 with staggered movers 508 across three sets of stators 509 in accordance with an embodiment of the present invention. In one embodiment, short-stroke stage 609 is optionally designed to actuate only along one axis, such as the Y axis.

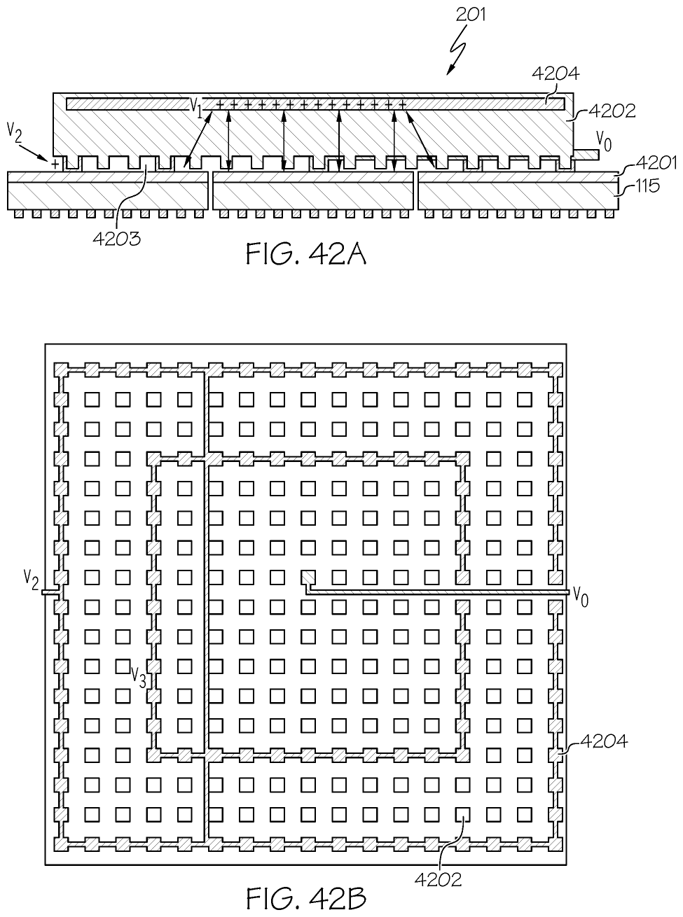

FIGS. 42A-42B illustrate an exemplary monopolar electrostatic ACM 201 in accordance with an embodiment of the present invention.

Referring to FIG. 42A, a standard encapsulation layer 4201 (e.g., chemical vapor deposition (CVD) carbon) is deposited on die 115. Alternatively, die 115 is encapsulated with medium-to-high conductivity, such as by depositing a thin layer of chromium on top of die 115 or dispersing metal nanoparticles on die 115 or by coating and/or dispersing doped polysilicon on standard encapsulation layer 4201.

Furthermore, as shown in FIG. 42A, in one embodiment, a dielectric layer 4202 with chuck pins 4203 is deposited on standard encapsulation layer 4201. Additionally, as shown in FIG. 42A, an ACM electrode 4204 is located within dielectric layer 4202.

FIG. 42B depicts a cross-section view of dielectric layer 4202 which illustrates that ACM 201 could contain multiple peripheral electrodes 4204 depending on the width of the smallest and largest die 115 being picked up. For example, if the smallest die 115 being picked up has a width of 2 mm and the largest die 115 being picked up has a width of 15 mm, then ACM 201 could contain up to 4 peripheral electrodes 4204.

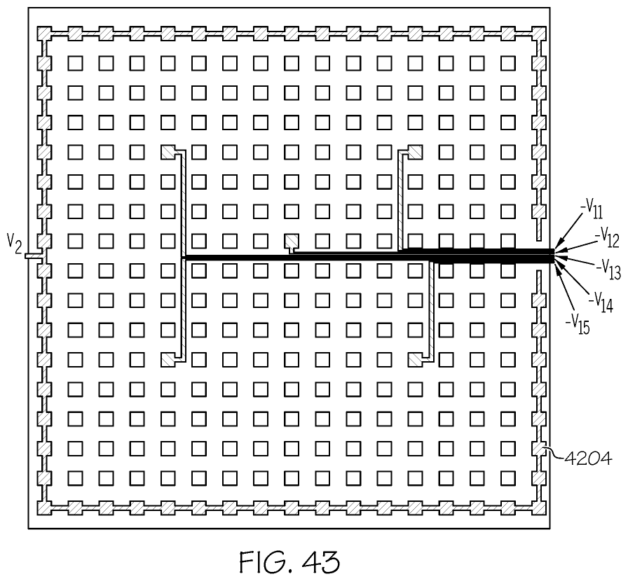

FIG. 43 illustrates an exemplary monopolar electrostatic ACM 201 for picking up multiple dies 115 using the same ACM 201 in accordance with an embodiment of the present invention.

As shown in FIG. 43, multi-die pickup may be performed using the same ACM by using a small number of addressable electrodes (at a voltage of −V₁ᵢ). It is noted that electrodes 4204 do not have to be at the center of the multi-dies.

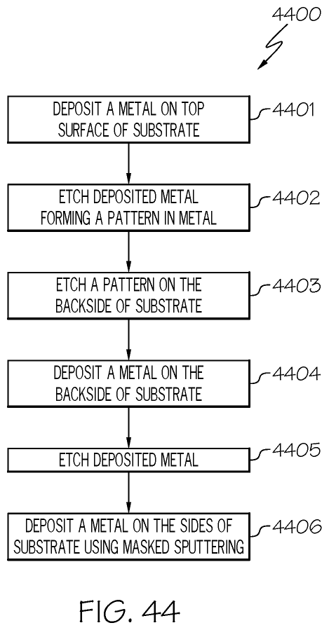

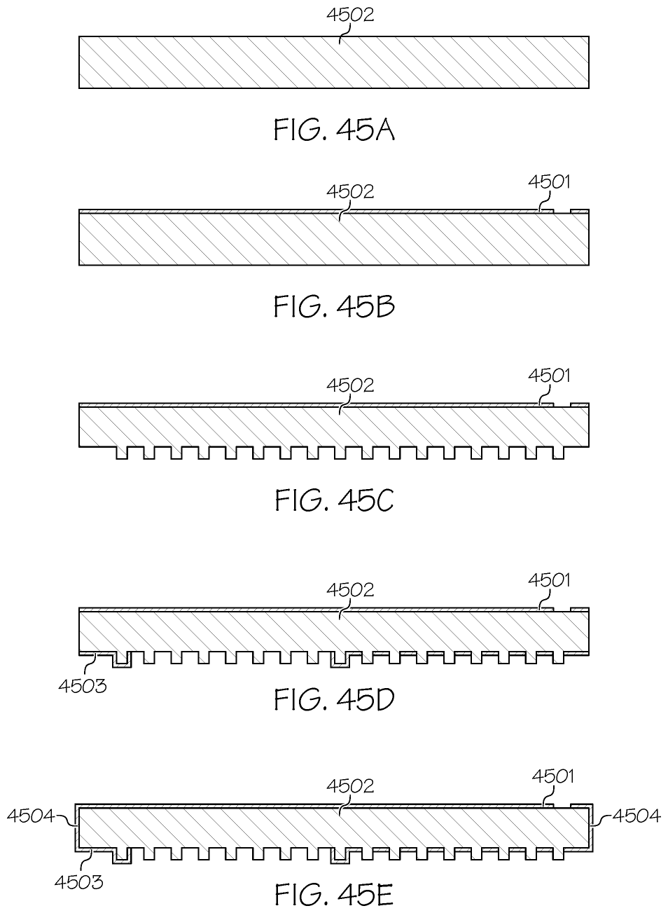

FIG. 44 is a flowchart of a method 4400 for fabricating an exemplary monopolar electrostatic ACM 201 in accordance with an embodiment of the present invention. FIGS. 45A-45E depict the cross-sectional views for fabricating an exemplary monopolar electrostatic ACM 201 using the steps described in FIG. 44 in accordance with an embodiment of the present invention.

Referring to FIG. 44, in conjunction with FIGS. 45A-45E, in step 4401, a metal (e.g., Ti, Ru) 4501 is deposited on the top surface of substrate 4502 as shown in FIGS. 45A-45B.

In step 4402, metal 4501 is etched forming a pattern in metal 4501 as shown in FIG. 45B. In one embodiment, a layer of photoresist is deposited on metal 4501, followed by bringing a photomask into alignment with substrate 4502, followed by exposing the photoresist with ultraviolet light through openings in the photomask, followed by etching metal 4501 with the photoresist serving as a masking layer followed by removing the photoresist, such as via a solvent.

In step 4403, a pattern is etched into substrate 4502, such as on the backside of substrate 4502, as shown in FIG. 45C. In one embodiment, substrate 4502 is etched by depositing a layer of photoresist on the backside of substrate 4502, followed by bringing a photomask into alignment with substrate 4502, followed by exposing the photoresist with ultraviolet light through openings in the photomask, followed by etching substrate 4502 with the photoresist serving as a masking layer followed by removing the photoresist, such as via a solvent.

In step 4404, metal (e.g., Ti, Ru) 4503 is deposited, such as chemical vapor deposition, physical vapor deposition, atomic layer deposition, etc., on the backside of substrate 4502.

In step 4405, metal 4503 is etched, such as via plasma etch, as shown in FIG. 45D. In one embodiment, after metal 4503 is deposited on the backside of substrate 4502, metal 4503 is etched by depositing a layer of photoresist on metal 4503, followed by bringing a photomask into alignment with substrate 4502, followed by exposing the photoresist with ultraviolet light through openings in the photomask, followed by etching metal 4503 with the photoresist serving as a masking layer followed by removing the photoresist, such as via a solvent.

In step 4406, metal (e.g., Ti, Ru) 4504 is deposited on the sides of substrate 4502 as shown in FIG. 45E. In one embodiment, such deposition occurs via masked sputtering.

Referring to FIGS. 42A-42B, 43-44 and 45A-45E, in one embodiment, ACM 201 utilizes electrostatic attraction to chuck one or more dies 115 that need to be picked and placed. In one embodiment, ACM 201 contains a single electrode 4204, where the single electrode, such as electrode 4204, is set to a predefined voltage, with a portion or the entirety of die 115 to be picked set to a different predefined voltage (monopolar electrostatic ACM). Alternatively, ACM 201 contains two or more electrodes 4204, where half of the electrodes, such as electrodes 4204, are set to a predefined voltage and the other half set to a different predefined voltage (bipolar electrostatic ACM). In the bipolar design, electrodes 4204 with the two different set point voltages could be placed such that no two adjacent electrodes 4204 have the same predefined voltage (for instance, an inter-digitated electrode design).

In one embodiment, ACM 201 utilizes coulombic attraction between die 115 to be picked and electrode 4204 within ACM 201, to chuck die 115. Alternatively, ACM 201 utilizes the J-R effect, where dielectric 4202 (along with chuck pins 4203, which could optionally be made of the same material as dielectric 4202) has a finite resistance and allows some amount of current to flow between die 115 and the one or more ACM electrodes 4204. In one embodiment, the material of dielectric 4202 separating the one or more electrodes 4204 and the one or more dies 115 to be picked is sapphire, fused silica, undoped silicon, or a mixture that contains those materials.

In one embodiment, one or more pins 4203 of ACM 201 near the center of ACM 201 are set to a different voltage compared to ACM electrode 4204 (the electrode at V₁ voltage in FIGS. 42A-42B). These pins 4203 near the center of ACM 201 could be used to set the voltage of die 115 to the same voltage as pin 4203, creating electrostatic attraction between die 115 and ACM 201. In one embodiment, ACM 201 is designed such that the neighboring dies 115, to the one or more dies 115 that are intended to be handled by ACM 201, are not attracted to ACM 201. Alternatively, the neighboring dies 115 are attracted with a negligible force to ACM 201. In one embodiment, dies 115 are coated with a conductive encapsulation layer on the side that faces ACM 201 to enable charge redistribution on the ACM facing side. Exemplary encapsulation layers (see, e.g., encapsulation layer 4201) include conductive polymers (such as PEDOT:PSS), doped carbon, thin layer of metal (such as chromium), etc. or any combination thereof. In one embodiment, the encapsulation layer, such as encapsulation layer 4201, is stripped-off using one or more of the following cleaning methods after die pick and place: O₂ plasma cleaning, wet strip, and vapor-based strip. In one embodiment, encapsulation layer 4201 is removed for all dies 115 in parallel after all die pick-and-places onto the target substrate (e.g., transfer substrate 108, product substrate, etc. onto which the die placement is to be performed) are finished. In another embodiment, encapsulation layer 4201 on the neighboring dies 115 of die 115 to be placed on the target substrate is removed prior to die placement of the current die 115. In one embodiment, removal of encapsulation layer 4201 is performed using O₂ plasma etch. In one embodiment, the plasma etching is performed using one or more atmospheric pressure plasma jets. In one embodiment, plasma etching of encapsulation layer 4201 is utilized to create a gap in the vertical direction between ACM 201 (which is carrying die 115 to be placed onto the target substrate) and the neighboring dies 115 that have already been assembled onto the target substrate prior to the current die 115.

In one embodiment, the voltages applied to dies 115 to be picked and the neighboring dies 115 are set to predefined values calculated to reduce the likelihood of electrostatic discharge between neighboring dies 115.

In one embodiment, if the side of dies 115 to be picked and placed using ACM 201 is made of a material with a finite conductivity (for instance, lightly to highly doped silicon), no encapsulation layer is coated prior to die assembly using ACM 201.

In one embodiment, the die detachment time for the electrostatic ACM 201 is minimized by sensing residual charges on die 115 and applying voltage of an opposite polarity (compared to the polarity used during die assembly) to remove the charges.

In one embodiment, ACM 201 is attached to CPP 2604 using a mechanism that allows one or more of tip/tilt/theta motion of ACM 201 with respect to CPP 2604.

In one embodiment, ACM 201 has the ability to bow in the z direction.

In one embodiment, ACM 201 has fixed lateral extents that are smaller than the extents of the smallest die 115 in the group of dies 115 being picked and placed using ACM 201.

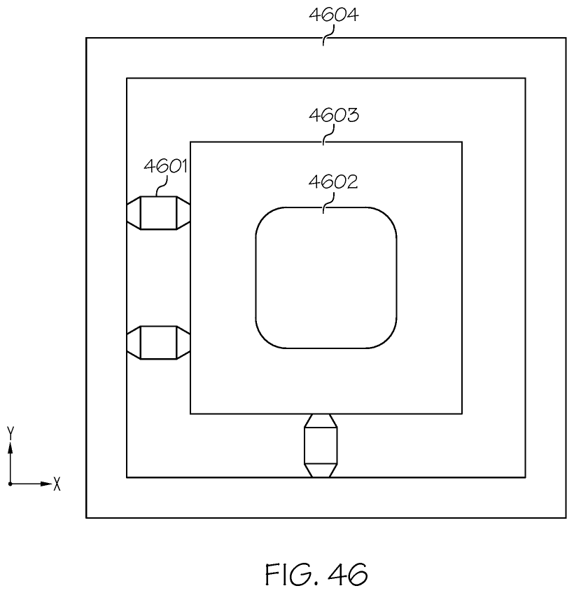

Referring now to FIG. 46, FIG. 46 illustrates an exemplary piezo stack configuration for the short-stroke stage, such as short-stroke stage 609, in accordance with an embodiment of the present invention.

In particular, FIG. 46 illustrates piezo stack actuators 4601, a metrology window 4602 and a mover 4603 and a stator 4604. In one embodiment, moving the two x-directed actuators 4601 in parallel provides X travel while moving them differentially provides θ_{z} travel.

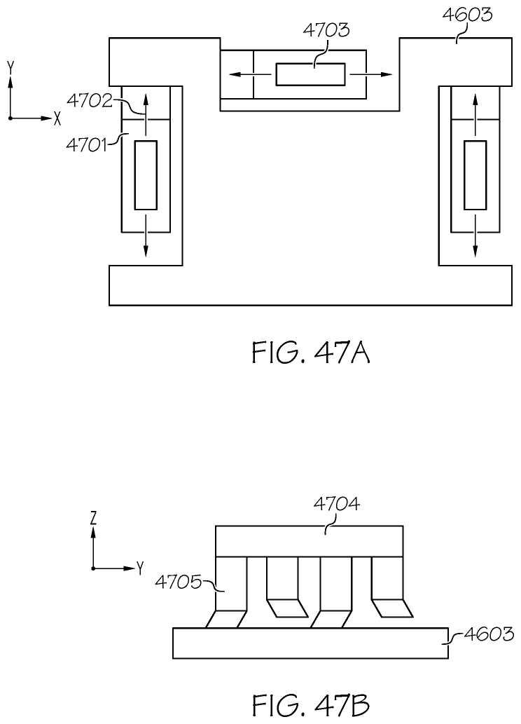

FIGS. 47A-47B illustrate an exemplary piezo inchworm actuator configuration in accordance with an embodiment of the present invention.

In particular, FIG. 47A illustrates mover 4603 and an intermediate flexure stage 4701 along with the associated piezo actuation directions 4702. Furthermore, FIG. 47A illustrates the piezo inchworm actuators 4703. Additionally, as shown in FIG. 47A, the short-stroke stage, such as short-stroke stage 609, is constrained by the inchworm period in Z, θₓ and θ_{y}.

Furthermore, FIG. 47B is a side view of piezo inchworm actuators 4703 that illustrates the actuator body 4704 along with the axial extension piezo stacks 4705.

In one embodiment, actuators 4703 are mounted on flexure stages 4701 to allow the stage, such as stage 609, to translate in the orthogonal direction of each actuator 4703. In one embodiment, preload holding actuators 4703 to the stage, such as stage 609, constrains the stage in the Z, θₓ and θ_{y} directions.

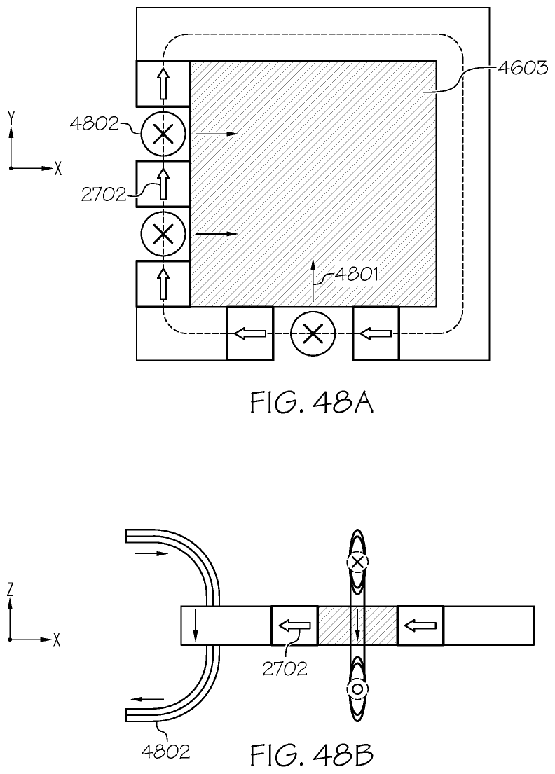

FIGS. 48A-48B illustrate an exemplary stage 609 which exploits the Lorentz force (see 4801) between a current-carrying coil 4802 and a magnetic field to provide three degrees of freedom position control in accordance with an embodiment of the present invention.

As shown in FIG. 48A, such coils 4802 are mounted to a stator, such as stator 4604. Furthermore, FIG. 48A illustrates magnets 2702 with steel flux guides which encircle the perimeter of mover 4603.

FIG. 48B illustrates a side view of coils 4802 mounted to a stator, such as stator 4604.

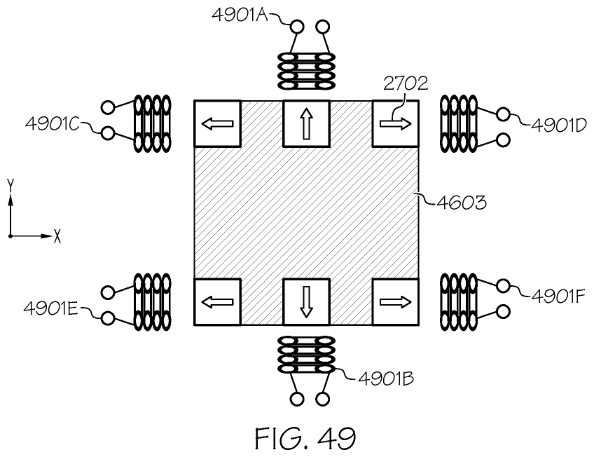

FIG. 49 illustrates an exemplary alternative configuration of a stage, such as stage 609, that uses stator-mounted electromagnets to interact with permanent magnets 2702 on mover 4603 in accordance with an embodiment of the present invention. As shown in FIG. 49, opposing pairs of coils, such as coils 4901A-4901B, 4901C-4901D, and 4901E-4901F, reduce the non-linearity of force through the stroke of the stage, such as stage 609.

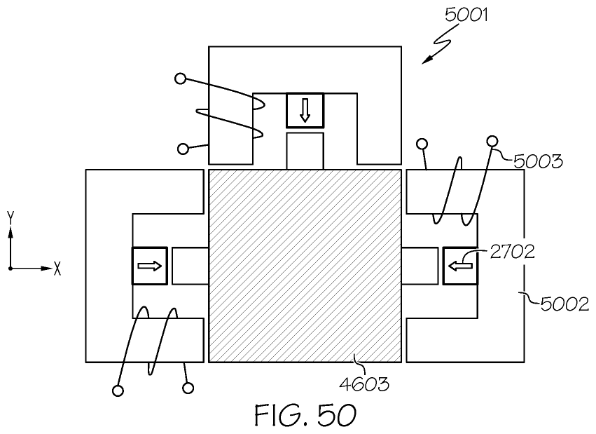

FIG. 50 illustrates exemplary magnet-biased reluctance actuators 5001 interacting with the steel portions of mover 4603 to provide three degrees of freedom control in accordance with an embodiment of the present invention.

As shown in FIG. 50, actuators 5001 include stator coil/magnet assemblies 5002 along with permanent magnets 2702 and coils 5003 wound on each of the stator coil/magnet assemblies 5002.

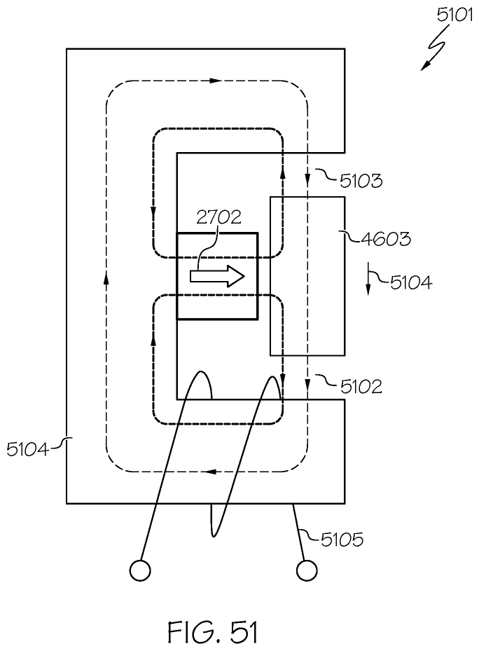

FIG. 51 illustrates an exemplary diagram demonstrating the force-producing mechanism of the magnet-biased actuator 5101 in accordance with an embodiment of the present invention.

As shown in FIG. 51, coil flux increases the gap flux (5102) on one side of mover 4603 and decreases flux (5103) on the other side of mover 4703. Such a flux difference produces a force (designated as “F” 5104).

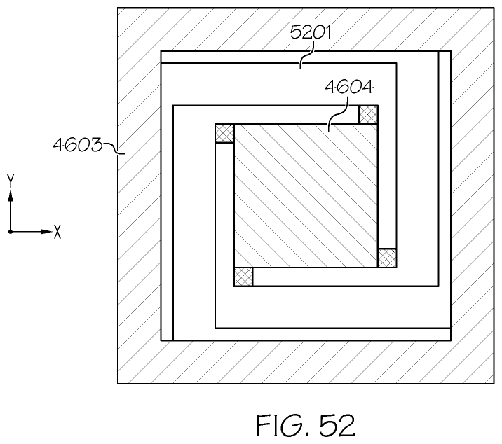

FIG. 52 illustrates an exemplary flexure configuration in which series, orthogonal cantilevers 5201 provide compliance in the plane and stiffness perpendicular to the plane in accordance with an embodiment of the present invention.

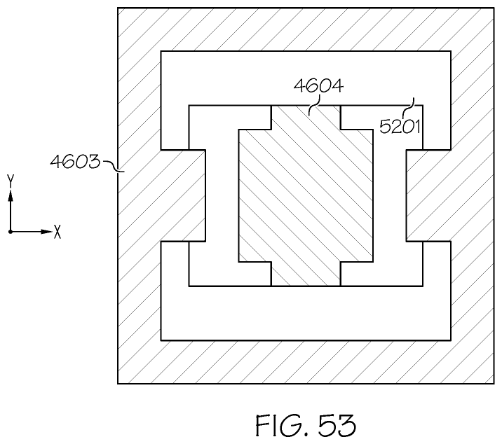

FIG. 53 illustrates an alternative exemplary flexure configuration in which the series, orthogonal cantilevers 5201 in FIG. 52 are re-oriented and shrunk to provide room for actuation in accordance with an embodiment of the present invention.

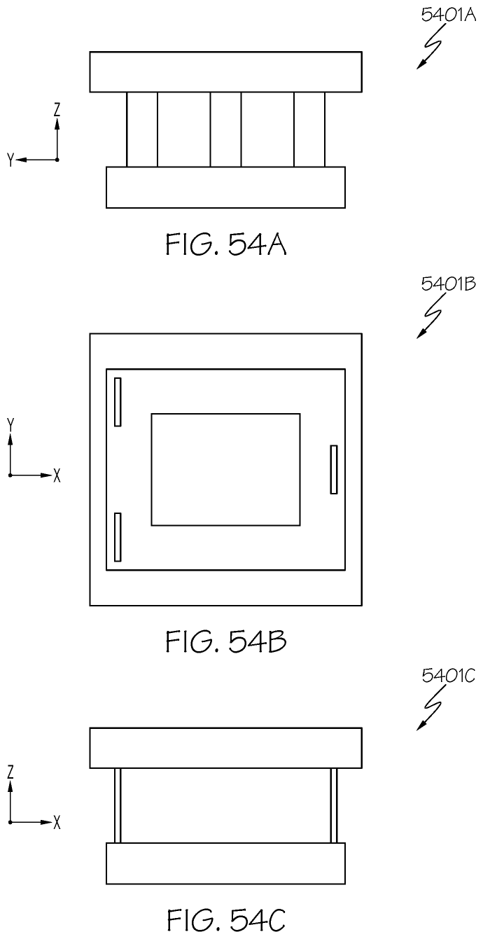

FIGS. 54A-54C illustrate an exemplary out-of-plane flexure 5401A-5401C, respectively, that allows for more access to mover 4603 for actuation in accordance with an embodiment of the present invention. Flexures 5401A-5401C may collectively or individually be referred to as flexures 5401 or flexure 5401, respectively. In one embodiment, flexure 5401 is manufactured out of sheet spring steel and bolted to mover 4603 from above.

The following discusses nano-precise short-stroke stage, such as nano-precise short-stroke stage 609, in connection with FIGS. 46, 47A-47B, 48A-48B, 49-53 and 54A-54C. In particular, the following discusses several configurations for a precision-positioning stage 609 that can be integrated into a larger SiP assembly platform and enable nanometer-level overlay. Furthermore, the following discusses both actuation methods for such a stage 609 and constraint possibilities. All configurations consist of actuators that provide small displacements in one or more of the following three degrees-of-freedom (3-DoF) that lie in a plane: one rotation and two translations.

In one embodiment, the short-stroke stage (e.g., short-stroke stage 609) is mounted to a long-stroke mechanism above a source silicon substrate 106 containing many dies 115. The long-stroke mechanism will position the short-stroke stage 609 above a particular die 115. Once in place, the short stroke will locate a chuck to pick up die 115 from the substrate, such as substrate 106. Then, actuated by the long stroke, it will translate to a separate stage for assembly and place the die in a package with nanometer precision. Closed-loop feedback control will maintain the position of the short-stroke moving portion, or ‘mover’ (e.g., mover 4603), relative to the stator (e.g., stator 4604) mounted on the long-stroke. An additional control loop can also be employed at lower bandwidth with global metrology feedback to ensure accurate positioning of the mover (e.g., mover 4603) relative to the die pickup and assembly locations. In one embodiment, the short-stroke stage actively controls three degrees of freedom (3-DoF) in the horizontal plane (X, Y, and θz) while the three remaining axes (Z, θx, and θy) are constrained passively. In such an embodiment, three independent actuators and three sensors are integrated into the stage (e.g., stage 609).

In one embodiment, piezo actuators (e.g., piezo actuators 4703) are utilized due to their low power consumption, high stiffness, and high bandwidth. In one embodiment, two piezo-based actuation methods are used for the stage (e.g., stage 609). In the first method, piezo stacks 4601 are utilized which expand in the longitudinal direction when a voltage is applied. In one embodiment, three piezo stacks 4601—two in one direction and one perpendicular to the first two—are utilized to enable 3-DoF control as shown in FIG. 46. Operating the two parallel stacks 4601 in common mode provide translation while differential mode produces rotation. The third actuator 4601 gives translation in the orthogonal direction. In an alternative piezo-based actuation method, more compact actuation is allowed using an inchworm mechanism, such as the PiezoWalk® drive by PI L.P. These actuators have the advantage of infinite range through using a series of smaller steps and so can be smaller compared with stacks which provide the entire stage motion in a single stroke. Three inchworm drives could be held to the top surface of the mover 4603 on intermediate flexure stages as shown in FIGS. 47A-47B for DoF control. In one embodiment, the vertical preload for the actuators can serve a dual purpose providing strong frictional contact between the actuator and the stage (e.g., stage 609) as well as constraining the stage in Z, θx, and θy. In one embodiment, preload is provided with permanent magnets mounted on the actuators.

Several magnetic actuation methods could also be used in place of piezo mechanisms. FIGS. 48A-48B shows the mover 4603 of a stage (e.g., stage 609) driven by Lorentz actuators. Coils 4802 mounted on the stator (e.g., stator 4604) pass through magnetic fields produced by permanent magnets (e.g., permanent magnets 2702) on mover 4603. Three such coils give three degrees of freedom control and have the advantage of being non-contact. Lorentz actuators have excellent linearity and force-control characteristics but require more power than piezo methods and are less rigid.

FIG. 49 illustrates another magnetic configuration to provide position control to the stage, such as stage 609. The stator (e.g., stator 4604) contains coils (e.g., coils 4901A-4901F) which serve as electromagnets to interact with permanent magnets which are integrated into mover 4603. Pairs of magnets—consisting of a permanent magnet and an electromagnet—can create attractive or repulsive forces depending on the direction of current through the coils (e.g., coils 4901A-4901F). The coils (e.g., coils 4901A-4901F) are shown in differential pairs with every coil facing another coil across from it. Operating pairs of coils on either side of the stage (e.g., stage 609) can cancel out the nonlinearity of the magnetic force as mover 4603 travels through its stroke. This method can be packaged efficiently as only small coils are needed on the stator (e.g., stator 4604).

FIG. 50 shows magnet-biased reluctance actuators 5001 providing motion control for the stage (e.g., stage 609). Reluctance actuators 5001 may have a much greater force density than Lorentz actuators at small strokes and so can be smaller and leave more room for flexure arrangements. FIG. 51 portrays the process by which such a configuration can generate a force. The stator portion consists of a steel C section 5104, a permanent magnet 2702, and a coil 5105. In one embodiment, mover 4603 only needs a small piece of steel protruding into the gap of the stator. The stator sections could also be rotated above mover 4603 to leave room for flexure constraints with the two legs of the C-shaped steel extending down around the mover piece. Reluctance actuators 5001 have saturation and hysteresis nonlinearities which make them difficult to position on the nanometer level. As a result, in one embodiment, the control scheme incorporates feedforward inverse plant models or other sophisticated approaches to combat the nonlinearity effects.

Aside from piezo and magnetic actuators, electrothermal actuators could drive the stage precisely, though their low bandwidth could limit the speed of the stage. Electrostatic comb drives could also be used, but their low force density would require a large volume around the mover to generate the required forces.

In one embodiment, the stage (e.g., stage 609) is actively controlled in three degrees of freedom and, as a result, the additional three axes of motion (Z, θx, and θy) are constrained mechanically. In one embodiment, flexures are used to provide such constraint. FIG. 52 depicts a spiral flexure pattern with thickness into the page which allows for free translation and rotation in plane but resists out-of-plane deflection with higher stiffness. This pattern takes advantage of the space available in the stage footprint to allow for long, compliant flexures. The mover (e.g., mover 4603) and stator (e.g., stator 4604) can all be produced from one piece of stock steel using the wire EDM process. Each of the four attachment paths between the stator (e.g., stator 4604) and the mover (e.g., mover 4603) consist of two orthogonal cantilevers 5201 in series. While the arrangement allows for free motion in the plane, it also will be compliant out of the plane too, especially in a coupled Z and θz screw motion. In addition, ambient thermal changes will cause the stage (e.g., stage 609) to rotate in θz, though this could be compensated for with a position control system. Finally, the spiral design does not leave room for an actuation method to be integrated in the same plane as the flexures.

In contrast, FIG. 53 shows another flexure configuration which uses series orthogonal cantilevers 5201 but which leaves room for actuator integration. Also, the symmetry of the stage (e.g., stage 609) eliminates the thermally induced rotation of the previous design. However, this design will also demonstrate relatively low stiffness in the Z direction unless the flexures are sufficiently tall (deep into the page). And what the stage gains in space for actuation, it loses in compliance created by the longer flexures of the previous design.

Lastly, FIGS. 54A-54C illustrate an alternate approach where mover 4603 is constrained to the stator (e.g., storage 4604) vertically rather than in the plane of actuation. In this configuration, there is more free space to actuate mover 4603 around the sides. The flexures could be machined with the wire EDM process out of spring steel and could be bolted to mover 4603 and stator (e.g., stator 4604).

The following includes some definitions.

“SiP,” as used herein, refers to “system-in-package.” A SiP is formed of separately manufactured dice that have been physically and/or functionally integrated so as to create a system larger than each individual die. It is used interchangeably with the term Multi-Chip Module (MCM), 2.5D IC and 3D IC.

“Field,” as used herein, refers to individual die or a small cluster of die collocated in the SiP.

“SPP,” as used herein, refers to SiP pitch on product-substrate (SPP) including SPPₓ and SPP_{y}.

“n-MASC bonding head (nBH),” as used herein, refers to a system that is used to transfer fields and/or dies from one substrate to another, while maintaining thermo-mechanical stability of said fields and/or dies. This has been previously referred to as transfer chuck or TC.

“Variable pitch mechanism (VPM),” as used herein, refers to a sub-system of the nBH, which can be used to change the pitch of the dies picked up by the transfer chuck prior to placement onto a transfer/product/intermediate substrate.

“Universal chucking module (UCM),” as used herein, refers to a sub-system of the nBH, which can be used to securely hold dies of non-arbitrary and/or arbitrary lateral dimension (within pre-defined maximum and minimum lateral dimensions), in a thermo-mechanically stable manner. UCM has previously been referred to as Mini Transfer Chuck (Mini-TC), Adaptive Chucking Module (ACM), mini-TC system, mini-TC assembly, ACM system. A UCM-BH, or a UCM Bonding Head, consists of the UCM along with an optional single or multi-axis short-stroke stage, optional tip-tilt, z motion mechanisms, optional flexure systems, optional bowing systems. A UCM-BH can be used to receive one or more die (from a source, intermediate, transfer substrate, or a second UCM-BH), and transfer/attach/bond received die to a product, intermediate, transfer substrate.

“Alignment,” is to be used interchangeably with overlay and placement.

“Metrology microscope assembly,” as used herein, refers to a sub-system for measuring the alignment of dies with respect to a reference. This could consist of the metrology optics, imagers, and electronics.

“Actuation units,” as used herein, are used to actuate one or more dies, along one or more of X, Y, Z, θ_{X}, θ_{Y}, θ_{Z} axes. These could also to be used to create deformation in the one or more dies. Furthermore, “actuation units” are also referred to herein as short-stroke actuators and short-stroke stages.

“Wafer,” is to be used interchangeably with the word substrate.

In the following description, several configurations for an n-MASC bonding head (nBH) that can be integrated into a larger SiP assembly platform and enable nanometer-level overlay with high throughput are disclosed. n-MASC stands for nano-precise Modular Assembly of Semiconductor Chiplets. The nBH is an architecture which enables high-throughput chip assembly through the use of parallelization. Though features vary in the designs detailed below, they all rely on the simultaneous or rapid precise placement of multiple dice using numerous individual stages and metrology assemblies. Processing many die at once lowers assembly cost and allows for chip-shooter-level throughput with orders of magnitude more precision. The nBH architectures below are largely agnostic to the choice of short-stroke precision stage, die-chucking mechanism, metrology framework, and additional elements of a SiP assembly platform and can be treated as general design concepts.

SiP assembly can be summarized as gathering multiple chiplets or die from their respective source wafers and precisely placing them on a product wafer or substrate. The objective of the nBH is to accomplish this in a parallel and high-throughput manner. Most conceptions of the design consist of an array of chucks positioned above a source wafer to simultaneously pick up many die at once. However, the pitch of dice on each source wafer will vary as will the pitch of SiPs on the product wafer; so, a mechanism is developed to accommodate the changing pitch of pickup and place locations. The following designs are all ways of addressing this challenge to enable rapid and precise advanced packaging.

In one embodiment, the nBH is used for direct bonding of dice onto a product substrate. The dice could face away (with the metal pads on the dice facing away from the source substrate) from the source substrate (for instance, a tape frame) when attached to the source substrate. The dice could face towards the product substrate, when attached (or being attached) to the product substrate. The source substrate (for instance, tape frame) could be mounted face-down (such that the side on which dice are located faces away from the bridge) on the bridge, or mounted face-up. In one embodiment, the source substrate (for instance, tape frame) could be mounted face-down on the bridge and dice transferred to a die chuck (which could be a part of the n-BH), or alternatively, a separate source-substrate-to-die-chuck flip-and-transfer mechanism could be utilized for transfer to the die chuck. Subsequently, pick and place assembly using the nBH (or sub-components thereof) could be implemented from the die chuck, wherein, the pick-and-place assembly could lead to direct bonding of the dice onto the product substrate.

In one embodiment, the source substrate is mounted face-down on the bridge and product substrate face-up near the base of the nBH. In another embodiment, the product substrate is mounted face-down on the bridge and source substrate face-up near the base of the nBH. In another embodiment, the product and source substrates are mounted face-up near the base of the nBH. In another embodiment, the product and source substrates are mounted face-down on the bridge.

In one embodiment, the nBH allows the UCM-BHs to move by at least 15 mm relative to each other. In one embodiment, the nBH allows the UCM-BHs to move by at least 25 mm relative to each other. In one embodiment, the nBH allows the UCM-BHs to move by at least 50 mm relative to each other. In one embodiment, the nBH allows the UCM-BHs to move by at least 50 mm in absolute terms. In one embodiment, the nBH allows the UCM-BHs to move by at least 100 mm in absolute terms. In one embodiment, the nBH allows the UCM-BHs to move by at least 200 mm in absolute terms. In one embodiment, the nBH allows the UCM-BHs to be positioned in X, Y with a precision better than 50 μm. In one embodiment, the nBH allows the UCM-BHs to be positioned in X, Y with a precision better than 20 μm. In one embodiment, the nBH allows the UCM-BHs to be positioned in X, Y with a precision better than 5 μm. In one embodiment, the nBH allows the UCM-BHs to be positioned in X, Y with a precision better than 1 μm. In one embodiment, the nBH allows the UCM-BHs to be positioned in X, Y with a precision better than 500 nm. In one embodiment, the nBH allows the UCM-BHs to be positioned in θ_{Z} with a precision better than 50 mrad. In one embodiment, the nBH allows the UCM-BHs to be positioned in θ_{Z} with a precision better than 10 mrad. In one embodiment, the nBH allows the UCM-BHs to be positioned in θ_{Z} with a precision better than 1 mrad. In one embodiment, the UCM-BHs are stable in one or more of X, Y, Z axes to better than 10 nm, when pitch readjustment is not being performed. In one embodiment, the UCM-BHs are stable in one or more of X, Y, Z axes to better than 5 nm, when pitch readjustment is not being performed. In one embodiment, the UCM-BHs are stable in one or more of X, Y, Z axes to better than 1 nm, when pitch readjustment is not being performed. In one embodiment, the UCM-BHs are stable in one or more of θ_{X}, θ_{Y}, θ_{Z} axes to better than 10 μrad, when pitch readjustment is not being performed. In one embodiment, the UCM-BHs are stable in one or more of θ_{X}, θ_{Y}, θ_{Z} axes to better than 5 μrad, when pitch readjustment is not being performed. In one embodiment, the UCM-BHs are stable in one or more of θ_{X}, θ_{Y}, θ_{Z} axes to better than 1 μrad, when pitch readjustment is not being performed. In one embodiment, the pitch readjustment settling time for the nBH is better than 5 seconds. In one embodiment, the pitch readjustment settling time for the nBH is better than 2 seconds. In one embodiment, the pitch readjustment settling time for the nBH is better than 1 seconds. In one embodiment, the pitch readjustment settling time for the nBH is better than 0.5 seconds. In one embodiment, the pitch readjustment settling time for the nBH is better than 0.2 seconds. In one embodiment, cable routing is performed between the array of UCM-BHs in an nBH in such a manner that cables emanating from any single UCM-BH exert a disturbance force of less than 5N on said UCB-BH during the range of actuation of the nBH. In one embodiment, cable routing is performed between the array of UCM-BHs in a nBH in such a manner that cables emanating from any single UCM-BH exert a disturbance force of less than 1N on said UCB-BH during the range of actuation of the nBH. In one embodiment, cable routing is performed between the array of UCM-BHs in a nBH in such a manner that cables emanating from any single UCM-BH exert a disturbance force of less than 0.5N on said UCB-BH during the range of actuation of the nBH. In one embodiment, cable routing is performed in a star topology, wherein, each UCB-BH is supplied electrical power, fluidic connections, control signals using cables that emanate from one or more central units. In one embodiment, cable routing is performed in a mesh topology, wherein, each UCB-BH is supplied electrical power, fluidic connections, control signals using cables that link neighboring UCB-BHs with each other, and an external unit for supplying electrical power, fluidic connections, control signals is located outside the nBH and connects to one or more UCM-BHs at the periphery of the nBH. In one embodiment, the nBH generate less than 10 particles per pitch readjustment. In one embodiment, the nBH generate less than 1 particles per pitch readjustment. In one embodiment, the nBH generate less than 1 particles per 100 pitch readjustments. In one embodiment, the nBH generate less than 1 particles per 10000 pitch readjustments. In one embodiment, the short-stroke stages in an nBH could have a motion range in Z of over 1 mm. In one embodiment, the short-stroke stages in an nBH could have a motion range in Z of over 500 μm. In one embodiment, the short-stroke stages in an nBH could have a motion range in Z of over 100 μm. In one embodiment, the short-stroke stages in an nBH could have a motion range in Z of over 10 μm. In one embodiment, the short-stroke stages in an nBH could have a minimum incremental motion in Z of less than 5 μm. In one embodiment, the short-stroke stages in an nBH could have a minimum incremental motion in Z of less than 1 μm. In one embodiment, the short-stroke stages in an nBH could have a minimum incremental motion in Z of less than 200 nm. In one embodiment, the short-stroke stages in an nBH could have a minimum incremental motion in Z of less than 100 nm. In one embodiment, the short-stroke stages in an nBH could have a minimum incremental motion in Z of less than 10 nm. In one embodiment, the short-stroke stages in an nBH could have a force application sensitivity in Z of less than 50 mN. In one embodiment, the short-stroke stages in an nBH could have a force application sensitivity in Z of less than 10 mN. In one embodiment, the short-stroke stages in an nBH could have a force application sensitivity in Z of less than 5 mN. In one embodiment, the short-stroke stages in an nBH could have a force application sensitivity in Z of less than 1 mN. In one embodiment, the short-stroke stages in an nBH could have a motion range in X, Y of over 500 μm. In one embodiment, the short-stroke stages in an nBH could have a motion range in X, Y of over 100 μm. In one embodiment, the short-stroke stages in an nBH could have a motion range in X, Y of over 50 μm. In one embodiment, the short-stroke stages in an nBH could have a motion range in X, Y of over 10 μm. In one embodiment, the short-stroke stages in an nBH could have a motion range in X, Y of over 3 μm. In one embodiment, the short-stroke stages in an nBH could have a minimum incremental motion in X, Y of less than 50 nm. In one embodiment, the short-stroke stages in an nBH could have a minimum incremental motion in X, Y of less than 20 nm. In one embodiment, the short-stroke stages in an nBH could have a minimum incremental motion in X, Y of less than 5 nm. In one embodiment, the short-stroke stages in an nBH could have a minimum incremental motion in X, Y of less than 2 nm. In one embodiment, the short-stroke stages in an nBH could have a minimum incremental motion in X, Y of less than 1 nm. In one embodiment, the short-stroke stages in an nBH could have a motion range in one or more of θ_{X}, θ_{Y}, θ_{Z} axes that is over 50 mrad. In one embodiment, the short-stroke stages in an nBH could have a motion range in one or more of θ_{X}, θ_{Y}, θ_{Z} axes that is over 20 mrad. In one embodiment, the short-stroke stages in an nBH could have a motion range in one or more of θ_{X}, θ_{Y}, θ_{Z} axes that is better than 10 μrad. In one embodiment, the short-stroke stages in an nBH could have a motion range in one or more of θ_{X}, θ_{Y}, θ_{Z} axes that is better than 3 mrad. In one embodiment, the short-stroke stages in an nBH could have a minimum incremental motion in one or more of θ_{X}, θ_{Y}, θ_{Z} axes that is better than 10 μrad. In one embodiment, the short-stroke stages in an nBH could have a minimum incremental motion in one or more of θ_{X}, θ_{Y}, θ_{Z} axes that is better than 3 μrad. In one embodiment, the short-stroke stages in an nBH could have a minimum incremental motion in one or more of θ_{X}, θ_{Y}, θ_{Z} axes that is better than 1 μrad. In one embodiment, the short-stroke stages in an nBH could have a minimum incremental motion in one or more of θ_{X}, θ_{Y}, θ_{Z} axes that is better than 0.5 μrad. In one embodiment, the short-stroke stages in an nBH have a thermal stability of better than 1° C., over at least a cycle of pitch readjustment. In one embodiment, the short-stroke stages in an nBH have a thermal stability of better than 0.5° C., over at least a cycle of pitch readjustment. In one embodiment, the short-stroke stages in an nBH have a thermal stability of better than 0.1° C., over at least a cycle of pitch readjustment.

The following discusses cross-rail variable pitch mechanisms.

The cross-rail nBH contains an array of chucks (UCMs, or UCM bonding heads, or UCM-BHs) above the wafer held in place by a series of X-directed and Y-directed rails. At each intersection of X rails and Y rails lies one chuck. The rails are mounted on either end by linear motors such that the X-directed rails can translate in the Y direction and vice-versa. By controlling the position of the linear motors, the pitch of the chucks may be controlled in both horizontal axes. Thus, the chucks can be set to one pitch to pick up die from a source wafer, then adjust their pitch using the linear motors to match the spacing of product packages, and finally place die simultaneously.

The chucks can be located at rail intersections in a number of ways. In one embodiment, the chucks can be constrained by roller bearings or air bearings that interface between chuck assembly and rails. In another embodiment, the chucks can employ active electro-magnetic levitation to remain suspended at a fixed distance away from the rails. In one embodiment, chucks use a combination of constraint methods, such as magnetically pre-loaded air bearings where permanent magnets interact with steel rails to preload the air bearings (acting against a flat plane above the rail assembly) and also provide passive stabilization in the horizontal degrees of freedom. To improve structural rigidity during placement when accuracy is critical, the chuck assemblies could be clamped to a backplane structure above the rails which would increase the overall system stiffness. Other subassemblies required to pick up an individual die like a precision short-stroke stage and flexure mechanism could be part of the structure that resides at the rail intersection points.

The following discusses serial pickup, parallel placement.

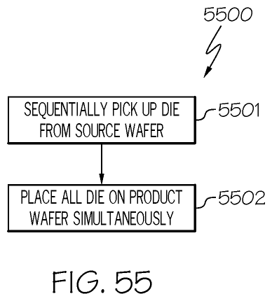

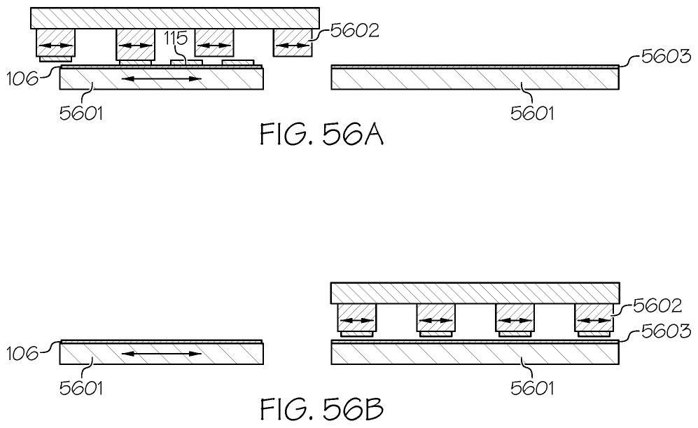

In this nBH configuration, the array of chucks (UCMs, or UCM bonding heads, or UCM-BHs) is mounted semi-permanently above the die at a fixed pitch which matches the pitch of the final product wafer. Thus, they do not have to change their pitch for every pick-and-place operation but only whenever a product wafer with a different pitch is loaded into the system. One challenge with this is that the chucks are not at the proper pitch to pick up die from the source wafers simultaneously. Instead, they will pick up die sequentially while the wafer stage translates rapidly in between each pickup until all chucks have secured one die. If each chuck is mounted to a precision short-stroke stage, then the wafer location accuracy during pickup is less important, because the short-stroke stage can counteract that effect during placement. Thus, the wafer stage can translate somewhat imprecisely (micrometer-level error rather than nanometer-level) to enable very rapid stepping between die pickups. And then the entire array of chucks will be lowered down to the product wafer to precisely place all die simultaneously which improves throughput for the slowest step of the process: nano-precise placement. Such a process is discussed in connection with FIGS. 55 and 56A-56B.

Referring to FIG. 55, FIG. 55 is a flowchart of a method 5500 for serial pickup, parallel placement in accordance with an embodiment of the present invention. FIGS. 56A-56B depict the cross-sectional views for serial pickup, parallel placement using the steps described in FIG. 55 in accordance with an embodiment of the present invention.

Referring to FIG. 55 in conjunction with FIGS. 56A-56B, in step 5501, each chuck 5602 sequentially picks up die 115 from source wafer 106 as shown in FIG. 56A. For example, as shown in FIG. 56A, short-stroke stages/chucks 5602 at semi-permanent SIP pitch sequentially picks up die 115 from source wafer 106 located on scanning stage 5601. FIG. 56A also illustrates product wafer 5603 on scanning stage 5601.

In one embodiment, a separate placement mechanism (e.g., cross-rail VPM) sets individual short-stroke stages at the pitch of product wafer 5603 on a backplane.

In step 5502, all die 115 are placed on product wafer 5603 simultaneously as shown in FIG. 56B.

In one embodiment, source wafer 106 is replaced with one or more die chucks. For instance, one could have an array of die chucks with the same arrangement and number of die chucks as short-stroke stages with the die chucks optionally integrated with a VPM 506 for pitch change.

In one embodiment, a mechanism will be required to reconfigure the chucks at the proper spacing for each new product wafer. This could be pitch adjustment mechanism similar to the one described above in connection with “cross-rail” or could be a standard robotic arm that moves each chuck one by one. Since the pitch is changed relatively infrequently, the pace at which this occurs is less critical, so sequential adjustment is feasible. The chuck assemblies could use vacuum or magnetic force to remain locked in place against a rigid planar surface parallel with the wafer and lying directly above it. The throughput of the entire process could be improved by using a twin approach where one set of chucks is over the source wafer picking up die while another set is placing die on the product wafer.

In another embodiment, the source wafer could be replaced by an upward-facing chip shooter which rapidly scans from chuck to chuck in the array and places a chip up onto each chuck. From there, the chucks would continue the process as normal and place the die simultaneously on the product wafer.

In one embodiment, upward facing UCM-BHs are clamped onto a reference plate at the SiP pitch. Downward facing short stroke stages (along with corresponding UCM-BHs) are clamped onto a reference plate at the SiP pitch. Upward facing UCM-BHs transfer dice to downward facing UCM-BHs. A reconfiguring mechanism could be used to reconfigure the pitch of the short-stroke stages and UCM-BHs (optionally using a cross-rail-type VPM) only when the SiP is changed. The pickup here is done serially, and the placement in parallel.

In one embodiment, a bonding system could be composed of an array of bonding heads, wherein, a sub-group of heads picks up a sub-group of dies, and subsequently a second sub-group of heads picks up a second sub-group of dies. The sub-group could be composed of one bonding head. One or more of the bonding head sub-groups could be actuated in the Z-direction. The pickup could be from one or more of the following: a source substrate, another bonding head, an intermediate wafer, and a transfer wafer. In one embodiment, one or more of the bonding heads are at SiP pitch. An Nth bonding head sub-group could be used to pick up an Nth sub-group of dies, wherein N is greater than or equal to 3.

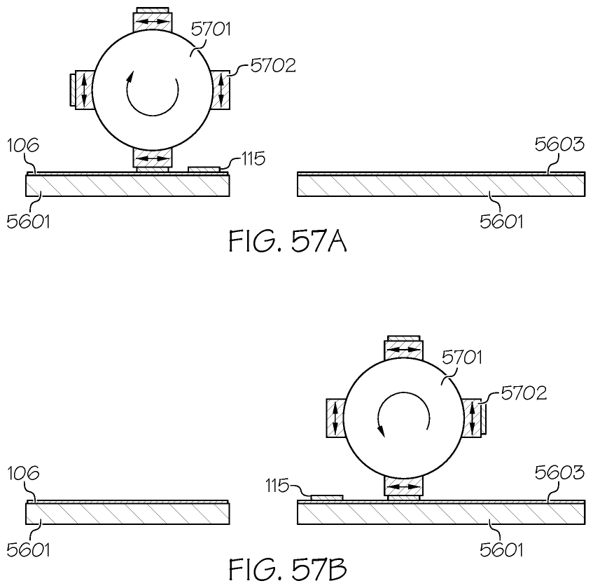

The turret-based approach more closely mirrors traditional packaging processes but incorporates nanometer precision which has before been missing. Above the wafer, the system would house a series of chuck assemblies arranged in axisymmetric fashion about a motorized axis. The rotation mechanism and collection of chuck assemblies is referred to as the turret. Each chuck assembly would contain a short-stroke stage capable of nanometer-level precision on which the chuck would be mounted. The turret is oriented in such a way that, at discrete intervals, one chuck assembly will be in contact with the wafer while the rest are above it. The turret steps rapidly such that it brings each chuck into contact with the wafer one by one and pauses to allow chucking or de-chucking of a die. This rotation, in concert with stepping in the horizontal plane (performed by either the wafer stage or a gantry system carrying the turret) allows the turret to rapidly pick up die sequentially from the source wafer and then place them one by one on the product wafer. Two turrets may work in parallel with one collecting die from the source wafer while the other one places the die on the product wafer. FIGS. 57A-57B depict such an nBH design.

Referring to FIGS. 57A-57B, FIGS. 57A-57B depict one configuration for turret-based pick and place in accordance with an embodiment of the present invention.

As shown in FIGS. 57A and 57B, turret 5701 contains a series of short-stroke/chuck assemblies 5702 and rotate to sequentially pickup die 115 on source wafer 106 to be placed on product wafer 5603. It is noted that source wafer 106 could be replaced with one or more die chucks. For instance, source wafer 106 could be replaced with an array of chucks with the same arrangement and number of die chucks as short-stroke stages with the die chucks optionally integrated with a VPM 506 for pitch change.

In one embodiment, the turret-based nBH is used for direct bonding of dice onto a product substrate. The dice could face upwards on a source substrate (for instance, a tape frame) (i.e., metal layers face away from the source substrate), and downwards on product substrate. Source substrate (for instance, tape frame) could be mounted face-down on the bridge, and dice could be picked down using the turret-based nBH, rotated by 180°, and subsequently placed (and, optionally direct bonded) onto the product substrate (which is mounted face-up near the base of the turret-based nBH). Alternatively, the source substrate (for instance, tape frame) could be mounted face-up near the base of the turret-based nBH, and dice could be picked up using the nBH, rotated by 180°, and subsequently placed (and, optionally direct bonded) up onto the product substrate (which is mounted face-down on the bridge).

In one embodiment, two or more turrets, such as turret 5701, could be used in the nBH, where each turret comprises one or more chuck assemblies. The two or more turrets, such as turret 5701, could have variable pitch. In one embodiment, the pitch change is implemented using a VPM integrated with the turrets. In one embodiment, the VPM, such as VPM 506, is a N×1 (or 1×N) VPM.

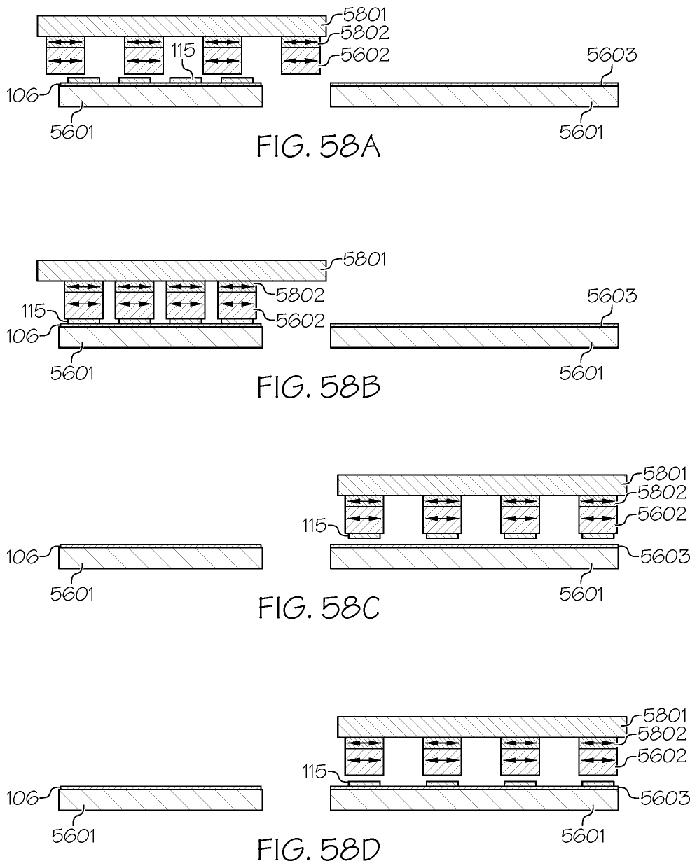

Furthermore, in one embodiment, the nBH takes advantage of planar motors to allow for versatile pitch adjustment. In this embodiment, there is a flat stator structure above the wafer with movers operating beneath it. The movers each have large or unlimited stroke in X and Y and some versions also contain planar rotation control built in. Each mover would hold a chuck assembly and short stroke stage. When picking up die from the source wafer, the movers would arrange themselves in order to match their pitch with that of the wafer. Once each chuck has retrieved one or more dice, the movers would adjust to the pitch of the source wafer for simultaneous die placement. FIGS. 58A-58D illustrate such a planar-motor-based nBH scheme.

Referring to FIGS. 58A-58D, FIGS. 58A-58D depict a configuration for planar-motor-based pick and place in accordance with an embodiment of the present invention.

As shown in FIG. 58A, the planar motor stator 5801 lies above wafer 106 located on scanning stage 5601. Furthermore, as shown in FIG. 58A, the planar motor movers 5802 adjust their pitch to match that of the source and/or product wafers 106, 5603.

Additionally, as shown in FIG. 58B, short-stroke stages/chucks 5602 at semi-permanent SIP pitch sequentially picks up die 115 from source wafer 106 located on scanning stage 5601.

In one embodiment, an additional short-stroke performs the final adjustments before placement. In one embodiment, source wafer 106 could be replaced with one or more die chucks. For instance, source wafer 106 could be replaced with an array of die chucks with the same arrangement and number of die chucks as the short-stroke stages with the die chucks optionally integrated with a VPM 506 for pitch change.

As shown in FIG. 58C, all picked-up die 115 are transferred to product wafer 5603. As shown in FIG. 58D, all pick-up die 115 are placed on product wafer 5603 simultaneously.

In one embodiment, a variety of planar motor designs could be used for this nBH. In one embodiment, stator 5801 consists of numerous independent coils while movers 5802 contain Halbach arrays of permanent magnets. Currents are applied to the coils to control the orientation of mover 5802 in up to six degrees of freedom. Another magnetic planar motor, called a Sawyer motor or 2D stepper motor, is composed of a steel waffle grid stator and a mover with at least two independent stepper assemblies containing coils wrapped around steel flux guides. The remaining degrees of freedom could be supported by air bearings or another planar constraint. Piezo motors can also be arranged to provide actuation in a plane and could act against a rigid plate with preload force supplied by vacuum or magnets. Some of these motors have precise enough motion that a short-stroke stage may not be needed to locate the die in X and Y when placing it.

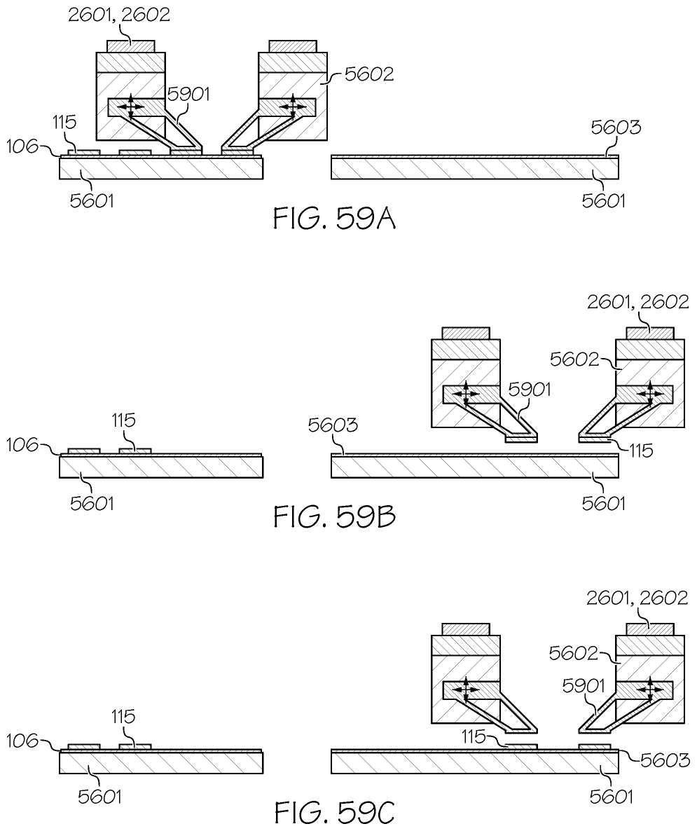

In one embodiment, there is a fan-out configuration for the nBH mounts chucks (UCMs, or UCM bonding heads, or UCM-BHs) away from the geometrical center (or away from the neighborhood of the geometrical center) of the short-stroke precision stages. In one embodiment, chucks are mounted on cantilever structures which connect to the short-stroke precision stages. The short-stroke stages themselves can be mounted to a cross-rail structure so that their pitch can be changed to match that of the source wafer or product wafer. FIGS. 59A-59C illustrate a diagram of such a design. In one embodiment, short-stroke stages could be arranged in an N×2 configuration.

Referring to FIGS. 59A-59C, FIGS. 59A-59C illustrate a fan-out style nBH in accordance with an embodiment of the present invention. In one embodiment, the fan-out style nBH moves short-stroke actuation to the sides of die 115 as shown in FIG. 59A. Cantilever structures 5901 connect stage 5601 to the chuck (UCM) 5602 which manipulates die 115. The pitch of the short-stroke stages can be varied by mounting each short stroke stage 5602 on a VPM rail system (e.g., VPM rails 2601, 2602) as shown. In one embodiment, the pitch of the short-stroke stages 5602 is fixed (no VPM needed). It is noted that the source wafer 106 could be replaced with one or more die chucks. For instance, source wafer 106 could be replaced with an array of die chucks with the same arrangement and number of die chucks as short-stroke stages, with the die chucks optionally integrated with a VPM 506 for pitch change.

Furthermore, as illustrated in FIG. 59A, cantilever structures 5901 pick up dies 115. As illustrated in FIG. 59B, such picked-up dies 115 are transferred to product wafer 5603. As shown in FIG. 59C, such picked-up dies 115 are placed on product wafer 5603.

Because actuation does not occur directly above the dice, the size of the short-stroke stage may be increased without affecting the minimum pitch of the chucks which are picking up die. So rather than developing an ultra-compact short-stroke stage to fit directly above each die, a more standard stage could be employed and placed in the extra room alongside the die. Another advantage comes from the relatively clear area above the wafer in this design as opposed to other designs whose actuation mechanisms and stages are directly above the wafer. This not only lowers the risk of particle generation above the wafer, but also makes it easier to setup in-line metrology from above the wafer that does not interfere with the actuation.

In one embodiment, the fanout-style nBH is used for direct bonding of dice onto a product substrate. The dice could face upwards on a source substrate (for instance, a tape frame) (i.e., metal layers face away from the source substrate, such as source substrate 106), and downwards on the product substrate, such as product substrate 5603. The source substrate (for instance, tape frame) could be mounted face-down on the bridge, and dice could be picked down using the fanout-style nBH, rotated by 180° (using a die flipper integrated into each fanout-style short-stroke stage), and subsequently placed (and optionally direct bonded) onto the product substrate (which is mounted face-up near the base of the turret-based nBH). Alternatively, the source substrate (for instance, tape frame) could be mounted face-up near the base of the nBH, and dice could be picked up using the nBH, rotated by 180° (using a die flipper integrated into each fanout-style short-stroke stage), and subsequently placed (and, optionally direct bonded) up onto the product substrate (which is mounted face-down on the bridge).

Another method for implementing the nBH uses light-switchable adhesive or LSA. This adhesive changes its state when exposed to different wavelengths of light. In one embodiment, the adhesive liquified with UV exposure. In one embodiment, the adhesive solidifies with visible light exposure. Thus, a die, such as die 115, can be rigidly held temporarily on an LSA-coated surface and can later be picked up. In this way, LSA allows for the decoupling of coarse positioning and nano-precise alignment. The die may be coarsely placed in roughly the correct location with one mechanism and then final adjustments are performed with another die. In one embodiment, the final adjustments (which could include correction in one or more of X, Y, θ_{Z} axes) are performed in a single step. In one embodiment, the final adjustments (which could include correction in one or more of the X, Y, θ_{Z} axes) are performed in multiple steps. For instance, the final adjustments could consist of performing X correction for all dice on the transfer wafer, followed by Y correction for all dies, followed by θ_{Z} correction for all dice. Alternatively, final adjustments could consist of performing X, Y correction for all dice on the transfer wafer, followed by Y, θ_{Z} correction for all dies, followed by X, θ_{Z} correction for all dice. In one embodiment, the nBH strategies discussed herein incorporate LSA-enabled decoupling to accomplish high-throughput advanced packaging.

In one embodiment, the first step of die placement in this design is coarse placement onto an LSA-coated surface. In one embodiment, such a step is be performed with a standard chip shooter mechanism or a cross-rail system as described in a previous design, albeit without the need for high precision actuation or a short-stroke stage attached to each chuck. Such a cross-rail system would be easier to produce than the one described above as it lacks the necessity for nano-precision. This coarse-placement mechanism will place the die, such as die 115, on the LSA at which time it will be hardened to lock the die in place.

Once the die are in their approximate position, another setup containing an array of chucks mounted on short stroke stages will make contact with the die. The system will expose the LSA to liquefy it and the short-stroke stages will make the final adjustments of the die positions and orientations. The LSA will then once again harden and the chucks will retract. The short-stroke array can be placed at the pitch of the product wafer in a manner similar to the serial-pickup-parallel-placement design (i.e., a robotic arm or some sort of cross-rail mechanism) and can be rigidly mounted to a backplane. In such a setup, the array would be reconfigured before any new product wafer could be processed. Alternatively, the short strokes could be mounted on more coarse, long-stroke stages which would be permanently attached to a surface above the wafer. This setup would eliminate the need for pitch readjustment with new product wafers but would likely limit the possible pitch adjustment achieved since long-stroke stage strokes would be limited by interfering with adjacent stages.

One advantage of separating the precision assembly process into two steps is the option to take precise, unencumbered metrology measurements in-between steps. For example, after coarse placement was accomplished, an array of microscopes could come over the die to measure their nanometer-level deviations from the desired position. Such data could be fed into the short-stroke controllers to ensure the die are moved to the proper final position. This would be especially useful if it is too difficult to fit in-line metrology into the system during final position adjustment. The LSA allows the die to be frozen in place without a chuck so a metrology setup can come close to the die without interfering with a chucking assembly.

In one embodiment, a two-stage nBH design could split die pick and place into a first coarse pickup (or pick down, depending on the orientation of the source wafer), followed by die transfer (or hand-off) to a set of short-stroke stages which permit fine motion control, and lastly precise alignment and placement onto a product wafer. In one embodiment, the two-stage nBH is used for direct bonding of dice onto a product substrate. The dice could face upwards on a source substrate (for instance, a tape frame) (i.e., metal layers face away from the source substrate), and downwards on the product substrate. The source substrate (for instance, tape frame) could be mounted face-down on the bridge, and dice could be picked down using the coarse portion of the nBH, and subsequently transferred to the set of short stroke stages (which are mounted on the nBH bridge), which could finally be used to place (and optionally direct bond) the dice onto the product substrate (which is mounted face-up near the base of the nBH). Alternatively, the source substrate (for instance, tape frame) could be mounted face-up near the base of the nBH, and dice could be picked up using the nBH, and subsequently transferred to the set of short-stroke stages (which could be mounted face-up near the base of the nBH), which could finally be used to place (and optionally direct bond) the dice up onto the product substrate (which is mounted face-down on the bridge).

The coarse portion of the nBH could comprise a variable pitch mechanism with chucks (or UCMs, UCM-BHs). The VPM could utilize one or more of the design principles described above (cross-rail, planar motor, turret, fan-out, etc.). In one embodiment, the fine portion of the nBH could comprise short-stroke stages that are attached to a reference plate, and the pitch of which matches that of the SiP being currently assembled. In one embodiment, the pitch of the short-stroke stages could be changed using the coarse portion of the nBH, or a separate VPM, or a separate robotic arm.

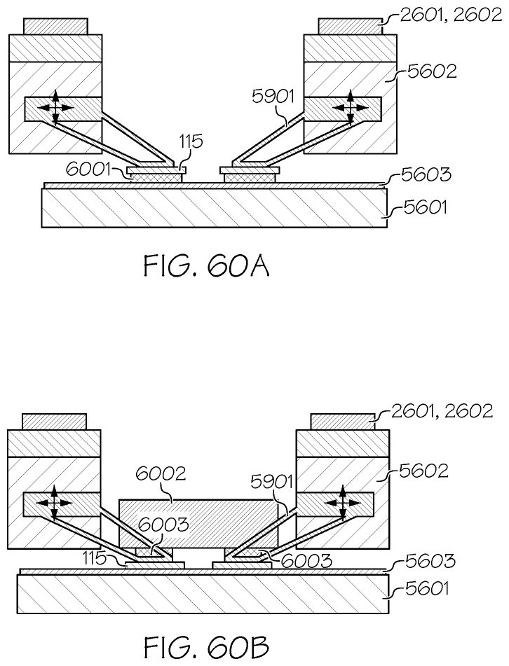

One manifestation of the bonding head architecture consists of larger short stroke stages arranged in an N×2 configuration as shown in FIGS. 59A-59C. In this design, the stages actuate the chuck and die via a cantilever structure. Since such structures can suffer from limited stiffness, they are prone to vibrations. One solution would be to apply damping to the system with a liquid interface 6001 between die 115 and substrate 5603 as shown in FIG. 60A. FIG. 60A illustrates a method of preventing unwanted oscillations of the cantilever structure 5901 by placing a curable adhesive 6001 on the destination substrate 5603 to create a liquid interface between die 115 and substrate 5603 in accordance with an embodiment of the present invention. In one embodiment, liquid 6001 is an adhesive (for instance, a UV-curable adhesive or Light-Switchable adhesive (LSA)) which could be hardened once die 115 is in the correct position. But, in some applications—such as direct die-to-wafer bonding—there cannot be a material between die 115 and the substrate, such as substrate 5603. In this case, a liquid 6003 is between backplane 6002 and the backside of chuck 5602 as shown in FIG. 60B. FIG. 60B illustrates inserting fluid between a rigid structural backplane 6003 and the backside of chuck 5602 in accordance with an embodiment of the present invention. In this way, a mechanical connection could link the rigid machine structure with the compliant cantilever and reduce unwanted oscillation without impeding the bonding process.

As discussed below, there are several configurations for a Universal Chucking Module (UCM) that can be integrated into a larger SiP assembly platform and enable pickup and place of die with varying sizes and thickness. The UCM is a chuck designed to pick up one (or more) dice at a time in order to place them into a larger heterogenous package. Since SiPs are composed of dies with varying sizes, the UCM needs to be able to adjust its active chucking area depending on the target die. It should be small so that many can fit over a wafer at one time which enables high-throughput parallel operation. Furthermore, the following discusses numerous methods for constructing a UCM which could be integrated into a packaging tool. It is noted that the array of UCMs is generally integrated with short-stroke stages, which together can comprise a cross-point puck (CPP) or UCM bonding heads (UCM-BHs), which can further be integrated into a variable pitch mechanism (VPM), which can further be integrated into an n-MASC Bonding Head (nBH).

The common element connecting the various designs of the following UCMs is their ability to change their chucking area which enables their use for a wide variety of die sizes and thicknesses. The UCMs are able to selectively pick up one die while not interfering with an adjacent die. The concepts are detailed below.

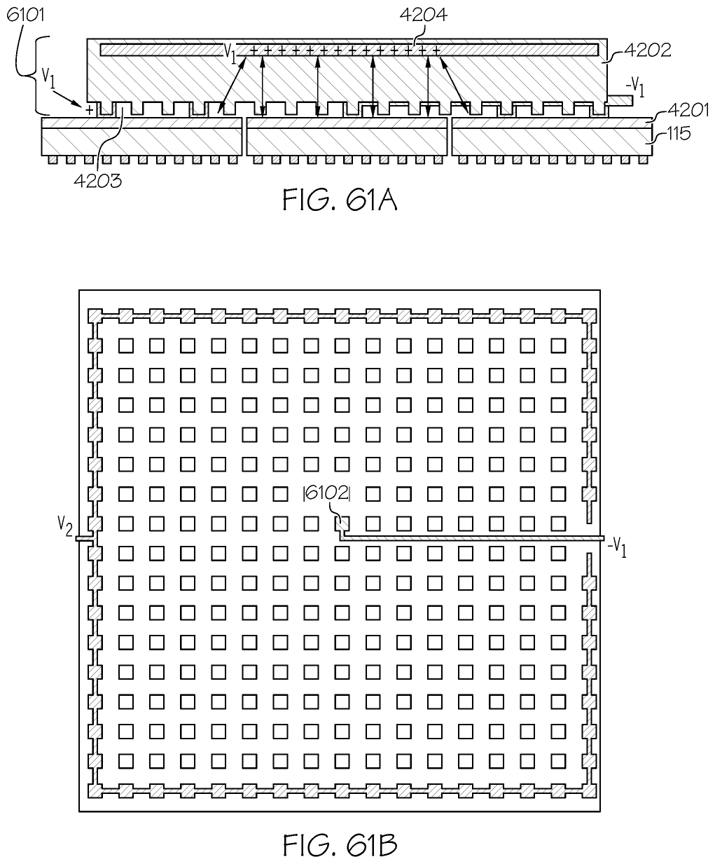

FIGS. 61A-61B illustrate an exemplary single UCM-BH in accordance with an embodiment of the present invention.

Referring to FIG. 61A, a standard encapsulation layer 4201 (e.g., chemical vapor deposition (CVD) carbon) is deposited on die 115. Alternatively, die 115 is encapsulated with medium-to-high conductivity, such as by depositing a thin layer of chromium on top of die 115 or dispersing metal nanoparticles on die 115 or by coating and/or dispersing doped polysilicon on standard encapsulation layer 4201.

Furthermore, as shown in FIG. 61A, in one embodiment, a UCM 6101 includes a dielectric layer 4202 with chuck pins 4203. Additionally, as shown in FIG. 61A, an ACM electrode 4204 is located within dielectric layer 4202.

FIG. 61B depicts a cross-section view of dielectric layer 4202 which illustrates one small electrode 6102 on the underside of dielectric layer 4202 which applies a voltage to the top surface of die 115. The other electrode is held at the opposite polarity to attract die 115.

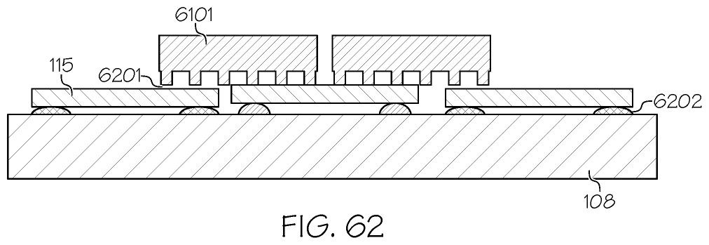

When picking up thin die, chucking pressure is applied over the entire die surface area to avoid inducing bending moments at the edges. A versatile chuck which can pick up thin die of various sizes should be as large as the largest die size but also be capable of picking up smaller die by only activating chucking pressure over the desired region. However, when trying to pick and place smaller die from a tightly spaced array of die, the chuck will contact the die adjacent to the one of interest. If the chuck translates horizontally (i.e., for precision alignment during placement) while contacting other die, the sliding contact will generate particles and undesirable forces on the system. One potential solution consists of dispensing (for instance, using an inkjet) an array of adhesive drops (for instance, a UV-curable adhesive) on the destination substrate for the die. Then, when the chuck is placing a small die between other dies of similar thickness, it can bring the chucked die into contact with the liquid-state drops. If the chuck backs away slightly, the surface tension of the liquid will maintain contact with the die to provide damping and the chuck surface will not be in contact with adjacent die as shown in FIG. 62. The chuck may then perform precision alignment with the chucked die before lowering it again. Finally, when the die is lowered to the proper height, the liquid drops may be exposed and hardened to hold the die in place.

Referring to FIG. 62, FIG. 62 illustrates a gap 6201 between the UCM 6101 and die 115 in accordance with an embodiment of the present invention. As shown in FIG. 62, in one embodiment, there is an adhesive 6202 between die 115 and transfer wafer 108.

Like many wafer chucks, this design takes advantage of electrostatic forces between an electrode in the chuck and the semiconductor being picked up. A dielectric layer insulates the chucking electrode from the die and can be manufactured with pins for particle tolerance. The chucking electrode is a single conducting layer which receives positive voltage during the pickup process. To accommodate different-sized die, the center pin of the dielectric is conductive and connected to a negative voltage source. Thus, when the chuck comes in contact with a die, a negative voltage is applied to the die which attracts it to the positively charged chucking electrode. Any adjacent die are not energized since the negative voltage is only applied at the center pin. Thus, adjacent die will not be picked up. In order to obtain a reasonable force, a high voltage may need to be applied: hundreds to thousands of volts.

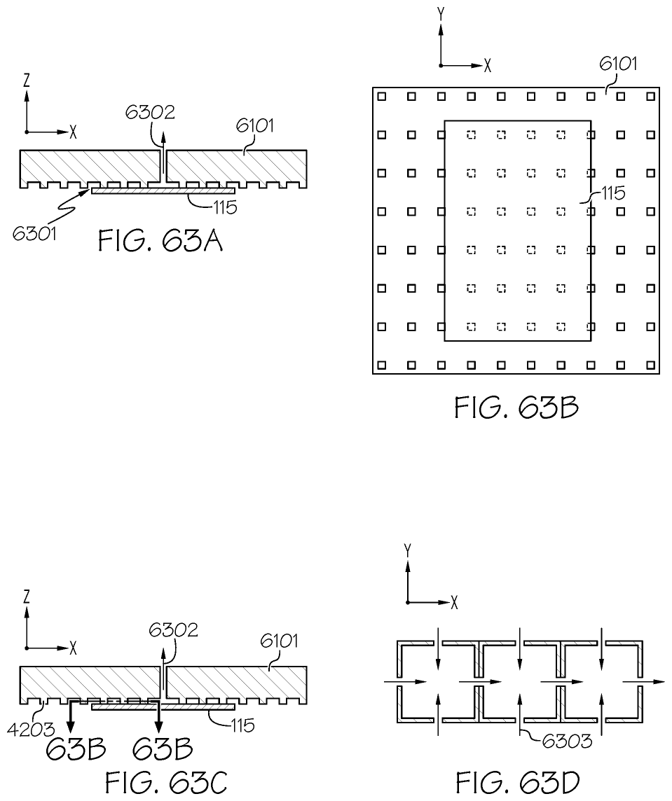

A “leaky chuck” contains an array of pins and applies a vacuum to the center of the array. Rather than relying on a border around the edge of the die to seal off the vacuum, this chuck allows air to leak into the chucking area above the die. In this method, there is no need for any mechanism to vary the chucking area or individually turn on chucking regions. Instead, the pin dimensions are chosen to restrict airflow behind the die enough to create a low-pressure region which can provide a lifting force to the die. Gaps between the central die and adjacent die will create a pressure change which reduces any holding force on adjacent die. In a slightly different configuration, the pin array can be replaced with tesla valves or other passive flow-restricting geometries to enable a sufficient pressure drop above the die to provide adequate clamping force. Such a leaky chuck design is depicted in FIGS. 63A-63D.

Referring to FIGS. 63A-63D, FIGS. 63A-63D depict various views of a leaky chuck design in accordance with an embodiment of the present invention.

As shown in FIG. 63A, UCM 6101 secures die 115 in place. In one embodiment, UCM 6101 secures die 115 in place with a low-pressure region created by air flowing to the vacuum source above die 115. For example, as shown in FIG. 63A, there is restricted airflow 6301 as well as an opening 6302 to a vacuum source.

FIG. 63B illustrates a cross-section view of the design of the leaky chuck design of FIG. 63A.

FIGS. 63C-63D illustrate an alternative design of a leaky chuck in which there is a mesh 6303 with an opening for restricted airflow at the chuck pins 4203 of UCM 6101.

The following discusses an embodiment of having a chuck pin array on the dies.

Such an embodiment adds preprocessing steps to the die in order to optimize the chucking force and pin spacing for each die. Before the dies are brought into the packaging machine, they are etched or otherwise processed to create a raised border around the perimeter of the die and an array of pins. The chuck will simply consist of a flat surface and a central hole where vacuum is supplied. In essence, each die contains its own chucking geometry, and that geometry can be optimized for the die characteristics.

Furthermore, an embodiment may utilize interchangeable chucks for different dies.

In one embodiment, the system has a permanent vacuum chuck mounted to the machine and a collection of interchangeable vacuum chucks. The permanent chuck serves to hold an interchangeable chuck in place corresponding to the die being positioned. Each interchangeable chuck can be tailored for the die it is picking up by varying the vacuum area as well as the pin size and spacing. Before handling a new die type, the system will release the previous interchangeable chuck and pick up one which corresponds to the incoming die.

Additionally, an embodiment of the present invention may utilize a vacuum grid with back-layer connections.

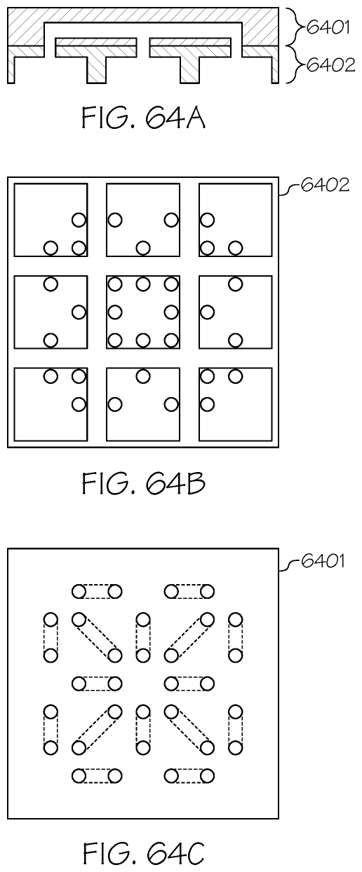

Rather than an array of pins, such a design consists of rows and columns of raised thin walls which intersect to form a grid. The grid lines create an array of hollow squares or cells which enables the application of vacuum to some squares and not others. Above the cell layer, there is a layer of passages which connect adjacent cells to one another pneumatically. The die of interest will always be located in one corner of the grid and vacuum will be applied to the cell in the same corner. The die serves to seal off the cells so the only path for air to travel is through the passages in the back layer of the chuck. A pair of sealing bars are actuated to close the passages at the cells corresponding with the border of the die being chucked. In this way, vacuum is applied to all of the cells above the die of interest and none of the cells outside of this region which prevents accidental pickup of adjacent die. In one embodiment, the sealing bars utilize two actuators to be integrated into the chuck or placed nearby so that the bars can be precisely placed to limit pneumatic connection at the proper cells. Such a design is depicted in FIGS. 64A-64E.

FIGS. 64A-64E depict a grid of vacuum cells with connections in the back layer in accordance with an embodiment of the present invention. In particular, FIG. 64A illustrates a back layer 6401 of chuck layer 6402.

FIG. 64B illustrates a bottom view of chuck layer 6402. FIG. 64C illustrates a bottom view of back layer 6401.

FIG. 64D illustrates a back layer bar 6403 defining the die X size 6404 as well as defining the die Y size 6405 corresponding to the die size 6406 shown in FIG. 64D. Furthermore, FIG. 64D illustrates an exemplary vacuum inlet 6407. In one embodiment, bar 6403 confines a vacuum to the cells directly over the die of interest.

FIG. 64E illustrates a compliant structure, such as a compliant sheet 6408, which is rigid enough to resist a vacuum but compliant enough to deform sufficiently using bar 6403, placed over the walls and bars 6403 in order to press down and seal it.

The following discusses an embodiment of check valves and a moving vacuum source.

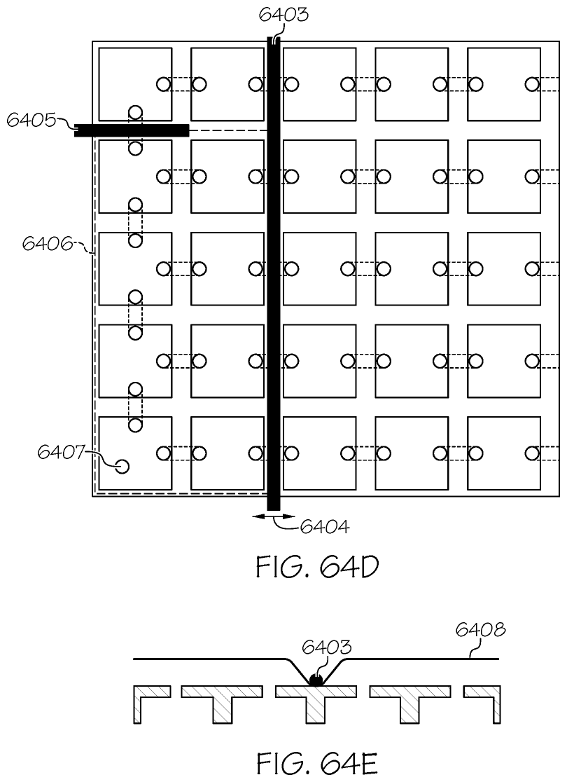

In one embodiment, the UCM design also employs a cell-grid structure rather than an array of pins. As shown in FIGS. 65A-65D, the wall edge between any two cells will contain a check valve which allows air to only flow in one direction. FIGS. 65A-65D illustrate check valves and a moving vacuum source in accordance with an embodiment of the present invention. Referring to FIG. 65A, a vacuum 6501 is applied within the die size 6406 of cell grid 6502. FIG. 65B illustrates that the die size can vary, such a by applying the vacuum source to different grid cells 6503.

Referring now to FIG. 65C, flap valves 6504 are placed along the wall 6505 of the cell grid 6503. For example, FIG. 65D illustrates a single grid cell 6503 with a flap valve 6504 along each edge.

In one embodiment, each interior grid cell 6503 may have valves 6504 arranged such that, when vacuum is applied to the cell, air will flow from the cell to the left of it and the cell beneath it, but not from the other two. In one embodiment, rather than the vacuum source being fixed to one particular cell, it will be moved in response to the size of the die being picked up. The system will line the die up at the lower lefthand corner of the chuck's cell grid 6502. The vacuum source will be moved to apply vacuum to a particular cell 6503 corresponding with the upper righthand corner of the die. And with the die providing a seal at the floor of each cell 6503, the air will be removed from all the cells 6503 over the die resulting in a vacuum pressure which can lift the die. To release the die, air at ambient pressure can be injected into the lower left cell 6503. It is noted that moving the vacuum source to different cells 6503 will require an additional actuation method.

The following discusses an embodiment of interchangeable vacuum masks.

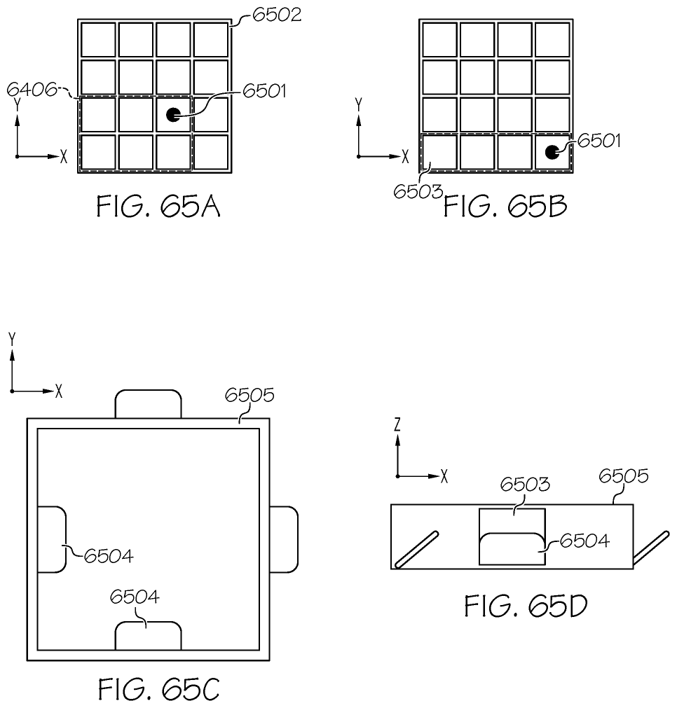

In one embodiment, the vacuum mask UCM design again uses a grid of cells as the basic chuck structure. It selectively admits vacuum through some cells and not others through the use of interchangeable masks. These masks will be flat structures which contain holes at the same pitch as the cells of the chuck grid. Different masks will have different numbers of holes so that by selecting a certain mask or mask combination, only the cells directly above the die of interest will be connected to vacuum. Unlike the design which uses a custom interchangeable chuck for each die, this can be implemented with a standard and limited set of masks and still allow for every rectangular die shape from one grid cell up to the entire chucking surface. One method of reducing the required number of masks is by stacking two masks on top of each other before chucking a die as shown in FIGS. 66A-66E. One mask would define the number of cell columns the die takes up, and one would define the cell rows. When stacked, they would only allow vacuum to pass through those cells directly above the die of interest. In this way, if there are N rows and N columns in the cell grid, the chuck only requires N different mask types (two of each type) compared to Σₖ₌₁^{N} k mask types if only using one grid layer.

Referring to FIGS. 66A-66E, FIGS. 66A-66E illustrate interchangeable vacuum masks in accordance with an embodiment of the present invention.

As shown in FIGS. 66A-66B, an interchangeable X vacuum mask 6501 is placed on a permanent cell grid 6502 to cover various cells 6503 in which a vacuum is applied in the X direction. Furthermore, as shown in FIGS. 66A, 66C, an interchangeable Y vacuum mask 6504 is placed on permanent cell grid 6502 to cover various cells 6503 in which a vacuum is applied in the Y direction

As shown in FIG. 66D, there are various cells 6503 that are covered thereby leaving an exposed die size 6406. A cross-sectional illustration of the cell grid 6502 with masks 6501, 6504 is shown in FIG. 66E.

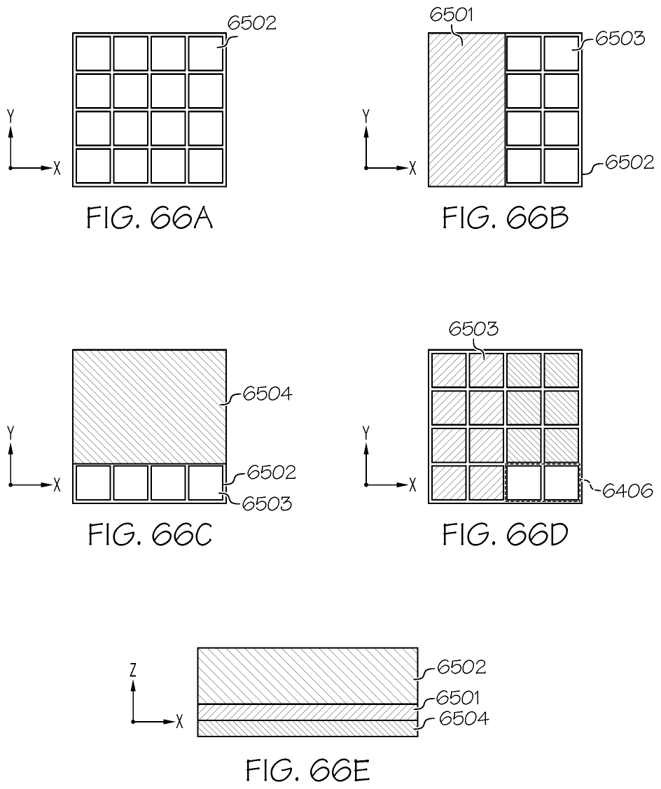

In one implementation of this design, vacuum masks 6501, 6504 required for picking up a particular die would be loaded into the machine in the same way as the die to be chucked, and the UCM would use vacuum suction to chuck mask 6501, 6504 to cell grid 6502. If using two stacked masks, it would perform this step twice—once for each mask—before proceeding to pick up die. Another variation would load masks 6501, 6504, behind cell grid 6502, though this strategy would require a more complicated loading scheme. And a third design could replace interchangeable masks 6501, 6504 with movable masks made of flexible material that remain permanently connected to cell grid 6502 as shown in FIGS. 67A-67E. Actuators above the chuck would then adjust their position so that they restrict pneumatic connection to rows or columns of cells precisely.

Referring to FIGS. 67A-67E, FIGS. 67A-67E illustrate a vacuum mask design which employs permanently attached masks of flexible material which are actuated to cover the desired number of rows and columns in accordance with an embodiment of the present invention.

As shown in FIG. 67A, a chuck body 6701 resides on cell grid 6502 where vacuum mask 6702 covers said chuck body 6701 and cell grid 6502 via rotating actuator 6703, which moves flexible vacuum mask 6702.

FIG. 67B illustrates the underside of the flexible vacuum mask 6702.

FIG. 67C illustrates a top view of chuck body 6701 with the masks in two axes. For example, FIG. 67C illustrates the covered cells 6704 and the flexible mask sides 6705.

FIG. 67D illustrates flexible mask 6702 in the X and Z axes; whereas, FIG. 67E illustrates flexible mask 6702 in the Y and Z axes.

The following discusses an embodiment of pin-actuated check valves.

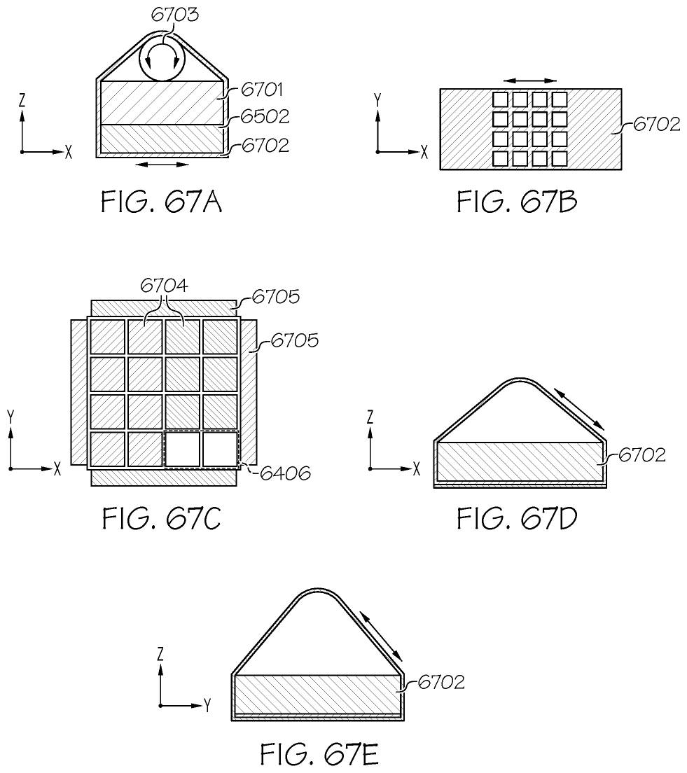

The pin-actuated check valve design takes advantage of the force the die exerts on the chuck to open valves allowing for vacuum chucking force to propagate. Such a design employs a grid of cells which are by default pneumatically isolated from one another except for their openings on the bottom side where they interface with the die. Each cell contains a lever mechanism that consists of a pin protruding downward toward the die and a valve between two adjacent cells. When the chuck is brought into contact with a die, the pins are depressed which opens the valves above the die and all of the cells in that area are pneumatically connected to one another. Vacuum can be supplied to one corner cell of the chuck and the die can be aligned with the same corner which would allow vacuum to spread to all of the cells directly above the die but no further. FIGS. 68A-68B depict such a UCM design.

FIGS. 68A-68B illustrates pin-actuated check valves in accordance with an embodiment of the present invention. As shown in FIGS. 68A-68B, die 115, such as die 115A (“die 1”) and die 115B (“die 2”), depresses pins in the grid cells above it in order to allow vacuum pressure to travel from the die corner to all cells required for chucking the die, such as die 115A. For example, FIG. 68A illustrates an exemplary actuated valve 6801, an exemplary airflow 6802 for the chucked die and a sealed valve 6803 at kerf. Furthermore, FIG. 68A illustrates that no vacuum is supplied to the neighboring dice as shown by element 6804.

FIG. 68B illustrates that only a single die 115A (as opposed to die 115B (“die 2”), die 115C (“die 3”) and die 115D (“die 4”)) is chucked and that no vacuum is supplied to the neighboring dice using the embodiment of FIG. 68A.

The following discusses an embodiment of UCMs based on dispensable dielectrics.

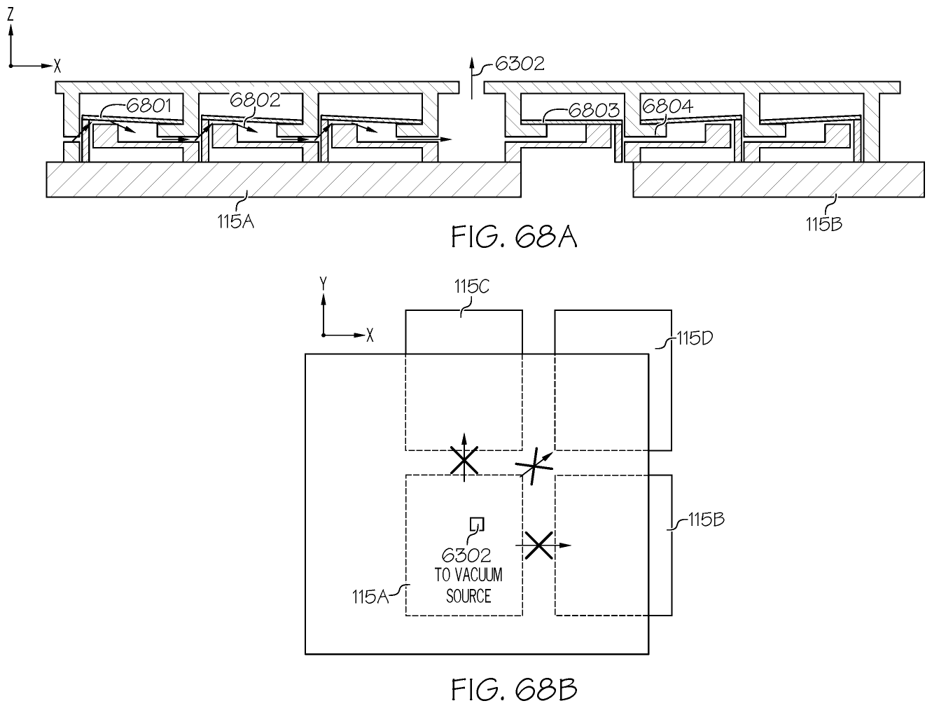

A UCM design which eliminates the interference problem when chucking small thin die located in a dense array while also allowing for the flexibility of chucking different-sized die involves depositing the chucking boundary onto the chuck for each new die size. In such an embodiment, before a wafer with dice of a new size is brought in, an ink-jetting or printing head would deposit pins and a sealing boundary on the flat lower surface of the chuck which corresponds to the size of each die as illustrated in FIG. 69. In one embodiment, said deposition is performed by a sub-system that is separate from the nBH. The added material would comprise the chucking surface which contacts each die. In one embodiment, the vacuum sealing boundary is comprised of dispensed and merged fluid drops. In one embodiment, the dispensed fluid includes one or more of the following: dielectrics, low-k dielectrics, spin-on-glass, alumina, mixture of alumina particles with filler materials, mixture of alumina and glass, and SiLK. In one embodiment, the dispensing is performed using one or more of the following: inkjetting and spin coating. In one embodiment, the dispensed fluid on the underside of the chuck could be brought into contact with a flat surface (such as a bulk silicon, glass, or sapphire wafer, with optional coatings to ensure low adhesion between the fluid and the flat surface), and subsequently heated to remove volatiles from the fluid and solidify it. This could be done to aid in the merging of the fluid drops, and optionally also to create a flat surface on the underside of the solidified fluid drops.

Referring to FIG. 69, FIG. 69 illustrates a permanent chuck body 6701 with a temporary chucking area boundary attached to it using dispensable dielectrics in accordance with an embodiment of the present invention. In one embodiment, chuck body 6701 is made using silicon. Furthermore, as shown in FIG. 69, FIG. 69 illustrates a UCM periphery 6901 that is defined by inkjetted mesas comprised of dispensable dielectrics. In one embodiment, chuck body 6701 may engage die of interest 115 without contacting adjacent die.

In one embodiment, once all of the die are moved, the temporary pins and boundary would be mechanically or chemically removed and the next chuck shape would be created. In one embodiment, Silicon Low-K dielectric material (SiLK) is used for the temporary chuck material because it can be removed from the chuck surface using hydrofluoric acid in order to prepare the chuck for an updated chucking-area boundary. Since only the area of the die contains material on the chuck, there is no overhanging portion of the chuck which will touch adjacent die.

The following discusses an embodiment of smart mesa designs.

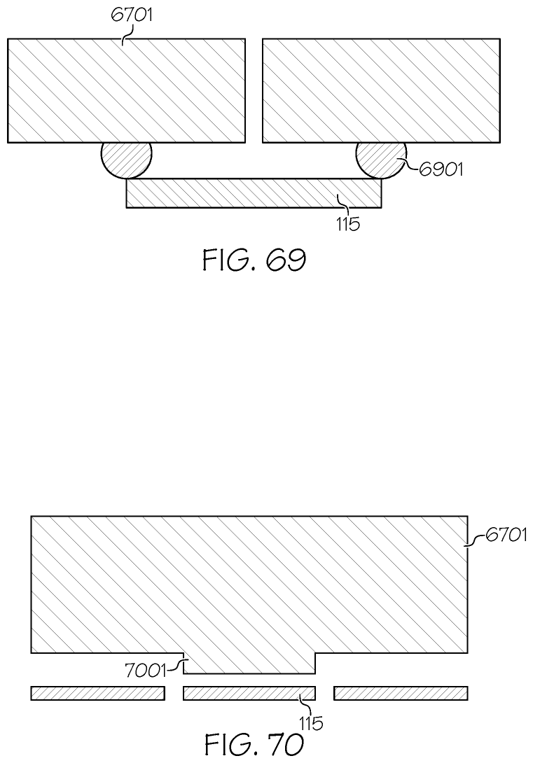

In some applications of individual-die-chucking mechanisms, it is important that the chucking area protrudes away from the chuck body. Such a raised area is referred to herein as the “mesa.” The mesa is important in applications where the dies to be chucked are small and densely packed together. If the die footprint is small relative to the chuck, then the chuck will span multiple die during the pickup process. If there is no mesa and the active chucking area is in the same plane with the inactive area, then the chuck will come into contact with adjacent die as well as the die of interest which will generate particles. And if, for some reason, the surrounding die have greater thickness than the die of interest, such contact could prevent chucking. FIG. 70 depicts a chuck with a mesa to solve the interference problem.

FIG. 70 illustrates a smart mesa design in accordance with an embodiment of the present invention. Referring to FIG. 70, mesa 7001 is utilized to restrict the chucking force to an area that matches the size of die 115. Furthermore, mesa 7001 raises the chucking area away from the inactive portion of chuck body 6701 to avoid interface with adjacent die 115.

Smart mesa designs still fit within the broader category of UCM because they vary their chucking area depending on the size of the die being chucked. But they have the added functionality of raising the active chucking area out away from the chuck body to avoid the interference issue. Several smart mesa designs are described below.

In one embodiment, the UCM includes a chucking surface that chucks a die (or a generic substrate) up till approximately the boundary of the die and retracts back beyond said boundary.

The following discusses the embodiment of vacuum cell pickup.

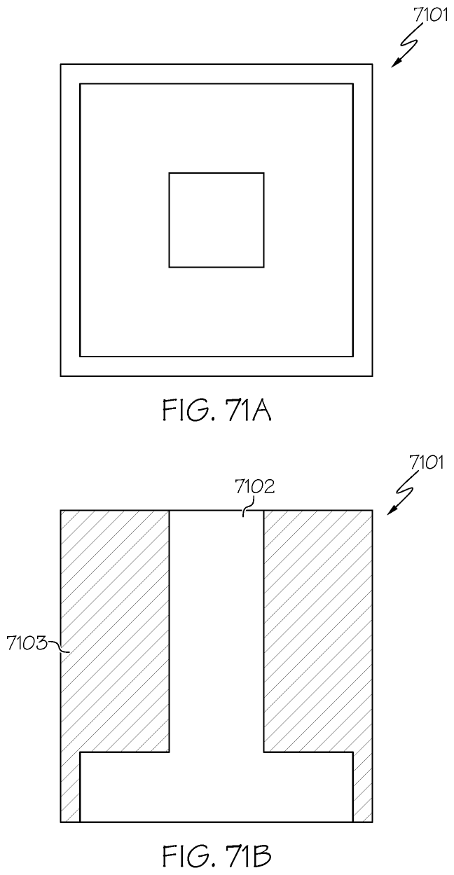

One smart mesa design centers around the idea of picking up individual vacuum cells with the UCM body which together define the shape of the chucking area. In such an embodiment, the UCM includes a permanent body and temporary vacuum cells which can be added or removed depending on the size of the die. The individual vacuum cells are squares whose side dimensions match the minimum incremental change in chucking area required (for instance, 50 μm×50 μm cell footprint to achieve arbitrary chucking length changes down to every 50 μm). In one embodiment, they consist of a vertical hollow region to carry vacuum from the chuck body down to the die and the hollow would open up at the bottom into a wider area as shown in FIGS. 71A-71B.

FIGS. 71A-71B illustrate a single vacuum cell 7101 constructed using MEMS techniques in accordance with an embodiment of the present invention. A bottom view of vacuum cell 7101 is depicted in FIG. 71A and a side view of vacuum cell 7101 is depicted in FIG. 71B. Furthermore, FIG. 71B illustrates vacuum region 7102 and cell structure 7103.

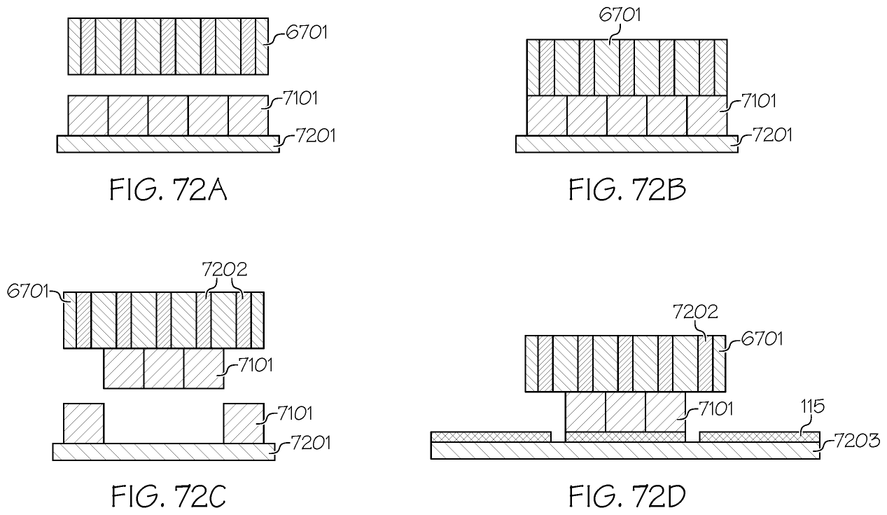

In one embodiment, the vacuum cells, such as vacuum cell 7101, are produced with high density and precise features using standard MEMS fabrication techniques. For instance, vacuum cells 7101 are made from a wafer of silicon carbide, diced, and placed on a tape frame for pickup by the UCM bodies. Before a new die size is chucked by the UCM, a substrate containing an array of the pre-fabricated vacuum cells is brought under the UCM. The UCM bodies would then be lowered and make contact with the vacuum cells and selectively pick up the cells within a border that matches the size of the die to be chucked. Finally, the substrate of the remaining extra vacuum cells would be removed and the wafer of dies is brought in for chucking. Since there are only vacuum cells directly over the die, their thickness forms a natural mesa which prevents the chuck body from contacting the adjacent die. FIGS. 72A-72D detail the process flow for creating the proper mesa for the desired die size.

Referring to FIGS. 72A-72D, FIGS. 72A-72D illustrate the process flow for vacuum-cell pick-up using the smart mesa design in accordance with an embodiment of the present invention.

Referring to FIG. 72A, a substrate 7201 of individual pre-fabricated vacuum cells 7101 is brought to the UCM body/chuck body 6701.

As shown in FIG. 72B, UCM body/chuck body 6701 is lowered to make contact with vacuum cells 7101.

As shown in FIG. 72C, UCM body/chuck body 6701 selectively attaches to vacuum cells 7101 which constitute the die footprint via the use of vacuum ports 7202.

As shown in FIG. 72D, the newly-configured UCM body/chuck body 6701 chucks a die 115 on a target substrate 7203 without adjacent die interference.

In one embodiment, these vacuum-cell-pickup designs are able to selectively pickup only the cells which are required for a given die size. In one embodiment, the force which is used to connect them to the UCM body 6701 is different from the vacuum they supply to die 115 so that chucking of dies 115 is not coupled with assembling the UCM. Finally, in one embodiment, vacuum is only applied at the locations where vacuum cells 7101 are attached so that there will not be leaks elsewhere on chuck body 6701.

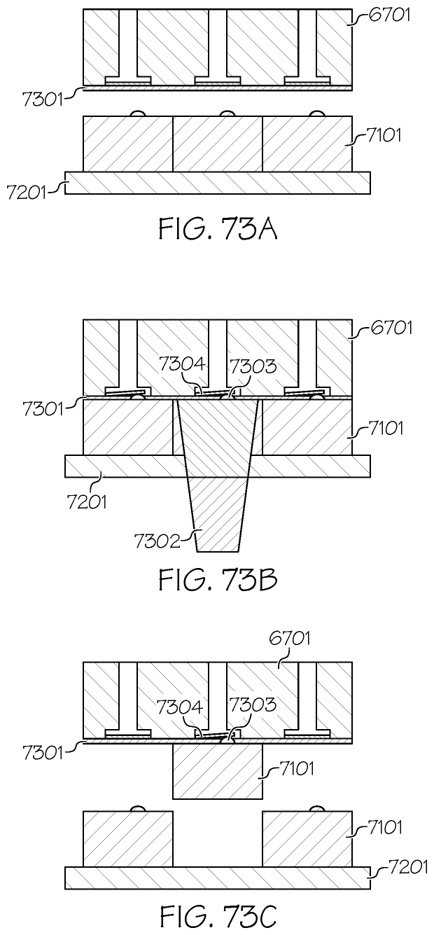

There are a number of design variations that meet the features discussed above. One design connects vacuum cells 7101 to die 115 using a light-switchable adhesive. In one embodiment, chuck body 6701 is coated with an adhesive in liquid form. Once body 6701 comes into contact with vacuum cells 7101, an addressable light source (such as a digital micromirror device) can expose the adhesive to the wavelength of light which will solidify it, but only in the region where the mesa will be made. Thus, only cells 7101 that are in the footprint of die 115 will adhere to chuck body 6701 while the rest of cells 7101 can be held onto the original substrate. In such a design, chuck body 6701 should have an array of flaps at the same pitch as vacuum cell 7101. In one embodiment, vacuum cells 7101 have a protruding feature which holds the flap open when in contact with chuck body 6701. In this way, the region of chuck body 6701 which does not hold vacuum cells 7101 will not pull air in during the chucking process. Once the UCM needs to be reconfigured, the adhesive can be exposed to a different wavelength which re-liquefies it. In one embodiment, vacuum cells 7101 are made out of a material which is transparent so that the adhesive can be exposed at the interface between cells 7101 and chuck body 6701. FIGS. 73A-73C show the adhesive-enabled vacuum cell design.

FIGS. 73A-73C illustrate an adhesive-enabled vacuum-cell-pickup design in accordance with an embodiment of the present invention.

As shown in FIG. 73A, vacuum cells 7101 on substrate 7201 are brought into contact with chuck body 6701. Furthermore, as shown in FIG. 73A, chuck body 6701 is coated with an adhesive 7301, such as a light-switchable adhesive.

As shown in FIG. 73B, adhesive 7301 is exposed with light (ultraviolet (UV) light 7302) above cells 7101 which are meant to stay fixed to chuck body 6701, such as via a flap-opening bump 7303 of flap 7304.

As shown in FIG. 73C, chuck body 6701 is separated from the vacuum cell substrate 7201. Cells 7101 which are attached hold flaps 7304 open to apply vacuum to die 115.

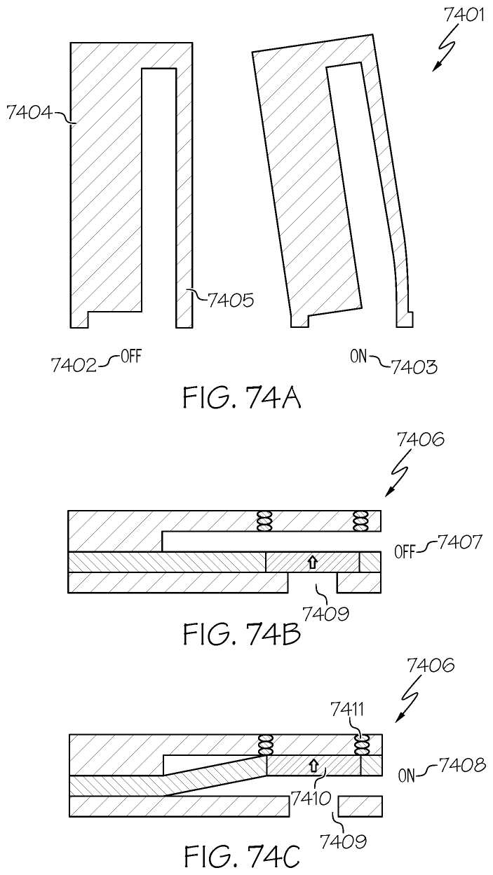

Other vacuum cell designs consist of an addressable array of MEMS-scale actuators within the chuck body. Each actuator acts as a valve to either allow vacuum or block it from reaching the bottom surface of the UCM body. The valves are at the same pitch as the vacuum cells so that each valve connects vacuum to a single cell. Depending on the desired mesa size, the proper valves are opened and the chuck body is brought into contact with the array of cells. At each location where a valve is open, the vacuum cell is connected to the body and becomes part of the mesa. In such a design, each cell must have two vacuum ports that are connected to two vacuum sources. One vacuum source connects the vacuum cell to the chuck body. The other supplies vacuum through the cells to the die to provide the chucking force. Examples of MEMS valves include thermal actuators, solenoid-type actuators, electrostatic, or piezo, etc. FIGS. 74A-74C illustrate two examples.

FIGS. 74A-74C illustrate two implementations of a MEMS-scale valve in accordance with an embodiment of the present invention.

As shown in FIG. 74A, a thermal actuator 7401 is depicted in both an OFF state 7402 and in an ON state 7403 in which the cold side 7404 and hot side 7405 are reversed between OFF state 702 and ON state 7403.

As shown in FIGS. 74B-74C, a magnetic cantilever valve 7406 is depicted in an OFF state 7407 and in an ON state 7408. In the OFF state 7407, as shown in FIG. 74B, magnetic cantilever valve 7406 has a closed valve opening 7409. In the ON state 7408, valve opening 7409 is opened as a result of magnet 7410 being attracted to coil 7411.

The following discusses the embodiment of high CTE cells.

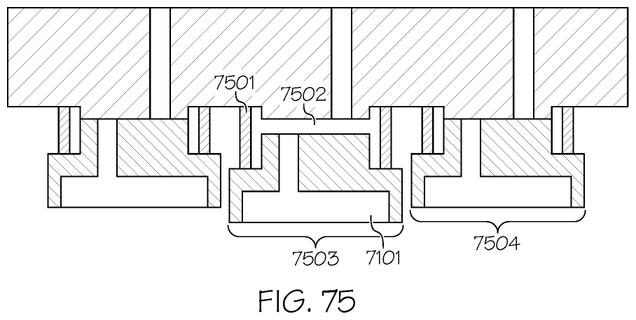

Unlike the previous design which picks up an array of vacuum cells depending on the die size, the high-CTE-cell design holds all the cells needed to pick up the largest required die. So in order to create a mesa, some cells protrude downward away from the chuck body while the inactive cells remain retracted. The high-CTE-cell design performs this displacement using simple thermal expansion. Each vacuum cell is connected to the chuck body via a hollow pillar made of a high-coefficient-of-thermal-expansion (CTE) material which also serves as a tube to transmit vacuum chucking force to the lower cell surface. In order to raise a cell as part of the mesa, current is passed through the tube so that it heats and expands downward. As shown in FIG. 75, the thermal actuation may also be used to open and close the vacuum connection to each cell so that only extended cells receive vacuum. Mechanical stops may be implemented so that all the extended cells remain at the same height. To supply current to each individual cell pixel, an array of switch circuits (such as thin-film transistors or a CMOS layer) may be used. The switching electronics may be built directly into the same substrate as the chuck with electrical connections down to the high-CTE pillars.

FIG. 75 illustrates a smart mesa design using high-CTE hollow pillars to connect vacuum cells 7101 to chuck body 6701 in accordance with an embodiment of the present invention.

As shown in FIG. 75, in order create the mesa, current runs through pillars (thermal actuators) (high-CTE hollow pillars) 7501 to cause cells 7101 to expand (see element 7503) and open a vacuum connection 7502. When current is not run through pillars 7501, cells 7101 are retracted (see element 7504).

The following discusses the embodiment of the DMD-inspired design.

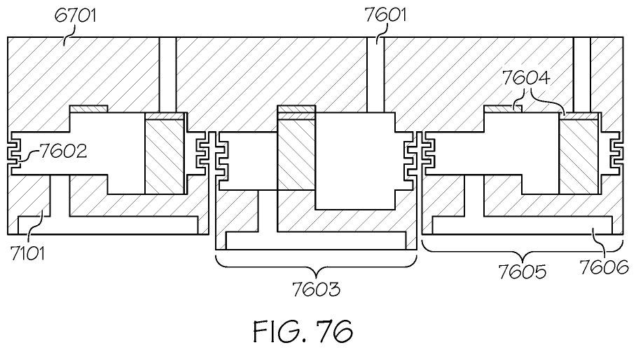

The digital micromirror device (DMD) created by Texas Instruments® is commonly found in projectors and other optical applications today. In one embodiment, in the MEMS device, there is an array of micron-scale mirrors which are tilted back and forth by electrostatic actuation to manipulate light. Each mirror controls one pixel of a display image and the actuation is performed by a CMOS circuit in the device body which selectively applies voltage to the proper pixels to enable the mirror to tilt. Starting from the same basic principles of CMOS-enabled addressability and electrostatic actuation, a smart mesa design can be created. In such a design, vacuum cells 7101 are each connected to the main chuck body 6701 via bellows as shown in FIG. 76. These bellows enable vacuum to be transmitted to vacuum cell 7101 from body 6701 while allowing vertical translation.

FIG. 76 illustrates a DMD-inspired smart mesa design in accordance with an embodiment of the present invention.

As shown in FIG. 76, cells 7101 are first extended, such as via a vacuum being transmitted to vacuum cell 7101 via vacuum inlets 7601 by bellows 7602. Such an extended vacuum cell may be said to be an active cell 7603. Electrostatic actuation performed by electrostatic actuator electrodes 7604 creates mechanical stops to keep mesa cells extended (see active cell 7603). In one embodiment, actuator electrodes 7604 act as a valve seal. A cell that is not extended is said to be an inactive cell 7605. Furthermore, FIG. 76 illustrates chucking area 7606.

In one embodiment, rather than directly extend and retract the vacuum cells 7101 using electrostatic actuation (which would require relatively high forces), actuator 7604 moves a mechanical stop in such a way that it can hold cell 7101 extended (see 7603) when on, or allow cell 7101 to retract when off (see 7605). To create room for the actuation to take place when configuring a new mesa size, all cells 7101 would be extended via an external force (i.e., chucking all cells against a reference plate). Then the proper actuators would be turned on and the external force would be removed. The backstops will remain extended only for those cells 7101 which had actuated; whereas, the other cells 7101 retract thereby forming a mesa. The backstop may also double as a valve seal which allows vacuum to flow to the chucking surface when the cell is extended but prevents flow when retracted. In one embodiment, the backstop is connected to chuck body 6701 through a flexure setup which only allows for motion in a single degree of freedom.

The following discusses the embodiment involving passive mesa creation.

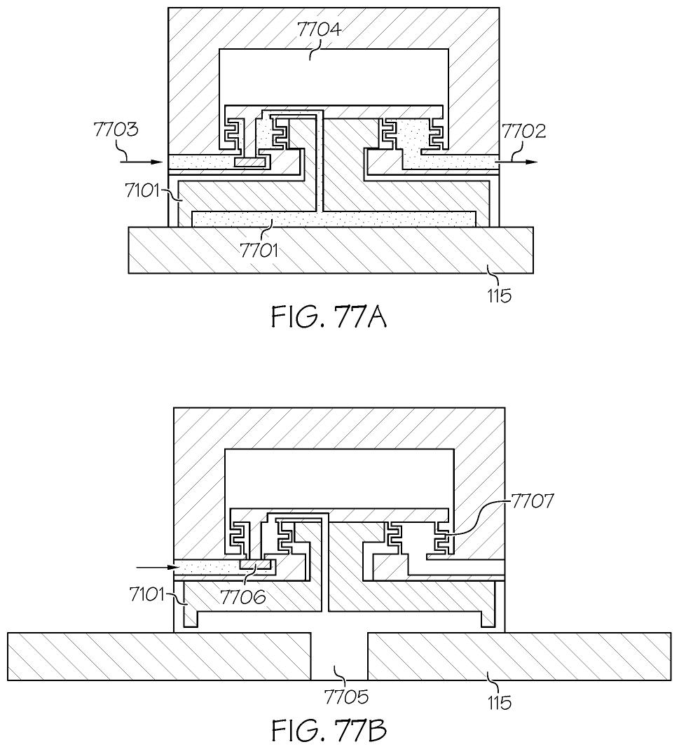

The above designs have required either picking up vacuum cells or individually actuating each cell in order to create the mesa. In one embodiment, the deign involving passive mesa creation eliminates the need for such actuation by employing the chuck's contact with the die to determine the mesa size. The basic mechanism consists of vacuum being sourced to one cell (i.e., the central vacuum cell of the chuck) and propagating to the other cells serially after the chuck makes contact with the die. And if a vacuum cell lies over the kerf separating two adjacent die, it retracts and does not allow vacuum to propagate further. The mechanism is designed in such a way that a strong vacuum seal is maintained at the chucking surface in order to keep the cell extended as shown in FIGS. 77A-77B. When an initial contact with the die is made, an external actuator extends all the cells downward to make contact with the die. Vacuum propagates to the cells that are over the die, but the cell over the kerf cannot maintain a vacuum seal so it retracts and vacuum fails to propagate further. In this way, the cells over the adjacent die do not apply chucking force to the die and after the initial contact made during mesa creation, they no longer touch neighboring die either. The retraction force on the die is carried out by bellows which double as an axial spring. This purely mechanical solution allows for mesa creation without individual addressability.

FIGS. 77A-77B illustrates a passive mesa design in accordance with an embodiment of the present invention.

Referring to FIG. 77A, FIG. 77A illustrates expanding a cell 7101 using a vacuum seal 7701 between die 115 and cell 7101 to propagate vacuum supply (see 7702) to adjacent cells (see 7703, which illustrates the vacuum from an adjacent cell) and hold cell 7101 in extended position. Furthermore, FIG. 77A illustrates the ambient air pressure 7704.

FIG. 77B illustrates a retracted cell in which vacuum cell 7101 lies over kerf 7705 separating two adjacent die 115 thereby causing cell 7101 to retract and not allow the vacuum to propagate further (see blocked vacuum 7706). Furthermore, FIG. 77B illustrates that the retraction force on die 115 is carried out by bellows 7707 which double as an axial spring.

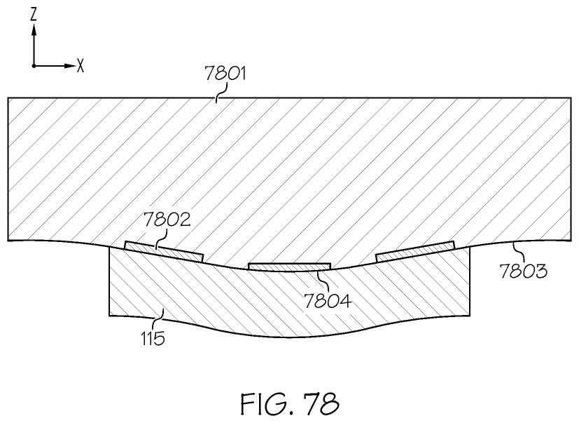

In one embodiment, the UCM consists of a chuck, whose chucking surface has a curvature along one or more of the X and Y directions. Such a UCM could be smaller than the size of the dies being picked up. The dies being picked up could be thick enough to have mechanical stability (against fracture and breakage, for instance). The dies could be over-50 μm, over-100 μm, over-200 μm, or over-500 μm thick. In one embodiment, the UCM is used during pickup from a source substrate, placement onto a product substrate, with intermediate substrates and during transfer between one bonding head to another bonding head. In one embodiment, the pickup is implemented in a manner such that a central chucking surface of the chuck makes first contact with a die. Subsequently vacuum on the side chucking surfaces could be activated to conform the die along the curvature of the chuck. During transfer form one bonding head to another bonding head or substrate, a central surface of the curved die makes first contact with the central surface of the chuck on the second bonding head or the substrate. The outer region of the first chuck could now be pressurized. Concurrently vacuum could be supplied to the second bonding head. An illustration of such a curved UCM is provided in FIG. 78.

FIG. 78 illustrates an exemplary design for a curved UCM in accordance with an embodiment of the present invention.

As shown in FIG. 78, there is a curved UCM 7801 with curvature in the X direction. Furthermore, as shown in FIG. 78, there are one or more optionally individually addressable, side-chucking surfaces 7802. Such surfaces 7802 may be used to produce a pulling force and/or pushing force using a pneumatic or electrostatic means. In one embodiment, side chucking surface 7802 is in the form of concentric rings around the central chucking surface 7804. In one embodiment, side chucking surfaces 7802 are sequentially actuated to bend dies 115 of different sizes. For instance, small dies (sub-5 mm on a side, for instance) might require only one ring-shaped side-chucking surfaces close to central chucking surface 7804 to be actuated. On the other hand, large dies (over 10 mm on a side, for instance) might require many ring-shaped side-chucking surfaces 7802 to be actuated.

Furthermore, FIG. 78 illustrates a UCM chucking surface 7803 and central chucking surface 7804 that is optionally smaller than the smallest die 115 to be picked up by UCM 7801.

As a result of the foregoing, the principles of the present invention provide a means for picking and placing components on a target device, such as a printed circuit board, in a less expensive manner than prior surface-mount technology component placement systems. Furthermore, the tool of the present invention for pick-and-place assembly enables the type of components to be mounted to be less limiting. Additionally, the speed for such placement of the components on a target device is less limiting using the tool of the present invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1-26. (canceled)

27. A system for assembling a group of dies from a source substrate onto a product substrate, comprising:
a high-throughput low-precision system configured to pick said group of dies from said source substrate and placed onto an intermediate substrate, wherein said placement of said group of dies onto said intermediate substrate is performed such that one or more of X and Y pitch of said placed group of dies matches a corresponding system-in-package (SiP) pitch; and
a parallel high-precision system configured to assemble said group of dies from said intermediate substrate onto said product substrate, wherein said placement of said group of dies onto said product substrate is performed at said SiP pitch, wherein a precision of assembly onto said product substrate is sub-500 nm.

28. The system as recited in claim 27, wherein said placement of said group of dies onto said product substrate utilizes one or more of the following: fusion, hybrid, and direct bonding.

29. The system as recited in claim 27, wherein said placement of said group of dies onto said intermediate substrate utilizes one or more of the following: fusion and adhesive bonding.

30. The system as recited in claim 27, wherein said group of dies comprises 9 or more dies.

31. The system as recited in claim 27, wherein said intermediate substrate is a tape frame.

32. The system as recited in claim 27, wherein said parallel high-precision system utilizes an architecture with oppositely oriented intermediate and product substrates, wherein a substrate-scale die chuck picks dies from said intermediate substrate and subsequently transfers them to an array of short-stroke stages which subsequently places said dies onto said product substrate.

33. The system as recited in claim 27, wherein said parallel high-precision system utilizes an array of die flippers for parallel flip-chip assembly.

34. The system as recited in claim 32, wherein said array of short-stroke stages allows one or more dies in said group of dies to displace in a z direction with a pre-specified compliance.

35. The system as recited in claim 27, wherein a precision of assembly onto said product substrate is sub-200 nm.

36. The system as recited in claim 27, wherein a precision of assembly onto said product substrate is sub-100 nm.

37. The system as recited in claim 27, wherein an adhesive in liquid form is used to secure said group of dies in a vicinity of their final position on said intermediate substrate using self-assembly principles.

38. The system as recited in claim 27, wherein a deformable solid or gel-type adhesive is used to secure said group of dies in a vicinity of their final position on said intermediate substrate.

39. The system as recited in claim 38, wherein a deformability of said adhesive is reduced after a fine alignment step on said intermediate substrate.

40. The system as recited in claim 38, wherein a UV curing step is utilized to reduce a deformability of said adhesive.

41. The system as recited in claim 27, wherein a group of die chucks is used to hold said group of dies in a thermo-mechanically stable manner.

42. The system as recited in claim 41, wherein said group of die chucks is clamped onto a support plate.

43. The system as recited in claim 42, wherein said support plate is composed of a material that is transparent in one or more of the following: UV, visible, and IR wavelengths.

44. The system as recited in claim 42, wherein said support plate is composed of and/or coated with a scratch resistant layer.

45. The system as recited in claim 42, wherein said group of die chucks is clamped onto said support plate using one or more of the following: vacuum suction, electrostatic forces, and magnetic forces.

46. The system as recited in claim 41, wherein said group of die chucks is provided with one or more of the following: control signals, electrical power, vacuum and pressure supply, and fluidic cooling using a group of wiring harnesses.

47-100. (canceled)
